(19) United States
(12) Patent Application Publication
(10) Pub. No.: US 2026/0276251 A1
(43) Pub. Date: Sep. 17, 2026

(54) FIELD ACTIVATED SOLID-STATE THERMAL SWITCHES AND SUB-KELVIN ADR STAGE INCLUDING FIELD ACTIVATED SOLID-STATE THERMAL SWITCHES

(71) Applicant: Ohio State Innovation Foundation, Columbus, OH (US)

(72) Inventors: Joseph Heremans, Upper Arlington, OH (US); Dung Vu, Hamden, CT (US)

(21) Appl. No.: 18/872,022

(22) PCT Filed: Jun. 7, 2023
(86) PCT No.: PCT/US2023/024691

§ 371 Date: Dec. 5, 2024

Related U.S. Application Data
(60) Provisional application No. 63/349,822, filed on Jun. 7, 2022.
(60) Provisional application No. 63/378,290, filed on Oct. 4, 2022.

(51) Int. Cl. F25B 21/00; F25B 7/00

(52) U.S. Cl. CPC F25B 21/00; F25B 7/00; F25B 2321/001

(57) ABSTRACT

Thermal switches, ADR stages and devices, and methods of using thermal switches and ADR stages and devices. A thermal switch includes a magnetothermal element made of a magnetothermal material that is inherently or is inducible by a magnetic field into being a Weyl semimetal. An ADR stage includes one thermal switch with a magnetothermal material having thermal conductivity that increases in response to application of a magnetic field and another thermal switch with a magnetothermal material having a thermal conductivity that decreases in response to application of the magnetic field. An ADR device includes multiple ADR stages operatively coupled in series, with each ADR stage optimized for the temperature range over which it operates.

### CROSS-REFERENCE TO RELATED APPLICATIONS

This application claims the benefit of U.S. Application No. 63/349,822 filed on Jun. 7, 2022 and entitled “Sub-Kelvin ADR Cycle Using Magnetic Field Activated Solid-State Thermal Switches Based on the Thermal Chiral Anomaly”, and U.S. Application No. 63/378,290 filed on Oct. 4, 2022 and entitled “Field Activated Solid-State Thermal Switches and Sub-Kelvin ADR Stage Including Field Activated Solid-State Thermal Switches”, the disclosures of which are incorporated by reference herein in their entireties.

### GOVERNMENT RIGHTS

This invention was made with government support under grant/contract number 2011876 awarded by the National Science Foundation and N00014-21-1-2377 awarded by the Office of Naval Research. The government has certain rights in the invention.

### FIELD OF INVENTION

The present invention relates generally to thermal switches and, more particularly, to magnetically activated solid state thermal switches, as well as systems and methods of using these switches for cryogenic cooling.

### BACKGROUND

Adiabatic Demagnetization Refrigeration (ADR) is technique used for cryogenic cooling, and is capable of producing very low temperatures, e.g., 100 milli-Kelvin and below from relatively high heat sink temperatures of 1-5 Kelvin. ADR utilizes the magnetocaloric effect, which is a phenomenon exhibited by magnetocaloric materials in which the temperature of the material changes in response to being exposed to increasing or decreasing magnetic fields. This phenomenon is due to the entropy of magnetocaloric materials being dependent on both magnetic field and temperature. Magnetizing a magnetocaloric material causes an increase in the temperature of the material, and demagnetizing a magnetocaloric material causes a decrease in the temperature of the material.

Conventional ADR cycles operate by repeatedly applying and removing a magnetic field from a mass of magnetocaloric material. While in the magnetized state, the magnetocaloric material is thermally coupled to a heat sink, such as a reservoir of liquid helium, which absorbs heat from the magnetocaloric material. While in the demagnetized state, the magnetocaloric material is thermally coupled to a thermal load, such as a test sample, so that the magnetocaloric material absorbs heat from the sample. The magnetocaloric material is thereby used to pump heat from the sample into the heat sink. Known ADR stages use vacuum pumping of helium heat exchange gas to selectively thermally couple the magnetocaloric material alternately to the heat sink and thermal load. These types of selective thermal couplers are commonly referred to as gas-gap thermal switches. However, these thermal switching devices include complex mechanical parts that are subject to wear and have slow switching rates. Accordingly, there is a need for improved thermal switches for use in ADR stages as well as improved ADR stages, and methods of using these thermal switches and ADR stages.

### SUMMARY

In an aspect of the invention, a thermal switch is provided. The thermal switch includes a magnetothermal element, a first thermal terminal, and a second thermal terminal. The magnetothermal element includes a first end face and a second end face, and is made of a magnetothermal material that is inherently or is inducible by a magnetic field into being a Weyl semimetal. The first thermal terminal is thermally coupled to the first end face of the magnetothermal element, and the second thermal terminal is thermally coupled to the second end face of the magnetothermal element.

In an embodiment of the thermal switch, the magnetothermal material may be induced into being the Weyl semimetal by the magnetic field.

In another embodiment of the thermal switch, an on-off state of the thermal switch may be controlled by the magnetic field being applied to a direction parallel to a separation of Weyl points in the magnetothermal material.

In another embodiment of the thermal switch, the magnetothermal material may have a thermal conductivity that increases in response to application of the magnetic field.

In another embodiment of the thermal switch, the magnetothermal material may be a bismuth-antimony alloy (Bi₁₋ₓSbₓ) including a first crystallographic axis and a second crystallographic axis, and the first end face and the second end face of the magnetothermal element may be normal to the first crystallographic axis. The magnetothermal material may be a thermal insulator without the magnetic field or in magnetic fields oriented along the second crystallographic axis, and may become a magnetic field-induced Weyl semimetal when the magnetic field is oriented along the first crystallographic axis. In this embodiment, the first crystallographic axis may be the (001) axis of the magnetothermal material, and the second crystallographic axis may be one of the (100) axis or the (010) axis of the magnetothermal material.

In another embodiment of the thermal switch, x may be greater than 0.04, less than 0.22, or between 0.09 and 0.16.

In another embodiment of the thermal switch, the Bi₁₋ₓSbₓ may be doped with about 20 parts per million tin, or with a concentration of tin between 10 and 200 part per million tin.

In another embodiment of the thermal switch, the magnetothermal element may include a plurality of sections of the magnetothermal material that form a laminate.

In another embodiment of the thermal switch, each section of the plurality of sections may have a length dimension, a lateral dimension less than the length dimension, and may be oriented so that the length dimension is orthogonal to one or both of the first end face and the second end face.

In another embodiment of the thermal switch, the first end face and the second end face of the magnetothermal element may be spaced apart in a longitudinal dimension, and the magnetothermal element may be configured so that paired Weyl points in the magnetothermal material are spaced along a line parallel to the longitudinal dimension.

In another embodiment of the thermal switch, the magnetothermal element may include nanoparticles in a size range of 10 nm to 100 μm. The nanoparticles may be made from an electrically insulating substance and have a concentration range from 1% to 30% by volume in the magnetothermal element.

In another aspect of the invention, another thermal switch is provided. The thermal switch includes the magnetothermal element having the first end face and the second end face, the first thermal terminal thermally coupled to the first end face of the magnetothermal element, and the second thermal terminal thermally coupled to the second end face of the magnetothermal element. However, in this aspect of the invention, the magnetothermal element is made of a magnetothermal material that is a member of a group consisting of trivial semimetals, Dirac semimetals, Weyl semimetals when a magnetic field is applied to a direction normal to the separation of Weyl points in the magnetothermal material, Weyl semimetals when the magnetic field does not have a component parallel to the separation of Weyl points and normal directions to at least one of the first end face or the second end face of the magnetothermal material, and intrinsic semiconductors and topological insulators when the magnetic field does not induce Weyl semimetal phase with an energy gap less than k_{B}T where Tis an operating temperature.

In an embodiment of the thermal switch, the magnetothermal material may have a thermal conductivity that decreases in response to application of the magnetic field.

In another embodiment of the thermal switch, the magnetothermal material may be the bismuth antimony alloy (Bi₁₋ₓSbₓ) including the first crystallographic axis and the second crystallographic axis, the first end face and the second end face of the magnetothermal material may be normal to the second crystallographic axis, and the magnetothermal material may have a first thermal conductivity without the magnetic field and a second thermal conductivity lower than the first thermal conductivity when the magnetic field is oriented along the first crystallographic axis, the first crystallographic axis may be the (001) axis of the magnetothermal material, and the second crystallographic axis may be one of the (100) axis or the (010) axis of the magnetothermal material.

In another embodiment of the thermal switch, the magnetothermal material may be the bismuth antimony alloy (Bi₁₋ₓSbₓ) including the first crystallographic axis and the second crystallographic axis, the first end face and the second end face of the magnetothermal material may be normal to the first crystallographic axis, the magnetothermal material may have a first thermal conductivity without the magnetic field and a second thermal conductivity lower than the first thermal conductivity when the magnetic field is oriented along the second crystallographic axis, the first crystallographic axis may be the (001) axis of the magnetothermal material, and the second crystallographic axis may be one of the (100) axis or the (010) axis of the magnetothermal material.

In another embodiment of the thermal switch, the Bi₁₋ₓSbₓ may be doped with a concentration of Tellurium between 50 and 400 parts per million Tellurium (Te).

In another aspect of the invention, an ADR stage is provided. The ADR stage includes a first thermal switch including a first magnetothermal material having a first thermal conductivity that increases in response to application of a magnetic field, a second thermal switch including a second magnetothermal material having a second thermal conductivity that decreases in response to application of the magnetic field, and a mass of magnetocaloric material having a first end face thermally coupled to the first thermal switch, and a second end face thermally coupled to the second thermal switch.

In an embodiment of the ADR stage, the ADR stage may include a magnetic field generator configured to selectively generate the magnetic field. The magnetic field generator may be magnetically coupled to the first thermal switch, the second thermal switch, and the mass of magnetocaloric material, and may orient the magnetic field in a direction which activates the first thermal switch and the second thermal switch.

In another embodiment of the ADR stage, the ADR stage may further include a controller operatively coupled to the magnetic field generator and configured to cycle the magnetic field generated by the magnetic field generator between a minimum magnetic field strength and a maximum magnetic field strength.

In another embodiment of the ADR stage, the first magnetothermal material may inherently be a Weyl semimetal, or may be induced into being a Weyl semimetal by the magnetic field.

In another embodiment of the ADR stage, the first end face and the second end face of the mass of magnetocaloric material may be spaced apart in a longitudinal dimension, and the first thermal switch may be configured so that paired Weyl points in the first magnetothermal material are spaced along a line parallel to the longitudinal dimension.

In another embodiment of the ADR stage, one or both of a magnetic sweep profile and a rate of magnetization transition may be configured to optimize a performance parameter of the ADR stage.

In another embodiment of the ADR stage, the first thermal switch may thermally couple the mass of magnetocaloric material to a heat sink, and the second thermal switch may thermally couple the mass of magnetocaloric material to a thermal load.

In another embodiment of the ADR stage, the second magnetothermal material may be a topological insulator.

In another embodiment of the ADR stage, the first thermal switch may be configured with a first geometric aspect ratio, the second thermal switch may be configured with a second geometric aspect ratio, and a ratio of the first geometric aspect ratio to the second geometric aspect ratio may be configured to optimize a performance parameter of the ADR stage.

In another aspect of the invention, a multi-stage ADR device is provided. The multi-stage ADR device includes a first thermal switch with a first magnetothermal material having a first thermal conductivity that increases in response to application of a magnetic field, a second thermal switch with a second magnetothermal material having a second thermal conductivity that decreases in response to application of the magnetic field, a third thermal switch with a third magnetothermal material having a third thermal conductivity that increases in response to application of the magnetic field, a fourth thermal switch with a fourth magnetothermal material having a fourth thermal conductivity that decreases in response to application of the magnetic field, a first mass of a first magnetocaloric material having a first end face thermally coupled to the first thermal switch and a second end face thermally coupled to the second thermal switch, a second mass of a second magnetocaloric material having a third end face thermally coupled to the third thermal switch and a fourth end face thermally coupled to the fourth thermal switch, and a thermal reservoir thermally coupled to both the second thermal switch and the third thermal switch.

In another embodiment of the multi-stage ADR device, the device may further include a magnetic field generator configured to selectively generate the magnetic field that is magnetically coupled to each of the first thermal switch, the second thermal switch, the third thermal switch, the fourth thermal switch, the first mass of the first magnetocaloric material, and the second mass of the second magnetocaloric material.

In another embodiment of the multi-stage ADR device, the device may further include the controller operatively coupled to the magnetic field generator and configured to cycle the magnetic field generated by the magnetic field generator between the minimum magnetic field strength and the maximum magnetic field strength.

In another embodiment of the multi-stage ADR device, the device may further include a first magnetic field generator and a second magnetic field generator. The first magnetic field generator may be configured to selectively generate a first magnetic field that is magnetically coupled to the first thermal switch, the second thermal switch, and the first mass of the first magnetocaloric material. The second magnetic field generator may be configured to selectively generate a second magnetic field that is magnetically coupled to the third thermal switch, the fourth thermal switch, and the second mass of the second magnetocaloric material.

In another embodiment of the multi-stage ADR device, the device may further include a controller operatively coupled to the first magnetic field generator and the second magnetic field generator. The controller may be configured to cycle each of the first magnetic field and the second magnetic field between respective first and second minimum magnetic field strengths and respective first and second maximum magnetic field strengths.

In another embodiment of the multi-stage ADR device, the first magnetocaloric material may comprise gadolinium iron garnet, and the second magnetocaloric material may comprise ferric ammonium alum.

In another aspect of the invention, a method of controlling heat flow is provided. The method includes providing the magnetothermal element that includes the first end face and the second end face, and that is made of the magnetothermal material that is inherently or is inducible by a magnetic field into being a Weyl semimetal. The method further includes thermally coupling the first thermal terminal to the first end face of the magnetothermal element, and thermally coupling the second thermal terminal to the second end face of the magnetothermal element.

In an embodiment of the method of controlling heat flow, the method may further include inducing the magnetothermal material into being the Weyl semimetal by applying the magnetic field.

In another embodiment of the method of controlling heat flow, the magnetothermal material may be the bismuth-antimony alloy (Bi₁₋ₓSbₓ) including the first crystallographic axis and the second crystallographic axis, the magnetothermal material may be the thermal insulator without the magnetic field or in magnetic fields oriented along the second crystallographic axis, and may become the magnetic field-induced Weyl semimetal when the magnetic field is oriented along the first crystallographic axis. In this embodiment, the first crystallographic axis may be the (001) axis of the magnetothermal material, and the second crystallographic axis may be one of the (100) axis or the (010) axis of the magnetothermal material.

In another embodiment of the method of controlling heat flow, the method may further include sectioning the magnetothermal material into the plurality of sections, and forming the laminate from the plurality of sections.

In another embodiment of the method of controlling heat flow, each section of the plurality of sections may have the length dimension and the lateral dimension less than the length dimension, and the method may further include orienting each section of the plurality of sections so that the length dimension is orthogonal to one or both of the first end face and the second end face.

In another embodiment of the method of controlling heat flow, the method may further include spacing the first end face and the second end face of the magnetothermal element in the longitudinal dimension, and configuring the magnetothermal element so that paired Weyl points in the magnetothermal material are spaced along a line parallel to the longitudinal dimension.

In another aspect of the invention, a method of refrigeration is provided. The method includes cyclically applying a magnetic field to, and removing the magnetic field from, each of a first thermal switch thermally coupled to a heat sink, a second thermal switch thermally coupled to a thermal load, and a mass of magnetocaloric material thermally coupled to each of the first thermal switch and the second thermal switch. The first thermal switch includes a first magnetothermal material having a first thermal conductivity that increases in response to application of the magnetic field, and the second thermal switch includes a second magnetothermal material having a second thermal conductivity that decreases in response to application of the magnetic field.

In another embodiment of the method of refrigeration, the method may further include cycling the magnetic field between the minimum magnetic field strength and the maximum magnetic field strength.

In an embodiment of the method of refrigeration, the first magnetothermal material may inherently be a Weyl semimetal, or may be induced by the magnetic field into being a Weyl semimetal.

In another embodiment of the method of refrigeration, one or both of a magnetic sweep profile and the rate of magnetization transition may be configured to optimize the performance parameter of the ADR.

In another embodiment of the method of refrigeration, the second magnetothermal material may be a topological insulator, a semimetal, or an intrinsic semiconductor.

In another aspect of the invention, yet another method of refrigeration is provided. The method of refrigeration includes cyclically applying a magnetic field to, and removing the magnetic field from a first thermal switch, a second thermal switch, a third thermal switch, a fourth thermal switch, a first mass of a first magnetocaloric material, and a second mass of magnetocaloric material. The first thermal switch is thermally coupled to a heat sink, the second thermal switch is thermally coupled to a thermal reservoir, the third thermal switch is thermally coupled to the thermal reservoir, and the fourth thermal switch is thermally coupled to a thermal load. The first mass of the first magnetocaloric material is thermally coupled to each of the first thermal switch and the second thermal switch, and the second mass of the second magnetocaloric material is thermally coupled to each of the third thermal switch and the fourth thermal switch. The first thermal switch includes a first magnetothermal material having a first thermal conductivity that increases in response to application of a first magnetic field, the second thermal switch includes a second magnetothermal material having a second thermal conductivity that decreases in response to application of the first magnetic field, the third thermal switch includes a third magnetothermal material having a third thermal conductivity that increases in response to application of a second magnetic field, and the fourth thermal switch includes a fourth magnetothermal material having a fourth thermal conductivity that decreases in response to application of the second magnetic field.

In another embodiment of the method of refrigeration, the first magnetocaloric material may comprise gadolinium iron garnet, and the second magnetocaloric material may comprise ferric ammonium alum.

In another aspect of the invention, another method of refrigeration is provided. The method includes cyclically applying a first magnetic field to and removing the first magnetic field from a first thermal switch thermally coupled to a heat sink, a second thermal switch thermally coupled to a thermal reservoir, and a first mass of a first magnetocaloric material thermally coupled to each of the first thermal switch and the second thermal switch. The method further includes cyclically applying a second magnetic field to and removing the second magnetic field from a third thermal switch thermally coupled to the thermal reservoir, a fourth thermal switch thermally coupled to a thermal load, and a second mass of a second magnetocaloric material thermally coupled to each of the third thermal switch and the fourth thermal switch. The first thermal switch includes a first magnetothermal material having a first thermal conductivity that increases in response to application of the first magnetic field, the second thermal switch includes a second magnetothermal material having a second thermal conductivity that decreases in response to application of the first magnetic field, the third thermal switch includes a third magnetothermal material having a third thermal conductivity that increases in response to application of the second magnetic field, and the fourth thermal switch includes a fourth magnetothermal material having a fourth thermal conductivity that decreases in response to application of the second magnetic field.

In an embodiment of the method of refrigeration, the method may further include cycling each of the first magnetic field and the second magnetic field between respective first and second minimum magnetic field strengths and respective first and second maximum magnetic field strengths.

In another embodiment of the method of refrigeration, the first magnetocaloric material may comprise gadolinium iron garnet, and the second magnetocaloric material may comprise ferric ammonium alum.

The above summary presents a simplified overview of some embodiments of the invention to provide a basic understanding of certain aspects of the invention discussed herein. The summary is not intended to provide an extensive overview of the invention, nor is it intended to identify any key or critical elements, or delineate the scope of the invention. The sole purpose of the summary is merely to present some concepts in a simplified form as an introduction to the detailed description presented below.

### BRIEF DESCRIPTION OF THE DRAWINGS

The accompanying drawings, which are incorporated in and constitute a part of this specification, illustrate various embodiments of the invention and, together with the general description of the invention given above, and the detailed description of the embodiments given below, serve to explain the embodiments of the invention.

FIG. 1 is a diagrammatic view illustrating an ADR cycle.

FIG. 2 is a schematic view illustrating an ADR stage for implementing the ADR cycle of FIG. 1 that includes thermal switches each having a magnetothermal element.

FIGS. 3-6 are diagrammatic views of several exemplary configurations for the magnetothermal elements of the thermal switches of FIG. 2.

FIG. 7 is a graphical view illustrating a relationship between temperature and entropy for the ADR cycle of FIG. 1.

FIGS. 8 and 9 are schematic views of ADR devices including the ADR stages of FIG. 2.

FIG. 10 is a graphical view illustrating a phase diagram for a magnetothermal material that may be used in the thermal switches of FIGS. 2, 8, and 9.

FIG. 11 is a diagrammatic view illustrating a thermal chiral anomaly that may be present in the magnetothermal material of FIG. 10.

FIGS. 12 and 13 are graphical views illustrating thermal conductivity verses magnetic field strength of a magnetothermal material for different temperatures.

FIG. 14 is a graphical view illustrating the temperature dependence of the slope of the ratio of the rate of change in thermal conductivity to the rate of change in magnetic field of a magnetothermal material in the chiral anomaly regime.

FIG. 15 is a graphical view of thermal conductivity along the trigonal direction of a cross-section of a sample of bismuth.

FIGS. 16-23 are graphical views illustrating changes in the properties of Bi₁₋ₓSbₓ alloys in response to changes in composition and magnetic field strength.

FIGS. 24 and 25 are diagrammatic views illustrating Brillouin zones and Fermi surfaces of Bi₁₋ₓSbₓ alloys.

FIGS. 26-28 are graphical views illustrating electronic and thermal properties of Bi₈₉Sb₁₁ and Bi₈₅Sb₁₅ versus temperature.

FIGS. 29-32 are graphical views illustrating a dependence of magnetothermal conductivity on magnetic fields at various temperatures for Bi₉₅Sb₅, Bi₈₉Sb₁₁, and Bi₈₅Sb₁₅.

FIG. 33 is a graphical view illustrating the magnetothermal conductivity and magnetoresistance of a Bi₈₉Sb₁₁ sample.

FIG. 34 is a graphical view illustrating the product of magnetothremal conductivity and magnetoresistance as a function of the magnetic field for the sample of FIG. 33.

FIG. 35 is a graphical view illustrating that the inter-Weyl point scattering time fits Arrhenius plots at T>60 K and various activation energies for Bi₈₉Sb₁₁ and Bi₈₅Sb₁₅.

FIG. 36 is a graphical view illustrating the dependence of band-edge energy on the concentration of antimony in samples of Bi₁₋ₓSbₓ.

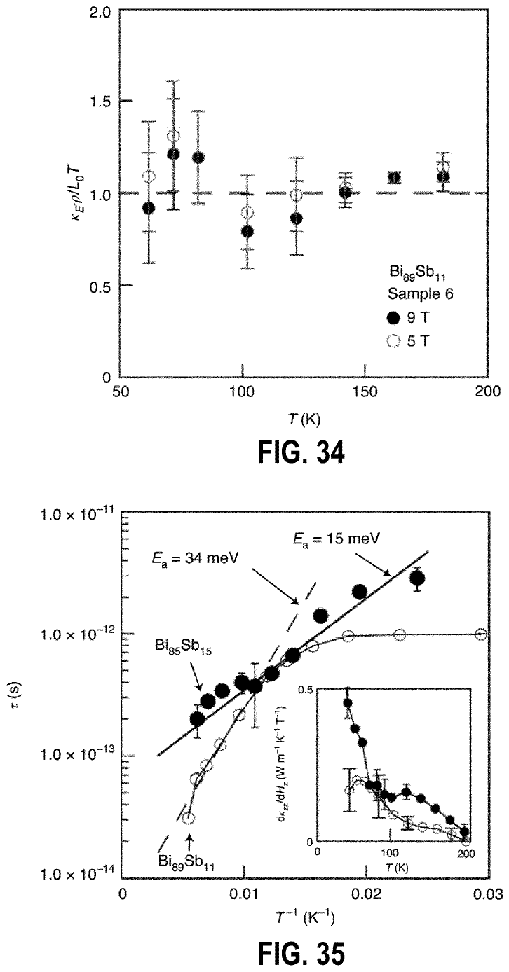

FIG. 37 is a graphical view illustrating Weyl points centered around L-points of a Brillouin zone.

FIG. 38 is a graphical view illustrating electron concentration versus temperature and band-edge energy versus magnetic field for an alloy of Bi₁₋ₓSbₓ.

FIG. 39 is a diagrammatic view illustrating Brillouin zones and Fermi surfaces of Bi₁₋ₓSbₓ alloys, and includes a reference frame comprising reciprocal lattice vectors G=(G₁, G₂, G₃) along Γ-L lines.

FIG. 40 is a graphical view illustrating solid and liquid phases of bismuth-antimony alloys versus temperature.

FIG. 41 is a graphical view illustrating an X-ray diffraction spectrum of a travelling molten zone crystal of Bi₈₉Sb₁₁.

FIG. 42 is a pictorial view illustrating the crystal of Bi₈₉Sb₁₁ used to generate the X-ray diffraction spectrum of FIG. 41.

FIGS. 43 and 44 are pictorial views of measurement set ups for measuring isothermal resistivity, magnetoresistance, and Hall effects in magnetothermal materials.

FIG. 45 is a graphical view illustrating resistivity, carrier concentration, and carrier mobility versus temperature for a travelling molten zone in samples of Bi₈₉Sb₁₁.

FIG. 46 is a graphical view illustrating the longitudinal magnetoresistance of a Bi₈₈Sb₁₂ crystal sample.

FIG. 47 is a graphical view illustrating resistivity versus magnetic field of a magnetothermal material at various temperatures.

FIG. 48 is a graphical view illustrating magnetoresistance versus magnetic field for Bi₈₉Sb₁₁ at various temperatures.

FIG. 49 is a graphical view illustrating thermal conductivity versus temperature for Bi₈₅Sb₁₅ and Bi₈₅Sb₁₂.

FIG. 50 is a graphical view illustrating magnetothermal conductivity versus magnetic field for samples of Bi₈₅Sb₁₂ at various temperatures.

FIG. 51 is a graphical view illustrating a length dependence of the slope of the magnetothermal conductivity of a sample of Bi₈₉Sb₁₁.

FIG. 52 is a graphical view illustrating the trigonal thermal conductivity of samples of Bi₈₉Sb₁₁ and Bi₈₅Sb₁₅ in a transverse magnetic field.

FIG. 53 is a graphical view illustrating the thermal conductivity of a sample of Bi₈₈Sb₁₂ as a function of temperature and the orientation of the magnetic field.

FIG. 54 is a graphical view illustrating the thermal conductivity of Bi₉₅Sb₅ along the trigonal direction.

FIG. 55 is a graphical view illustrating the Lorenz ratio for a sample of Bi₈₉Sb₁₁ while subjected to a magnetic field of six Tesla.

### DETAILED DESCRIPTION

Embodiments of the invention are directed to milli-Kelvin cooling systems that use the ADR cycle. These cooling systems may be used, for example, in cryogenic research environments and for quantum computing applications. The ADR stage of the cooling system includes two or more magnetic field-activated solid-state thermal switches. These switches may be controlled by the same magnetic field which is used to selectively magnetize the magnetocaloric material during the ADR cycle. One thermal switch may be based on the thermal chiral anomaly found in Weyl semimetals, also referred to as the gravitational anomaly. The other thermal switch may be based on magnetoresistance in topological insulators. This unique configuration allows the ADR stage to be operated at a frequency that is only limited by the cycling time of the magnetic field. This ability to operate at high frequencies enables the ADR stage to provide increased cooling power as compared to known ADR based cooling systems.

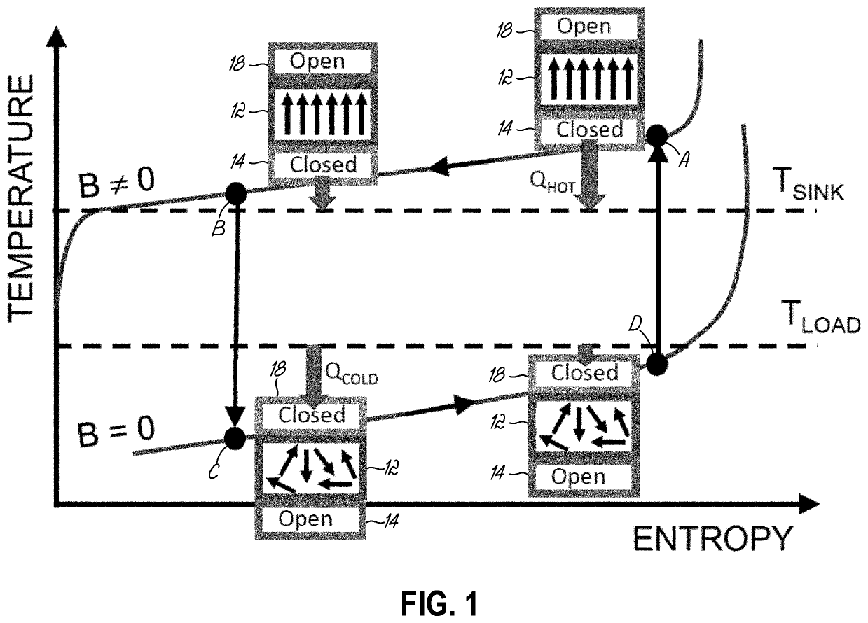

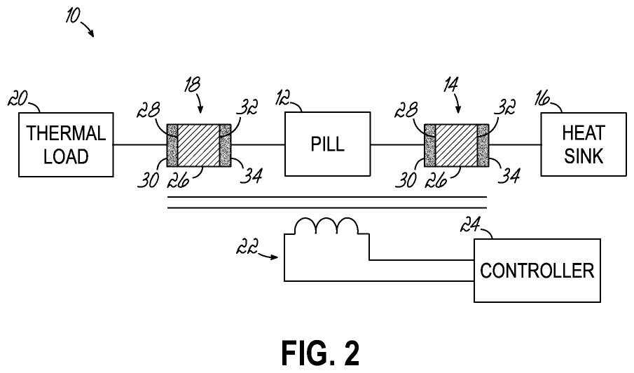

FIG. 1 depicts an exemplary ADR cycle, and FIG. 2 depicts an exemplary ADR stage 10 that may be used to implement the ADR cycle of FIG. 1. The ADR stage 10 includes an encapsulated mass of magnetocaloric material 12 (commonly referred to as a “pill”), a hot-side thermal switch 14 that selectively thermally couples the pill 12 to a heat sink 16 (e.g., a liquid helium reservoir), a cold-side thermal switch 18 that selectively thermally couples the pill 12 to a thermal load 20 (e.g., a cold tip), a magnetic field generator 22 (e.g., an electromagnet), and a controller 24 configured to selectively control the output of the magnetic field generator 22. The magnetic field generator 22 may be configured to selectively provide a magnetic field of varying strength (e.g., 0-2 Tesla) to the pill 12, hot-side thermal switch 14, and cold-side thermal switch 18 in response to signals from the controller 24.

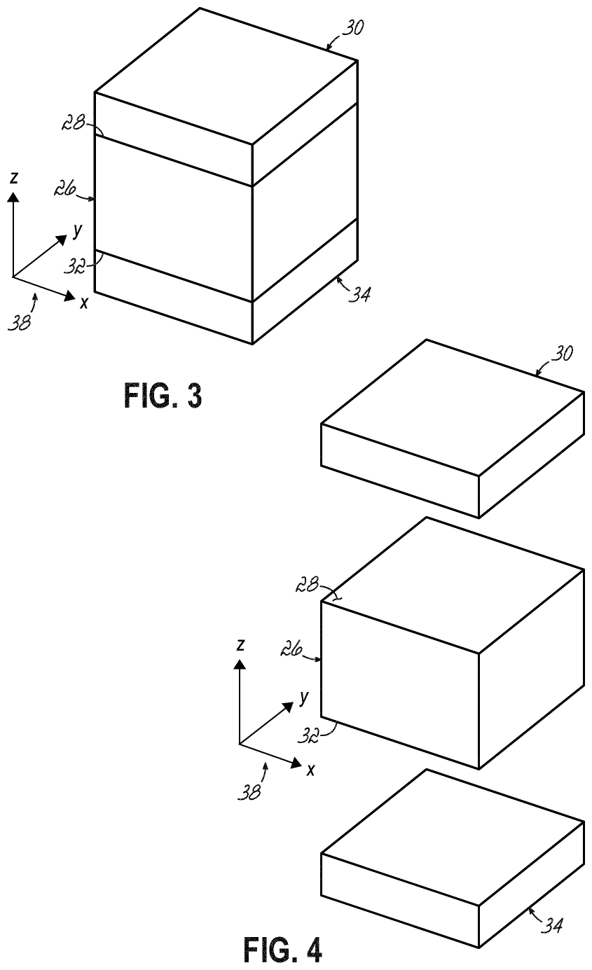

Referring now to FIGS. 3-6, and with continued reference to FIGS. 1 and 2, each thermal switch 14, 18 includes a magnetothermal element 26 having one end face 28 thermally coupled to one thermal terminal 30, and another end face 32 thermally coupled to another thermal terminal 34. The magnetothermal element 26 may be formed from a magnetothermal material comprising a Weyl semimetal, a topological insulator, or a material that can be induced into being either a Weyl semimetal or topological insulator by selective application of a magnetic field. The magnetothermal element 26 may have thermal conductivity that increases with the magnetic field generated by the magnetic field generator 22, or that decreases with the magnetic field generated by the magnetic field generator 22 depending on the type of thermal switch 14, 18 in which it is used.

As depicted in FIGS. 5 and 6, the magnetothermal element 26 may be a laminated element comprising a plurality of sections 36 (e.g., strips or layers) of the magnetothermal material. The sections may be oriented so that their length dimension (e.g., dimension parallel to the z-axis of coordinate system 38) is oriented orthogonal to the end faces 28, 32 of the magnetothermal element 26. The reduced lateral dimension or dimensions (e.g., dimensions in the x- and/or y-axes of coordinate system 38) of the sections 36 as compared to the non-laminated or “monolithic” magnetothermal element 26 depicted in FIGS. 3 and 4 may reduce phonon conduction. This reduction in phonon conduction may reduce the lattice thermal conductivity κ_{L} as compared to the monolithic magnetothermal element 26. As described in more detail below, lowering the lattice thermal conductivity κ_{L} may improve the performance of the thermal switches 14, 18.

At point A of the ADR cycle in FIG. 1, the hot-side thermal switch 14 is closed (i.e., in a low thermal resistance or “on-state”), thermally coupling the pill 12 to the heat sink 16, and the cold-side thermal switch 18 is open (i.e., in a high thermal resistance or “off-state”), thermally decoupling the pill 12 from the thermal load 20. The pill 12 is subjected to a high magnetic field and is in a high-entropy state, which has been arbitrarily chosen as the point at which to begin the description of the ADR cycle. The ADR cycle is designed such that the temperature of the pill 12 reached at point A is above the temperature T_{HS} of the heat sink 16. For example, this temperature T_{HS} may be ~1.8K, which is a temperature that can be achieved by a commercially available He⁴ cryostat. During the process that brings the system from point A to point B in the ADR cycle, the hot-side thermal switch 14 remains closed, bringing the pill 12 in thermal contact with the heat sink 16. This enables the conduction of heat from the pill 12 to the heat sink 16 as indicated by the large single-headed arrows in FIG. 1. The process follows the temperature-entropy curve of the magnetized pill 12, the line marked B≠0 in FIG. 1, thereby lowering the entropy in the pill 12. At point B in the cycle, when the pill 12 is in its low-entropy high-magnetic field state, the magnetic field is removed.

In response to the removal of the magnetic field, the hot-side thermal switch 14 is progressively switched to the open state and the thermal switch 18 is progressively switched to the closed state. At the same time, the pill 12 undergoes a transformation from point B to point C of the cycle. The removal of the magnetic field allows the magnetic moments in the pill 12 to lose their alignment (as indicated by the small single-headed arrows in point C), which increases the entropy-carrying capacity of the pill 12. Because the total energy is constant, the pill 12 cools down to a temperature that by design is below the temperature T_{TL} of the thermal load 20.

In response to the temperature of the pill 12 approaching or reaching the temperature T_{HS} of the heat sink 16 at point B of the ADR cycle, the magnetic field is reduced and the hot side thermal switch 14 switches to the open state (i.e., turns off), thermally isolating the pill 12 so the total entropy remains relatively constant. The removal of the magnetic field allows the magnetic moments to move, which absorbs some of the remaining thermal energy in the pill 12, thereby cooling the pill 12 to a temperature below the desired sub-K temperature T_{TL}.

At point C in the cycle, the hot-side thermal switch 14 is open, isolating the pill 12 thermally from the heat sink 16, and the cold-side thermal switch 18 is closed, bringing the pill 12 in thermal contact with the thermal load 20. The pill 12 now absorbs heat from the thermal load 20 as indicated by the large single-headed arrows in FIG. 1. This increases the temperature of the pill 12, following the process that brings the pill 12 from point C to point D in the cycle. At point D in the cycle, when the pill 12 is in its high-entropy zero magnetic field state, the magnetic field is reapplied.

In response to the application of the magnetic field, the hot-side thermal switch 14 is progressively switched to the closed state and the thermal switch 18 is progressively switched to the open state. At the same time, the pill 12 undergoes a transformation from point D to point A of the cycle. The magnetic field is applied to the pill 12 causes the magnetic moments in the pill 12 to align (as indicated by the small single-headed arrows). This alignment of magnetic dipoles causes the magnetic entropy of the pill 12 to decrease. Because the cycle is designed in such a way that the entropy remains constant during the application of the magnetic field (process D to A in FIG. 1) while the total energy also remains constant, the temperature of the pill 12 increases to offset the changes in magnetic entropy caused by the application of the magnetic field. The temperature reached at the of this process is the temperature at point A. The ADR cycle can then be repeated.

The performance of thermal switches may be characterized by their switching ratio SR, which is provided by,

$$S R ≡ \frac{{K}_{O N}}{{K}_{O F F}} \qquad Eqn . 1$$

where K_{ON} is the thermal conductance of the switch in its on-state and K_{OFF} is the thermal conductance of the switch in its off-state.

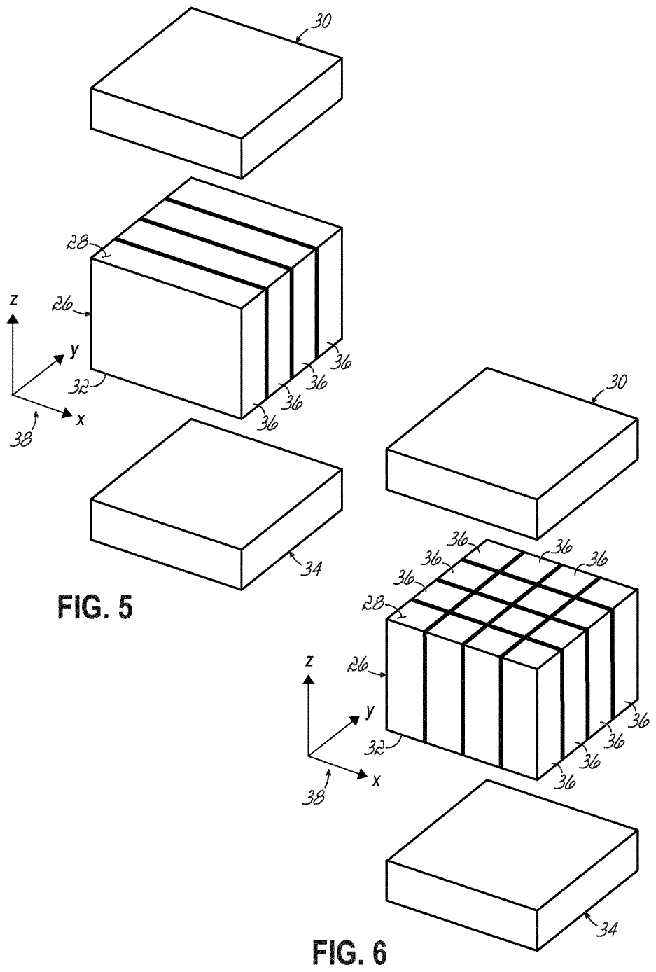

FIG. 7 depicts a graph of temperature versus entropy (normalized to the gas constant R), commonly referred to as a temperature-entropy (T-s) diagram. The depicted T-s diagram illustrates changes to temperature and specific entropy during the ADR cycle of a magnetocaloric material known as Ferric Ammonium Alum (FAA) based on data from P. Wikus et al. [Cryogenics 51 (2011) 555-558]. The points in the graph FIG. 7 labeled as A, B, C, and D correspond to the operation of an actual cycle, and thus do not exactly correspond to the points A, B, C, and D in FIG. 1, which represents represent an “ideal” ADR cycle. In particular, in FIG. 7, the cycle is controlled in such a fashion that the magnetic field applied to the pill 12 is not at exactly zero at point C, and is brought progressively to zero in the process C to D. Furthermore, points A′ and C′ represent “non-ideal” locations on the graph corresponding to A and C in FIG. 7, and represent actual values that may be reached during the ADR cycle.

The magnetocaloric material of a pill operates between the heat sink temperature T_{HS} and the thermal load temperature T_{TL}. While in the heat release phase, the ADR cycle is between points A′ and B on the graph, and the pill 12 is thermally coupled to the heat sink 16 by a hot-side thermal switch 14 having a conductance K_{H}. In the heat absorption phase, the ADR cycle moves from point C′ to point D on the graph while the pill 12 is thermally coupled to the thermal load 20 by a cold-side thermal switch 18 having a conductance K_{C}.

The hot-side thermal switch 14 may be made from a material having a field/temperature dependent thermal conductivity κ_{H} (B,T), and the cold-side thermal switch 18 may be made from a material having a field/temperature thermal conductivity κ_{C}(B,T). Because the conductivity κ of each material depends on the strength of an applied magnetic field B and the temperature T of the material, the conductance K of each switch can be modulated by adjusting the strength of the applied magnetic field B. The hot-side thermal switch 14 may be configured with a geometric aspect ratio g_{H} and the cold-side thermal switch 18 may be configured with a geometric aspect ratio g_{C}. These aspect ratios produce a hot-side thermal switch conductance K_{H}=g_{H}×K_{H}(B,T) and a cold-side thermal switch conductance K_{C}=g_{C}×κ_{C}(B,T). The ratio of the aspect ratios g_{C}/g_{H} may be used as a design parameter for the ADR stage. K_{H_ON} and K_{C_ON} represent the conductance of the hot-side and cold-side thermal switches 14, 18 in their on-states, and K_{H}_OFF and K_{C_OFF} represent the conductance of the hot-side and cold-side thermal switches 14, 18 in their off-states. The cold and hot side switch ratios SR of the conductance are provided by:

$$S {R}_{C} = \frac{{K}_{C\_ON}}{{K}_{C\_OFF}} \qquad Eqn . 2$$

$$S {R}_{H} = \frac{{K}_{H\_ON}}{{K}_{H\_OFF}} \qquad Eqn . 3$$

The ideal cycle in the magnetocaloric material is A-B-C-D. However, due to irreversible losses (such as the heat conducted back through the switches while they are in the off-state), position C is located at an entropy level less than or equal to C′, and position A is located at an entropy level less than or equal to A′. The ideal magnetic cooling capacity per cycle Q_{M} is dictated by the heat absorption capacity of the magnetocaloric material, which is given by:

$${Q}_{M} = \int T d s = {T}_{D} ( {S}_{D} - {S}_{{C}^{′}} ) \qquad Eqn . 4$$

Where T_{D} and S_{D} are the temperature and entropy at point D of the ADR cycle, and S_{C′} is the entropy at point C′ of the ADR cycle. However, as shown below, the net cooling capacity Q_{C} is typically lower than the ideal cooling capacity Q_{M}. Due to the conductance of the thermal switches being greater than zero in their off-states, there is non-zero heat transfer between the magnetocaloric material and both the heat sink 16 (which is at T_{HS}) and the thermal load 20 (which is at T_{TL}) at any phase during the cycle. Thus, during the heat absorption phase of the ADR cycle, the pill 12 absorbs heat from both the thermal load 20 and the heat sink 16. Because the thermal switches have a finite thermal conductance in their respective on-states (i.e., K_{C_ON}<∞ and K_{H_ON}<∞), the temperature of the pill 12 can only approach that of either the heat sink 16 or thermal load 20. Thus, the temperature of the heat sink 16 is less than the temperature of the pill 12 at point B (T_{HS}<T_{B}) and the temperature of the thermal load 20 is greater than the temperature of the pill 12 at point D (i.e., T_{TL}>T_{D}). Accordingly,

$${T}_{D} ( {S}_{D} - {S}_{{C}^{′}} ) = {Q}_{A L} + {Q}_{A S} \qquad Eqn . 5$$

where Q_{AL} is the heat extracted from the thermal load 20 by the pill 12 during the heat absorption phase, and Q_{AS} is the heat which leaks back into the pill 12 from the heat sink 16 during the heat absorption phase.

The quantities Q_{AL} and Q_{AS} are related by the ratio of the heat fluxes passing through the respective thermal switches, which is determined by the conductance of the thermal switches and the temperature differences between the pill 12 and the thermal load 20/heat sink 16. This relationship can be expressed as:

$${Q}_{A L} = {Q}_{A S} \frac{{K}_{C\_ON} ( {T}_{T L} - {T}_{D} )}{{K}_{H\_OFF} ( {T}_{H S} - {T}_{D} )} \qquad Eqn . 6$$

Equivalent equations can be derived for the heat release phase of the ADR cycle based on the heat flowing from the pill 12 into each of the heat sink 16 and thermal load 20. The heat released by the pill 12 is equal to the entropy lost from the pill 12, and is equal to the sum of the heat flow Q_{DS} from the pill 12 into the heat sink 16 and the heat flow Q_{DL} from the pill 12 into the thermal load 20. This relationship is shown by:

$${T}_{B} ( {S}_{{A}^{′}} - {S}_{B} ) = {Q}_{D L} + {Q}_{D S} \qquad Eqn . 7$$

$${Q}_{D L} = {Q}_{D S} \frac{{K}_{C\_OFF} ( {T}_{B} - {T}_{T L} )}{{K}_{H\_ON} ( {T}_{B} - {T}_{H S} )} \qquad Eqn . 6$$

Accounting for both the heat released by and absorbed by the pill 12, the net cooling capacity seen by the thermal load 20 per cycle is given by:

$${Q}_{C} = {Q}_{AL} - {Q}_{DL} = \frac{{T}_{D} ( {S}_{D} - {S}_{{C}^{′}} )}{1 + \frac{{K}_{H \_ OFF} ( {T}_{HS} - {T}_{D} )}{{K}_{C \_ ON} ( {T}_{TL} - {T}_{D} )}} - \frac{{T}_{B} ( {S}_{{A}^{′}} - {S}_{B} )}{1 + \frac{{K}_{H \_ ON} ( {T}_{B} - {T}_{HS} )}{{K}_{C \_ OFF} ( {T}_{B} - {T}_{TL} )}} \qquad Eqn . 7$$

In order for the pill 12 to cool the thermal load 20, the heat Q_{AL} extracted from the thermal load 20 during the heat absorption phase of the ADR cycle should be greater than the heat Q_{AS} leaking back into the pill 12 from the heat sink 16. This requires the thermal conductance K_{C_ON} of the cold-side thermal switch 18 to be greater than the thermal conductance K_{H_OFF} of the hot-side thermal switch 14. Likewise, during the heat release phase of the ADR cycle, the heat flow from the magnetocaloric material into the heat sink 16 Q_{DS} should be greater than the heat flow from the magnetocaloric material into the thermal load 20 Q_{DL}. This requires the thermal conductance K_{H_ON} of the hot-side thermal switch 14 to be greater than the thermal conductance K_{C_OFF} of the cold-side thermal switch 18. Fulfilling these conditions during the heat absorption and heat release phases of the ARD cycle requires both a high switch ratio SR for the thermal switches and properly sizing the thermal switch geometries (g_{H} and g_{C}) so as to optimize a geometric parameter Z defined as:

$$Z ≡ \frac{{K}_{C \_ OFF}}{{K}_{H \_ OFF}} \qquad Eqn . 8$$

Equation 7 sets functional requirements for the thermal switches and suggests cooling strategies to maximize the net cooling capacity Q_{C} of the ADR stage. One desirable design parameter of the ADR cycle is smaller temperature deltas between T_{B}-T_{D} and T_{H}-T_{C}. This may be achieved by dividing the cooling operation into multiple ADR stages.

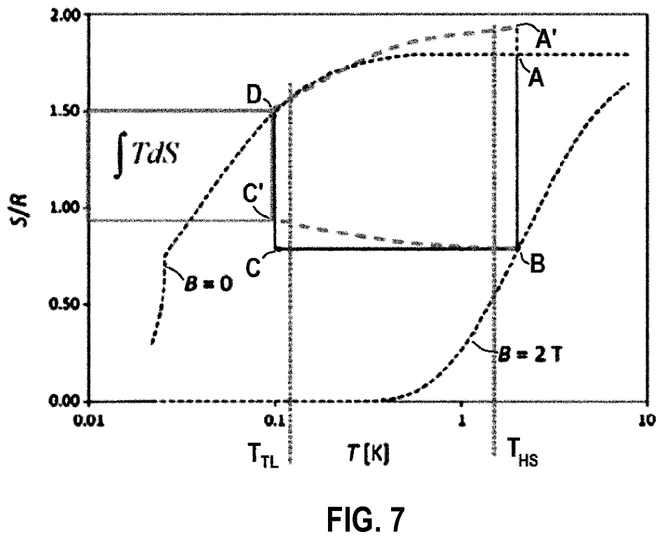

FIGS. 8 and 9 depict exemplary multi-stage ADR devices 40 including hot and cold-side ADR stages 10 thermally coupled through a thermal reservoir 42. The cold-side ADR stage 10 pumps heat from the thermal load 20 into the thermal reservoir 42, and the hot-side ADR stage 10 pumps heat from the thermal reservoir 42 into the heat sink 16. The ADR stages 10 may be sized relative to one another so that the thermal reservoir operates at a temperature T_{TR} that divides the temperature range T_{HS}-T_{TL} into two optimal temperature ranges T_{HS}-T_{TR} and T_{TR}-T_{TL}. Each ADR stage 10 may be optimized for the temperature range across which it operates, with the temperature ranges themselves being selected to optimize one or more performance parameters of the ADR device 40. The ADR device 40 depicted by FIG. 8 has a single magnetic field generator 22 that is magnetically coupled to both ADR stages 10. The ADR device 40 depicted by FIG. 9 has separate magnetic field generators 22 each magnetically coupled to a respective ADR stage 10 to enable independent cycling of the ADR stages 10.

Another desirable design parameter is a smaller value for the entropy S_{A′} at point A′ on the ADR cycle. This may be achieved by selection of the magnetocaloric material and optimization of the magnetic sweep profile and rate of the magnetization transition phase, which starts at point D and moves the ADR cycle to point A′. The magnetic sweep profile and rate of the magnetization transition phase during the heat release phase from point A′ to point D of the ADR cycle during which the magnetic field is maintained may also be optimized. Yet another desirable design parameter of the ADR cycle is to maximize the net cooling capacity Q_{C} as defined by Equation 7 by optimizing the geometric parameter Z. Maximizing net cooling capacity Q_{C} and meeting the conditions K_{C_ON}>>K_{H_OFF} and K_{H_ON}>>K_{C_OFF} may be facilitated by large switch ratios SR_{C}, SR_{H} in both the cold-side and hot-side switches.

Superconducting thermal switches, or topological switches, provide a baseline against which the cold-side switches disclosed herein may be evaluated. Their principle of operation is based on the fact that Cooper pairs in superconductors do not conduct heat, while electrons in the normal state do. In metals in their normal state, the total thermal conductivity κ is:

$$κ = {κ}_{L} + {κ}_{E} \qquad Eqn . 9$$

where κ_{L} is the lattice thermal conductivity and κ_{E} the electronic thermal conductivity. When the metal is superconducting, κ_{E} tends to zero. A magnetic field can be used to drive the metal from superconducting to the normal state so that the thermal conductivity κ switches from an on-state κ_{ON}=κ_{L}+κ_{E} to an off-state κ_{OFF}=κ_{L}. The thermal conductivity switching ratio SR is then SR=1+κ_{E}/κ_{L}. At temperatures below about 4 K, the lattice thermal conductivity κ_{L} of bulk solids decreases with the cube of temperature (κ_{L}=αT³) whereas the electronic thermal conductivity KE decreases linearly with temperature (κ_{E}=βT). As a result, the switch ratio SR can be written as:

$$S R = 1 + ( \frac{β}{α} ) \frac{1}{{T}^{2}} \qquad Eqn . 10$$

which is a function that increases rapidly with decreasing T. Some exemplary formulas for the switching ratio of superconducting switches include:

$$\begin{matrix}Sn wires & SR = 1 + 1.5 / {T}^{2} to SR = 1 + 2 / {T}^{2} \\ In switches & SR = 1 + 0.1 / {T}^{2} \\ Zn foil & SR = 1 + 5 / {T}^{0.5}\end{matrix}$$

The switch ratio of Zn foil is less dependent on temperature due to the lattice thermal conductivity κ_{L} of Zn foil decreasing with temperature at a rate slower than the cube of temperature.

Materials exhibiting magnetoresistance change their thermal conductivity in response to the application of magnetic fields. It has been determined that at least some topological insulators exhibit decreased thermal conductivity in the presence of a magnetic field, i.e., negative magnetothermal conductivity or positive magnetothermal resistance. In contrast, it has been determined that at least some Weyl semimetals exhibit enhanced thermal conductivity in the presence of a magnetic field, i.e., positive magnetothermal conductivity or negative magnetothermal resistance. In an exemplary embodiment of the present invention, a thermal switch made from a topological insulator (or “topological insulator switch”) is used to provide the cold-side thermal switch 18, and a thermal switch made from a Weyl semimetal (or “Weyl switch”) is used to provide the hot-side thermal switch 14.

By way of example, a single-crystal Bi₁₋ₓSbₓ alloy that is a topological insulator at zero magnetic field or in magnetic fields oriented along its crystallographic (010) axis, but that turns into a magnetic field-induced Weyl semimetal when the magnetic field is oriented along its (001) axis, may be used in both the topological insulator switch and the Weyl switch. These thermal switches may have switch ratios at least as high as known thermal switches based on preliminary results showing that Weyl switches have much better switching ratios than superconducting switches. Still further, superconducting switches only exhibit positive magnetoresistance, i.e., the thermal conductivity is low when exposed to a high magnetic field strength and high when exposed to a low magnetic field strength. Advantageously, the Weyl and topological insulator switches can be used as a bipolar pair in which the topological insulator switch behaves like a superconducting switch, and the Weyl switch behaves in an opposite manner. This is due to the Weyl material exhibiting negative magnetoresistance so that the thermal conductivity is high when exposed to a high magnetic field strength and low when exposed to a low magnetic field strength. This property may enable operation of switches in pairs using the same magnetic field.

Weyl semimetals are three-dimensional topological solids, in which the band structure has “Weyl points” that come in pairs of opposite chirality, which is a symmetry property of the wavefunction of the electrons at those points. With the chemical potential at the Weyl point energy possible in the Bi₁₋Sbₓ alloys, the charge carriers at the Weyl points are neither electrons nor holes, but Weyl fermions that behave like photons. That is, they have no mass but only a group velocity and a chirality.

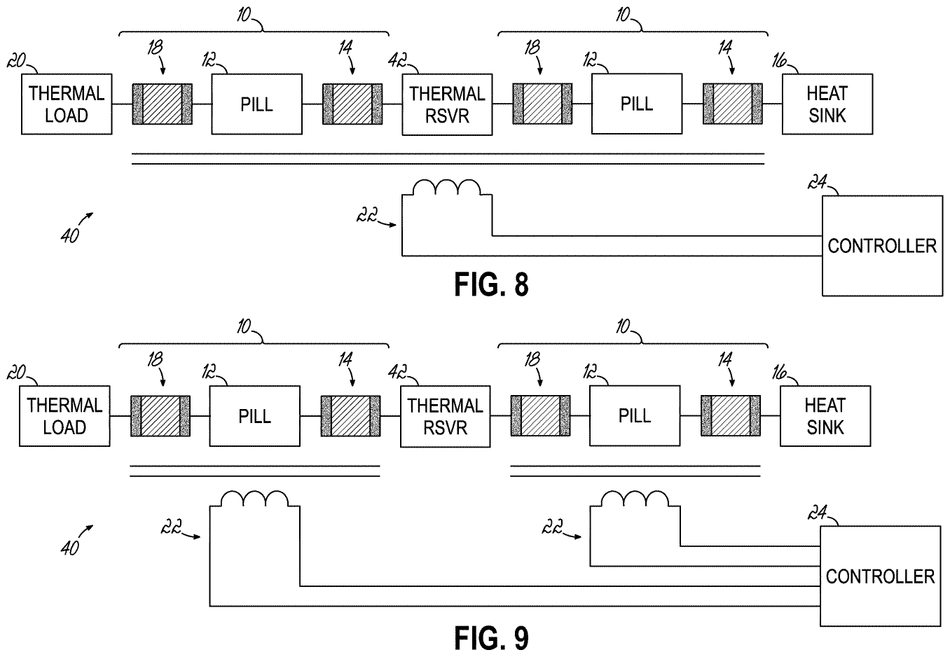

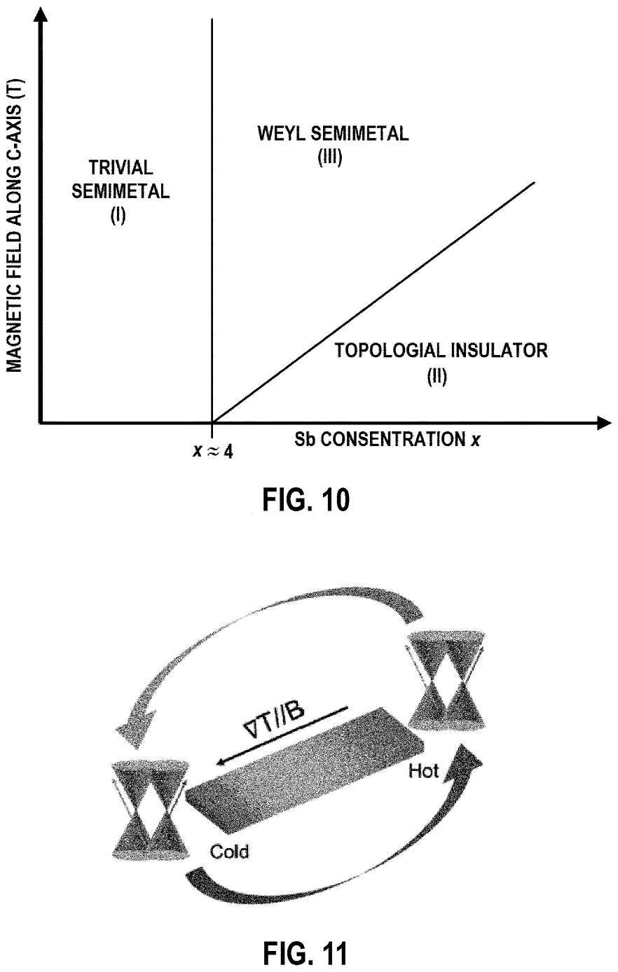

FIG. 10 depicts a phase diagram for single-crystal Bi₁₋ₓSbₓ alloys. For x<4%, Bi₁₋ₓSbₓ alloys are trivial semimetals. For x>4%, Bi₁₋ₓSbₓ alloys are topological insulators at a zero magnetic field (lower region), but become Weyl semimetals when a magnetic field is applied along the (001) direction (upper region). Weyl switches may be based on switching the material through the depicted phase transitions by controlling the magnetic field. FIG. 11 depicts the thermal chiral anomaly, which is an anomalous energy flux that is generated at one Weyl point of a pair and annihilated at the other in the presence of a temperature gradient. This thermal chiral anomaly generates an anomalous heat flux, and thus an anomalous thermal conductivity κ_{A}.

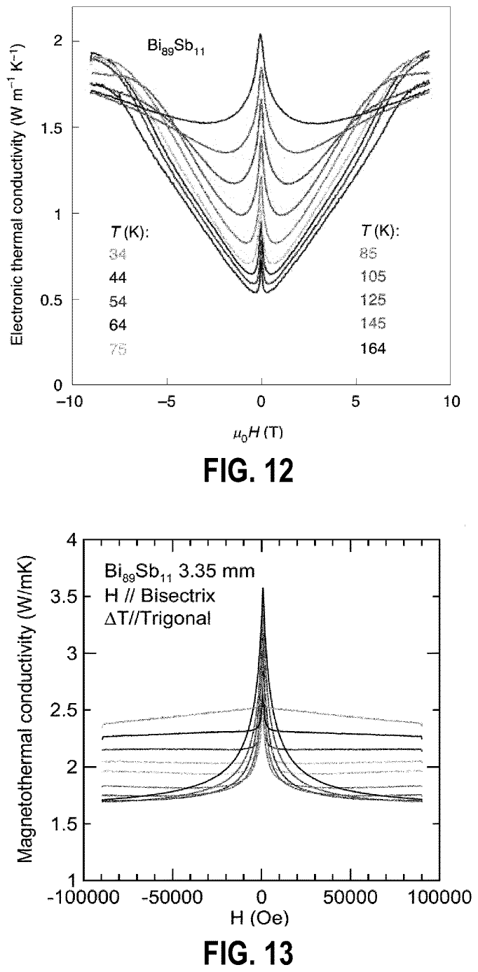

The above described thermal chiral anomaly has been shown to exist in both theory and by experimental results. Referring now to FIG. 12, in the configuration that induces the anomaly, the magnetic field B is applied along the trigonal direction (001) of Bi₁₋ₓSbₓ alloys and parallel to an applied temperature gradient ∇T. An energy flux is then generated at one Weyl point and absorbed at its conjugate, creating an anomalous heat flux proportional to ∇T×B. The anomalous thermal conductivity κ_{A} is thus a function that increases linearly with B, and is given by,

$${κ}_{A} = {N}_{w} \frac{{π}^{2}}{3} \frac{e v τ {k}_{B}^{2} T}{4 π {ℏ}^{2}} {B}_{( 001 )} \qquad Eqn . 11$$

where N_{W} is the number of Weyl point pairs in the Brillouin zone, e is the electron charge, v the Weyl fermion group velocity, k_{B} and h the Boltzmann and Planck constants, τ the inter-Weyl point scattering time, and B₍₀₀₁₎ the field along the (001) direction.

As can be seen from Equation 11, the anomalous thermal conductivity κ_{A} is a function that increases linearly with magnetic flux density B. The total thermal conductivity of the material is then:

$$κ = {κ}_{A} + {κ}_{E} + {κ}_{L} \qquad Eqn . 12$$

where κ_{E} is the ordinary electronic thermal conductivity and κ_{L} the lattice thermal conductivity.

FIGS. 12 and 13 depict the thermal conductivity of Bi₈₉Sb₁₁ verses magnetic field strength for different temperatures ranging from 34 to 164 K. The depicted curves are in good agreement with the thermal conductivity predicted by Equations 11 and 12. As described in detail below, ratios of anomalous to electronic conductivity κ_{A}/κ_{E}>300% have been shown for Weyl mode Bi₁₋ₓSbₓ at 70K. In an optimized sample, a ratio of anomalous to electronic conductivity κ_{A}/κ_{E}>500% has been shown at 40K.

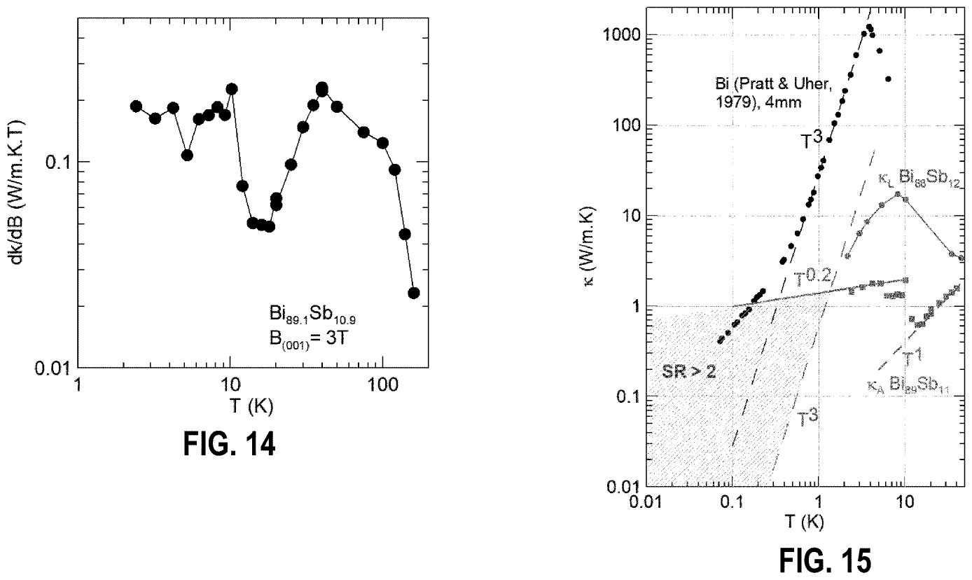

FIG. 14 depicts experimental data obtained by measuring the temperature dependence of the slope dκ_{A}/dB in the chiral anomaly regime. As can be seen, the anomalous thermal conductivity κ_{A} decreases as predicted by Equation 11 down to 15 K. Surprisingly, the anomalous thermal conductivity κ_{A} begins increasing again below 10 K to about 1.8 W/mK at 9 tesla, and remains nearly independent of temperature T below 10 K.

Because the electronic thermal conductivity KE is negligible at T<10 K in undoped samples, the switching ratio of a Weyl mode switch made from Bi₁₋ₓSbₓ is provided by:

$${SR}_{H} = \frac{( {κ}_{A} + {κ}_{L} )}{( {κ}_{E} + {κ}_{L} )} \approx 1 + \frac{{κ}_{A}}{{κ}_{L}} \qquad Eqn . 13$$

Equation 11 predicts that the conductance K_{H} of this Weyl mode switch scales as T¹. This would indicate that the switching ratio SR_{H} would be similar in magnitude to that of a superconducting switch at sub-K temperatures. However, the data plotted in FIG. 14 promises a better performance below 10 K than is predicted by Equation 11 because the anomaly does not decrease much with decreasing temperature T.

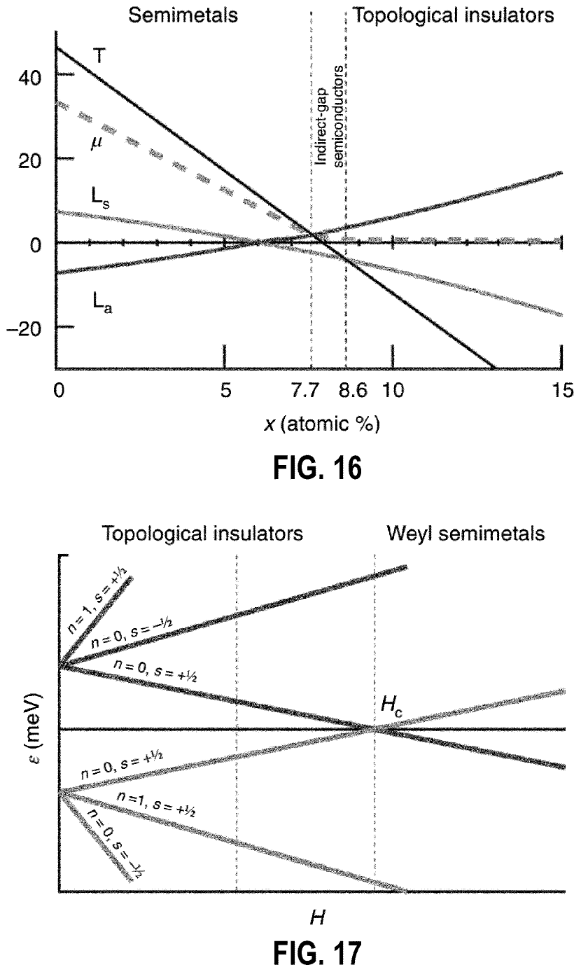

FIG. 15 depicts the thermal conductivity κ along the trigonal direction of elemental Bi, the lattice thermal conductivity κ_{L} of Bi₈₅Sb₁₂, and the anomalous thermal conductivity κ_{A} of the Bi₈₅Sb₁₂. At low temperature, the lattice thermal conductivity κ_{L} follows a T³ law, whereas the anomalous thermal conductivity κ_{A} follows a T^{0.2} law. This opens a wide temperature range where a switching ratio SR>2 can be expected. If extrapolated to 0.3 K, this suggests that SR_{H}=1+(β/α)/T^{2.8}, with β=1.5 W/m K at a magnetic field of 9 tesla. This is a more favorable outcome than provided by Equation 10 that is valid for superconducting switches. Reducing the lattice thermal conductivity κ_{L} may increase the SR_{H} of Weyl-mode Bi₁₋ₓSbₓ. FIG. 15 shows k reported along the trigonal direction of a 4×4 mm cross-section Bi sample. Bi has a free electron density of 3×10¹⁷ cm⁻³, and the electronic thermal conductivity KE follows a T¹ law that dominates total thermal conductivity κ for a temperature T<500 mK. But above that temperature, the lattice thermal conductivity κ_{L}=αT³ as indicated by its proximity to the dashed black line. FIG. 15 also shows experimental data for the lattice thermal conductivity κ_{L} of a 1 mm-wide sample of Bi₈₈Sb₁₂, which has a free electron density of 3×10¹⁵ cm⁻³ at 10 K. The dashed gray line is an extrapolation using a T³ law for the lattice thermal conductivity κ_{L}. Taking that extrapolation at face value predicts an SR_{H}=1+2.5/T^{2.8}, which produces a switch ratio SR_{H}>2 in the hatched region of FIG. 15.

Further improvements may be possible in view of two properties of Bi₁₋ₓSbₓ. The first property is that the lattice thermal conductivity κ_{L} of Bi₁₋ₓSbₓ is much lower than for pure Bi due to alloy scattering of the phonons. The second property is that for T<4 K, the lattice thermal conductivity κ_{L} enters the Casimir regime where it is limited by boundary scattering of phonons. The value of x=11% may maximize the anomalous thermal conductivity κ_{A} and also reduces the lattice thermal conductivity κ_{L} as compared to lower values of x. Further optimization of x may yield improvements lattice thermal conductivity κ_{L}. However, these improvements may be at the expense of adversely affecting the anomalous thermal conductivity κ_{A}.

Operation in the Casimir regime indicates that decreasing the size of the Bi₁₋ₓSbₓ sample may provide further improvements in performance. The plotted experimental data was obtained using a sample with a 2 mm cross-section. Cutting such samples into platelets 200 μm thick and gluing 10 platelets together may reduce the lattice conductivity κ_{L} by an order of magnitude at 1 K, which could potentially improve the switching ratio to SR_{H}=1+25/T^{2.8}.

Referring again to FIG. 10, and as noted previously, Bi₁₋ₓSbₓ alloys with x>4% are in the topological insulator region (II) when the magnetic field B has a magnitude of zero or is applied along crystallographic directions other than (001). Referring again to FIG. 13, and with continued reference to FIG. 10, when Bi₁₋ₓSbₓ is in the topological insulator region, the anomalous thermal conductivity κ_{A}=0 and the electronic thermal conductivity κ_{E} is a function that decreases with the cube of the magnetic field B². This is because Bi₁₋ₓSbₓ has a very strong magnetoresistance in the topological region and the Wiedemann-Franz law applies. Thus,

$$S {R}_{C} = 1 + \frac{{κ}_{E}}{{κ}_{L}} = 1 + \frac{β}{α {T}^{2}} \qquad Eqn . 14$$

Nano-structuring can further reduce the lattice thermal conductivity. See Heremans, J. P., Dresselhaus, M. S., Bell, L., and Morelli, D. T., “When Thermoelectrics Reached the Nanoscale,” Nature Nanotechnology 8, 471-473 (2013). For switches that use single crystal materials, it may be impossible to nano-structure the grains of the materials. However, nanoparticles may be randomly added in the crystal. Topological protection may also protect the carriers at the Weyl points from scattering on charge neutral defects. Thus, adding charge-neutral nanoparticles (e.g., silica powder) to the magnetothermal material may reduce its lattice thermal conductivity without affecting its electronic or anomalous thermal conductivity. Following Equation 14, this reduction in lattice thermal conductivity may increase the SR_{C}. To be effective, the nanoparticles size may need to be on the order of the phonon mean free path, which below 10 K is of the order of a millimeter in high-quality semiconductors and semimetals. Therefore, particles having diameters of 10 nm-100 μm may be suitable for this purpose. Scattering of phonons on neutral impurities tends to increase linearly with the concentration of the particles. But since the conductivity of the particles does not switch with magnetic field, too high a particle concentration may be detrimental to the SR_{C}. It may be desirable to avoid the percolation threshold for thermal conduction by the particles themselves (30% by volume in a three-dimensional composite). Accordingly, the optimum concentration may be in the range of 1% to 30% by volume.

A trivial semimetal (such as a Bi₁₋ₓSb alloy in the trivial semimetal region) may work for this switch, but because the Sb content is low in those samples, the lattice thermal conductivity κ_{L} is relatively large. Accordingly, better performance may be expected by operating in the topological region with x≈12%, so that the lattice thermal conductivity κ_{L} is that depicted in FIG. 15. Bi₁₋ₓSbₓ may be doped heavily n-type with tellurium (Te) to increase the coefficient β in Equation 14. A resistivity of 1.05 10⁻⁹ Ωm can be obtained in elemental Bi at 4.2 K by doping the material n-type to n=4×10¹⁹ cm⁻³. Using the Wiedemann-Franz law at 1 K, this would produce an electronic thermal conductivity κ_{E}=23 W/mK. Because the mobility of Bi₈₉Sb₁₁ is smaller than that of elemental Bi by about a factor of 5, the electronic thermal conductivity κ_{E} may be reduced by an order of magnitude to κ_{E}=5 W/mK. This result may agree with theory because in both cases, ionized impurity scattering dominates over alloy scattering.

Using an electronic thermal conductivity κ_{E}=5 W/mK and a lattice thermal conductivity κ_{L}=0.5 W/mK at 1 K, a switch ratio of SR_{C}=1+10/T² is expected in the topological insulator mode. Advantageously, this indicates that topological insulator mode thermal switches outperform superconducting switches by an order of magnitude. The decrease in electron mobility due to ionized impurity scattering may require a higher magnetic field to generate enough magnetoresistance than in pure Bi, but this can be further compensated by shaping the samples so as to maximize the geometric magnetoresistance. Size effects may also be used to reduce the lattice thermal conductivity κ_{L}.

As noted above, using multiple ADR stages in series may provide further performance benefits. A multi-stage ADR device may operate by turning one or more external sources of magnetic fields on and off and incorporating optimized switches in each ADR stage as determined using the above analysis. Assuming that the ADR cycle is rectangular (i.e., S_{A′}~S_{B}≈S_{D}-S_{C′}), Equations 7 and 8 produce a cooling capacity Q_{C} in Joules per cycle of:

$${Q}_{C} = ( {S}_{D} - {S}_{{C}^{′}} ) [ \frac{{T}_{D}}{( 1 + \frac{1}{Z \times S {R}_{C}} ( \frac{{T}_{HS} - {T}_{D}}{{T}_{TL} - {T}_{D}} ) )} - \frac{{T}_{B}}{( 1 + \frac{S {R}_{H}}{Z} ( \frac{{T}_{B} - {T}_{HS}}{{T}_{B} - {T}_{TL}} ) )} ] \qquad Eqn . 15$$

For a magnetic field B of 9 tesla in a Physical Property Measurement System (PPMS) from Quantum Design of San Diego, California, the field charge rate is 15 minutes per cycle to 9 tesla. The cooling power of this instrument is then,

$${P}_{C} = \frac{{Q}_{C}}{450} W \qquad Eqn . 16$$

By operating the magnet cyclically to only produce a magnetic field B=3 tesla (which may be sufficient to activate the cold-side switch and cycle a pill 12 using gadolinium iron garnet as the magnetocaloric material), this cooling power can be multiplied by a factor of three. Optimization of the thermal switch designs, optimizing Z in Eq. 15, optimizing the magnetic field value and ramping rate, and minimizing thermal contact resistance between the magnetocaloric material and the thermal switches may provide further improvements in performance.

In an exemplary embodiment, the hot-side ADR stage 10 may cover a temperature range of between 300 mK to 1.0 K using commercial gadolinium iron garnet (GdIG) for which (S_{D}-S_{C′})≈2 J/K/mole GdIG at 300 mK for a magnetic field B in the paramagnetic state that is greater than 2 tesla. With T_{TL}=400 mK, T_{D}=300 mK, T_{HS}=1 K and T_{B}=1.1 K, and a fixed SR_{H}, Equation 15 may be numerically optimized for Z and SR_{C}. For example, for SR_{H}=3.5, which is nearly achieved with the Weyl samples described below, the optimum Z=0.04 and the optimum SR_{C}=200. Using the above equations to calculate the cold-side switch ratio SR_{C} for these parameters produces a value of SR_{C}=112. This value may be improved by optimization. Using these numbers, the square bracket in Equation 15 has a value of 0.003. The cooling power Pc at 400 mK is then P_{C}=13 μW per mole of GdIG. This compares favorably to the performance of an He³ insert from Quantum Design, which has a cooling power P_{C} at 0.3 K of P_{C}=6 μW. With a much improved Weyl-mode switch having SR_{H}=26 at 1 K, the optimum Z=0.3, and with SR_{C}>50 the bracket value is >0.1 and P_{C}=430 μW per mole of GdIG.

The calculation may be repeated for a cold-side ADR stage 10 operating with FAA between 400 mK and 40 mK. Taking T_{H}=400 mK, T₂=0.5 mK, T_{C}=40 mK, T₄=30 mK, (S₄-S_{3′})=0.7 R=5.8 J/mole K and an SR_{H}=15 as expected from the present material yields an optimal value of Z=0.17 for SR_{C}=100, Q_{C}=0.06 J/mole and P_{C}=128 μW/mole of FAA. The number of moles of FAA may be adjusted so the hot-side ADR stage 10 is able to absorb the heat rejected from the cold-side ADR stage 10, which is T_{H}. (S₄-S_{3′})=2.32 J/mole of FAA. Thus, the cold-side ADR stage 10 may have a coefficient of performance COP=0.026. For a cooling capacity of the hot-side ADR stage 10 of P_{C1}=6 μW, the cooling capacity of the cold-side ADR stage 10 at 40 mK may be P_{C2}=0.16 μW per mole of GdIG in the hot-side ADR stage 10. This is very close to the cooling capacity of the Quantum Design dilution refrigerator insert.

The optimization model for a two-stage ADR stage combines the temperature dependence of the switch ratios and conductances, and optimizes the intermediate temperature stage and the strength of the magnetic field. Selecting the strength of the magnetic field is a tradeoff being between cycle time and the change in entropy ΔS=S_{D}-S_{C}. The optimal values may be determined empirically by testing different device layouts and magnetic switching schemes. The two stages may operate independently (e.g., using separate magnetic field generators) or may be cascaded (e.g., using a single magnetic field generator).

Devices have not been previously designed around topological insulators because topological insulators are band insulators, and their topologically protected electrons live in Dirac bands on the surfaces. Weyl semimetals have topologically protected bulk bands that are more conducive to large effects in transport properties, particularly thermal transport. The topological insulator based thermal switches described herein have performances that are believed to exceed those of superconducting switches at temperatures below 1 K. Advantageously, when a Weyl switch and a topological insulator switch are operated as a pair, they are bipolar. That is, one is in an on-state ant the other in an off-state in a high magnetic field, and vice-versa for weak magnetic fields. This makes it possible to operate a pair of thermal switches and a magnetocaloric material in an ADR stage using the same magnetic field.

Advantageously, the cyclical sub-K ADR's supplements dilution refrigeration with a technology that does not require He³. He³ is a rare gas that escapes the earth's gravitational field. The cooling needs of superconducting quantum computers will be enormous and He³ is in a critically short supply. Thus, embodiments of the invention may help alleviate problems caused by the short supply of He³.

### Physical Basis of Operation

Materials whose electrons are described by relativistic equations of motion for gravitational forces and electron dynamics are known as Weyl semimetals. The chiral anomaly has been predicted to be an experimental signature for the existence of Weyl semimetals. The importance of the chiral anomaly extends beyond solid-state physics as it provides a mechanism for charge-parity violation and the matter/antimatter imbalance in the universe. In condensed-matter materials, the analogous quasiparticle non-conservation is connected with a change in the vacuum state, thus preserving overall electron number.

It has been determined that previous experimental methods for determining the chiral anomaly may be tainted. First, currently investigated Weyl semimetals are not ideal at least because their Fermi surfaces contain features other than Weyl points. Second, the signature chiral anomaly feature is a negative longitudinal magnetoresistance, however the distorted current lines in the applied magnetic field complicate the interpretation.

Ideal Weyl semimetals have two distinguishing characteristics. First, the band structure has linearly dispersing bands that intersect at Weyl points in a system that breaks time reversal symmetry or inversion symmetry. Second, the electrochemical potential μ is at the Weyl point energy (μ=0). In an ideal Weyl semimetal, there are no trivial bands at the energy μ, which is pinned to the Weyl points. Then, the Fermi surface consists only of Weyl points with opposite Berry curvatures, i.e., right handed (W_{R}) and left-handed (W_{L}) Berry curvatures. One pair of Weyl points in the Brillouin zone is the minimum required by the Nielsen-Ninomiya theorem for a time reversal symmetry-breaking ideal Weyl semimetal. Experimentally, an ideal Weyl semimetal displays no Shubnikov-de Haas oscillations, and at a finite temperature, a nearly equal density of intrinsic holes and electrons is excited thermally, with any unbalance due to unintentional doping smaller than this intrinsic concentration.

The chiral anomaly in ideal Weyl semimetals results from applying parallel electric and magnetic fields E, B along the direction of the Weyl point separation. The magnetic field B separates the bands into Landau levels, with a two-dimensional density of states proportional to:

$$\frac{1}{{ℓ}_{B}^{2}} \qquad Eqn . 17$$

where the magnetic length [symbol] _{B} is:

$${ℓ}_{B} = \sqrt{\frac{ℏ}{e B}} \qquad Eqn . 18$$

e is the electron charge, and his Planck's constant. The chirality (χ=±1) dictates that in the extreme quantum limit, when only the last Landau level is populated, electrons have only one Fermi velocity per Weyl point. A Weyl point with a right handed chirality W_{R}(χ=+1) has only right-moving electrons of velocity v, and a Weyl point with left handed chirality W_{L}(χ=−1) has only left-moving electrons of velocity −v. The electric field E shifts the electron momentum in the last Landau levels by δk∝eEτ, where τ⁻¹ is the inter-Weyl point scattering rate. This generates right moving electrons by an amount δₙ₊₁∝δₖ₊₁/ [symbol] _{B}²∝Eτ/ [symbol] _{B}² and annihilates left moving electrons by an amount δₙ₋₁∝−Eτ/ [symbol] _{B}². This particle generation/annihilation process is the chiral anomaly, giving rise to an additional electric current proportional to v and δₙ₊₁−δₙ₋₁, which is proportional to E=|E| and |B|=μ₀H both applied along the z direction, where μ₀ is the permeability of a vacuum. The anomalous contribution to the electrical conductivity generated by N_{w} degenerate pairs of Weyl points is:

$${σ}_{zz} = {N}_{w} \frac{{e}^{2} v τ}{4 {πℏℓ}_{B}^{2}} = {N}_{w} \frac{{e}^{3} v τ}{4 π {ℏ}^{2}} {B}_{z} \qquad Eqn . 19$$

The resulting negative longitudinal magnetoresistance is considered as an experimental chiral anomaly signature.

Negative magnetoresistance is observed in many Weyl semimetals, such as NbAs, NbSb, TaAs, and TaSb compounds, as well as Dirac semimetals. Negative magnetoresistance is also observed in materials without Weyl points near μ, for example, NbAs₂, NbSb₂, TaAs₂, and TaSb₂ compounds and elemental semimetal bismuth. Broadly observing this effect reveals that negative magnetoresistance is unlikely to be a unique chiral anomaly signature, and that other, classical effects may be present.

Classical effects that may make longitudinal magnetoresistance measurements ambiguous can arise because the Lorentz force distorts the current flow spatial distribution in samples with high-mobility (μ_{B}) electrons under a magnetic field, i.e., when μ_{B}|B|>1. This can cause extrinsic, geometry-dependent magnetoresistance mechanisms. The first of these mechanisms is “current jetting” arising in four-contact measurements. When the magnetic field B and electric field E are parallel, the Lorentz force tends to concentrate the current in a cyclotron motion near the center of the sample. As a result, progressively less current passes near the voltage probes as the magnetic field B increases, lowering the measured voltage and possibly leading to the erroneous conclusion that the resistivity decreases with the magnetic field B. Another mechanism that can affect measurements is an extrinsic “positive geometric magnetoresistance” that arises if the magnetic field B is slightly misaligned with respect to the current flow lines. In the samples described herein, striations present on the surface of a Czochralski-grown crystal can overwhelm the magnetoresistance measurements, and care needs to be taken with the sample alignment and geometry. Samples with reduced cross-section and smooth edges minimize both effects. Measurements of magnetothermal conductivity κ_{zz}(H_{z}) with the heat flux and the magnetic field oriented along the z direction (H_{z}) avoid problems with extrinsic magnetoresistance because there is no external current flow, and the lattice contribution to the thermal conductivity κ maintains a more magnetic field B-independent heat flux than charge flux distribution in the sample. There may be a magnetic field effect on anharmonic phonon scattering, but it is an order of magnitude smaller than the effects described herein.

Energy transport in Weyl semimetals poses new theoretical challenges. From the equations of motion for charge carriers at the Weyl point and the Boltzmann transport equation, we write the imbalance between left- and right-moving particles (niₓ) and energy (δεₓ, the thermal chiral anomaly) in the presence of both an electric field E and thermal gradient ∇ᵣT as:

$$δ {n}_{χ} = \frac{χ {e}^{2} τ}{4 {π}^{2} {ℏ}^{2}} [ B \cdot E ] {C}_{0} + \frac{χ e τ}{4 {π}^{2} {ℏ}^{2}} [ B \cdot \frac{- {∇}_{γ} T}{T} ] {C}_{1} \qquad Eqn . 20$$

$${δε}_{χ} = \frac{χ {e}^{2} τ}{4 {π}^{2} {ℏ}^{2}} [ B \cdot E ] ( {μC}_{0} + {C}_{1} ) + \frac{χ e τ}{4 {π}^{2} {ℏ}^{2}} [ B \cdot \frac{- {∇}_{r} T}{T} ] ( {μC}_{1} + {C}_{2} ) \qquad Eqn . 21$$

$$where$$

$${C}_{m} = \int {( ε - μ )}^{m} ( - \frac{\partial {f}_{0}}{\partial ε} ) d ε , \qquad Eqn . 22$$

$$m ∈ \{ 0 , 1 , 2 … \}$$

and f₀ is the Fermi-Dirac distribution function.

The thermal chiral anomaly thus has two terms. First, a temperature gradient ∇ᵣT alone, disregarding any induced electric field, creates an imbalance between the energy carried by the left and right movers while maintaining equal populations when μ=0 (C₁=0, δn_{χ}=0, δε_{χ}≠0). This response contrasts with the electrical case where ∇ᵣT=0 and E create an imbalance between the populations of left and right movers while maintaining the same total energy (δn_{χ}≠0, δε_{χ}=0) when μ=0. Second, when the sample is mounted in open-circuit conditions and no external electric field is applied, applying ∇ᵣT induces a Seebeck electric field E=S(−∇ᵣT) (where S is the thermopower), driving both δn_{χ}≠0 and δε_{χ}≠0. This creates an additional magnetothermal conductivity κ_{zz}(H_{z}) term referred to as the ambipolar thermal conductivity, S²Tσ. The total thermal conductivity then becomes κ_{zz}=κ_{zz,0}+S²σT, where κ_{zz,0} denotes the energy carried directly by the charge carrier. For completeness, we mention that anomalously large quantum oscillations in the κ_{zz}(H_{z}) of TaAs is interpreted as a manifestation of chiral zero sound. We have not seen evidence of this behavior in Bi₁₋ₓSbₓ alloys for values of x>10%.

The experimental tests for these theories are to observe an increase in electronic thermal conductivity in a longitudinal magnetic field, and to verify the Wiedemann-Franz law in the extreme quantum limit,

$${κ}_{zz} = L T {σ}_{zz} \qquad Eqn . 23$$

where L the Lorenz ratio. If each electron carries charge e and entropy k_{B}, and conserves its energy during scattering, then:

$$L = {L}_{0} = \frac{{π}^{2}}{3} {( \frac{{k}_{B}}{e} )}^{2} \qquad Eqn . 24$$

The experiment includes testing the ratio κ_{zz}/Tσ_{zz}, which we define as L, against the independent variables H_{z} and T, and, if L is independent of these, to verify if the value equals L₀. In particular, a Weyl semimetal in which inelastic scattering is limited by the inter-WP scattering time τ, in the quasi-classical limit at H=0 is expected to have:

$$L = \frac{7 {π}^{2}}{5} {( \frac{{k}_{B}}{e} )}^{2} \qquad Eqn . 25$$

However, L=L₀ in the extreme quantum limit. In the presence of ambipolar conduction, L>L₀ because L₀ applies only to K_{zz,0}. Extrinsic effects may result in underestimations of L (current jetting) or overestimations of L (geometric magnetoresistance).

Below, we describe the dependence of magnetothermal conductivity κ_{zz}(H_{z}) on the magnetic field H_{z}, and show experimentally that the chiral anomaly affects energy and charge transport similarly, i.e.,

$$\frac{d {κ}_{zz}}{d {H}_{z}} > 0 \qquad Eqn . 26$$

as expected from Equations 19 and 22. Values for L are then derived experimentally. A 1% experimental increase in κ_{zz} for GdPtBi has been reported at H_{z}=9 tesla. However, those samples exhibited Shubnikov-de Haas oscillations in their magnetoresistance, which proves that their μ is not at the Weyl points. An excess κ_{zz} is also observed in NbP, and has been dubbed a gravitational anomaly due to the formal link between gradients ∇Φ in the gravitational field and ∇ᵣT. Below, we disclose magnetothermal conductivity κ_{zz}(H_{z}) in magnetic-field induced ideal Weyl semimetals, Bi₁₋ₓSbₓ alloys with x=11% and 15%. We further disclose that these alloy samples, topological insulators at |B|=0 become Weyl semimetals without trivial bands in a quantizing magnetic field along the trigonal axis (z=(001)) and the locations of the Weyl points. In these material samples, we show their carrier concentrations are intrinsic above ~30 K, where the relevant κ_{zz} data are collected. This makes them ideal Weyl semimetals by construction. Their magnetothermal conductivity κ_{zz}(H_{z}) shows an electronic thermal conductivity increase by up to 300% at H_{z}=9 tesla. Lorenz ratio L=κ_{zz}/Tσ measurements show that L≈L₀. The effect is robust to disorder and phonon scattering, depends on the ratio of the temperature to the Weyl bandwidth, and is absent in samples that fall outside the range of compositions where Weyl semimetals form in an applied magnetic field.

For values of x between 9% and 18%, Bi₁₋ₓSbₓ alloys are expected to be ideal Weyl semimetals in a magnetic field above a critical magnetic field threshold H_{z}=H_{C}. This expectation is due to: (1) the conduction and valence bands of these alloys crossing at H_{C}, (2) for magnetic fields H_{z}>H_{C}, two crossing points appear that are Berry curvature monopoles, i.e., Weyl points, and (3) no trivial bands cross μ.

For values of x between 9% and 18% in Bi₁₋ₓSbₓ alloys are expected to be ideal Weyl semimetals in a magnetic field above a critical magnetic field threshold H_{z}=H_{C}. This expectation is due to (1) the conduction and valence bands of these alloys crossing at H_{C}, (2) for magnetic fields H_{z}>H_{C}, two crossing points appear that are Berry curvature monopoles, i.e., Weyl points, and (3) no trivial bands cross chemical potential μ.

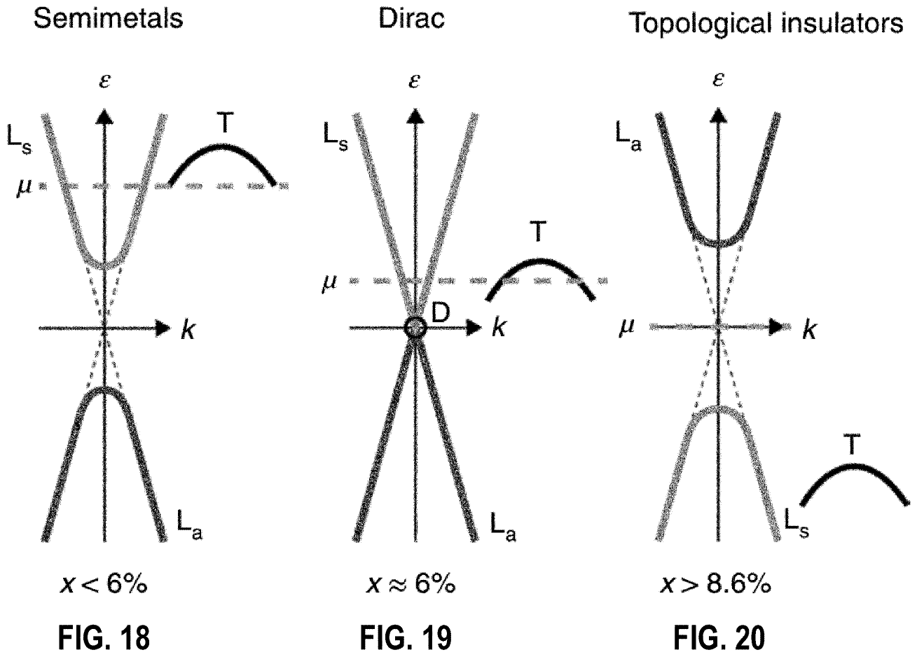

FIGS. 16-25 depict the evolution of Bi₁₋ₓSbₓ alloys with changes composition and magnetic field strength. FIG. 16 illustrates the dependence of band-edge energies (ε) on composition (x) at zero applied magnetic field H_{z}. Elemental semimetal Bi has electrons residing in a conduction band Lₛ and holes in a valence band T with a filled second valence band Lₐ. Increasing the value of x in the alloy causes the La-Ls gap to close until the bands intersect near x≈6%. The T-band edge intersects that of the La and Ls bands at x≈7.7% and x≈8.6%, respectively. The evolution of the chemical potential μ(x) for samples with no unintentional doping is shown as a dashed line. Alloys with x<7.7% are semimetals with μ in a band. Alloys with x>8.6% are direct-gap topological insulators with μ at mid-gap in undoped material.

FIG. 17 illustrates topological insulator alloy Bi₈₉Sb₁₁ band-edge energies with a magnetic field H_{z} applied along the trigonal direction. The field separates the Lₐ and Lₛ valence bands into Landau levels, with orbital quantum number n and spin s. With increasing strength of the magnetic field H_{z}, the orbital quantum number n=0, s=1/2 of the Lₐ and Lₛ bands cross again at a critical field H_{C}. At higher magnetic field strengths, the crossing points develop into Weyl points.

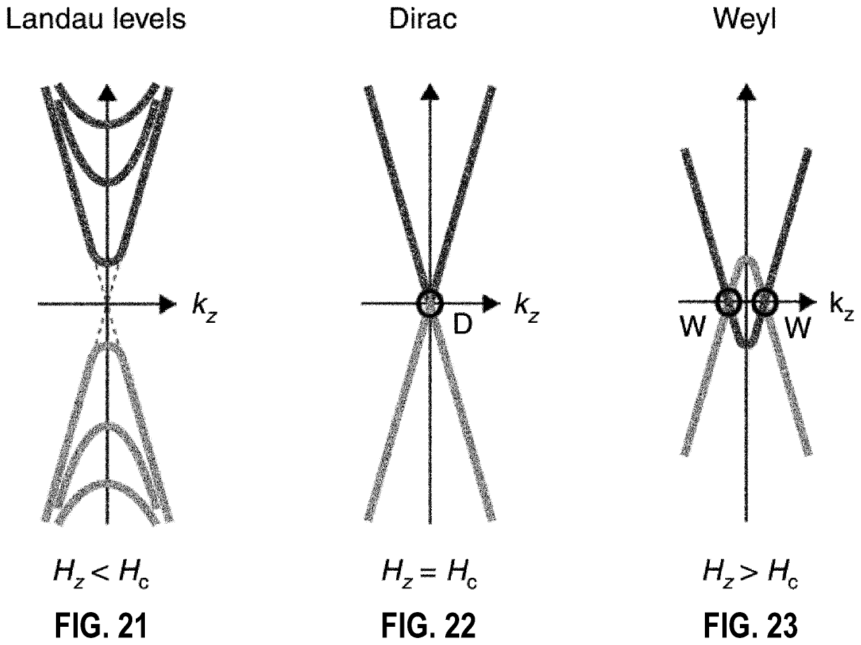

FIG. 18 illustrates the dispersion relationship for semimetal Bi. FIGS. 19 and 20 illustrate the Dirac dispersion of Bi₉₄Sb₆ alloys and the dispersion of Bi—Sb topological insulators. FIG. 21 illustrates dispersions along κ_{z} for H_{z}<H_{C}. FIG. 22 illustrates dispersion in κ_{z} for H_{z}=H_{C}. FIG. 23 illustrates the dispersion at H_{z}>H_{C} becomes that of a field-induced Weyl semimetal. FIG. 24 illustrates Brillouin zone and Fermi surfaces. Electrons fill six pockets at the Brillouin zone L-point, and holes fill two pockets at the T-points. FIG. 25 illustrates the Brillouin zone for Bi₁₋ₓSbₓ with locations of calculated Weyl points shown schematically, with opposite points in each pair being Weyl points with opposite Berry curvature.

The band structures of Bi₁₋ₓSbₓ alloys at zero magnetic field H_{z}=0 evolve with increasing x through four successive regimes: (1) conventional semimetals, (2) semimetals with an inverted band at the Brillouin zone L-point, (3) indirect-gap semiconductors, and (4) direct-gap topological insulators. A tight-binding Hamiltonian describes the band structure of unalloyed bismuth and antimony, incorporating the s and p orbitals of the two atoms in the conventional hexagonal unit cell. The alloy electronic structure is calculated using a modified virtual crystal approximation in which the tight-binding parameters are obtained directly from those of the elemental semimetals and agree with previous experiments within the experimental uncertainty on compositions, e.g., within 1%. The details of the electronic structure of the Bi—Sb alloy change slowly as the band positions change relative to chemical potential μ, as indicated by the nearly unchanged intrinsic spin-Hall conductivity calculated through the semimetal-topological insulator transitions.

With these parameters, and with reference to FIGS. 17 and 21-23, a quantizing magnetic field along the trigonal direction of the topological insulators inverts the bands again. The g_{eff} tensors at the high-symmetry Brillouin zone L- and T-points are calculated from the tight-binding electronic structure above for valence and conduction bands. The T-point g_{eff}-tensor has only one non-zero component, g_{hz}=20.5, which only couples to the magnetic field along z. The more complicated effective g_{eff}-tensor at the L-point shows substantial asymmetry. For the conduction and valence bands at the Bi₈₉Sb₁₁ L-point with a magnetic field applied along the trigonal direction, the calculated values are g_{z}=−77.5 and −72.3, respectively. Shubnikov-de Haas oscillations in Bi confirm the extremely large g-factor values experimentally. This results in an anomalously large effective Zeeman splitting energy Δϵ_{z}=−μ_{B}g_{z}B_{z}≈−4.2 meV T⁻¹ at the L-point that overwhelms the orbital splitting of the Landau levels. Consequently, the band gaps close (see FIGS. 17 and 22) at a critical magnetic field strength H_{C}, which is calculated to be ~3 tesla for alloy compositions near x=11%. Magnetic field-induced band closings are uncommon, but have been witnessed via magneto-optical measurements on Bi. The critical magnetic field strength H_{C} is sensitive to parameter values used in the calculations, and is of the order of 1 to 4 tesla. For a magnetic field H_{z}>H_{C}, the Zeeman energy increase further splits the degeneracy.

The Chern number is an integer that counts the monopoles enclosed in a given Gaussian surface in the Brillouin zone. Accordingly, the Kramers doublets are believed to be become Weyl points resulting from explicit time reversal symmetry breaking due to the Chern number changing by an integer for a momentum slice taken between these Weyl points.

Weyl points can be found by calculating the Berry curvature distribution Ωₙ(k) in momentum space, and searching for points where the Berry curvature is concentrated and singular. The two Weyl points carry monopole Berry curvature Ω(k)=χk/k³ with opposite chirality, χ=±1. Integrating the Berry curvature provides the Chern number. A Chern number integer change provides evidence of a topology change and the existence of Weyl points, with a pair of Weyl points separated symmetrically near each L-point in the three-dimensional Brillouin zone (see FIG. 25). The separation between the two Weyl points is in the binary-trigonal plane with a major component along the trigonal direction (coinciding with the external magnetic field direction) and a minor component along the bisectrix direction.

To ascertain that the Bi₈₉Sb₁₁ material is an ideal Weyl semimetal at H_{z}>H_{C}, the model verifies that no trivial bands contribute to transport. That is, neither the T-point band nor any new bands move near the chemical potential μ with increasing magnetic field H_{z}. In a semiconductor or semimetal without unintentional doping, the chemical potential μ is pinned at the energy of the lowest density of states, which, without trivial bands, occurs at the Weyl points. Therefore, if unintentional doping is avoided, ideal Weyl semimetals are formed by construction.

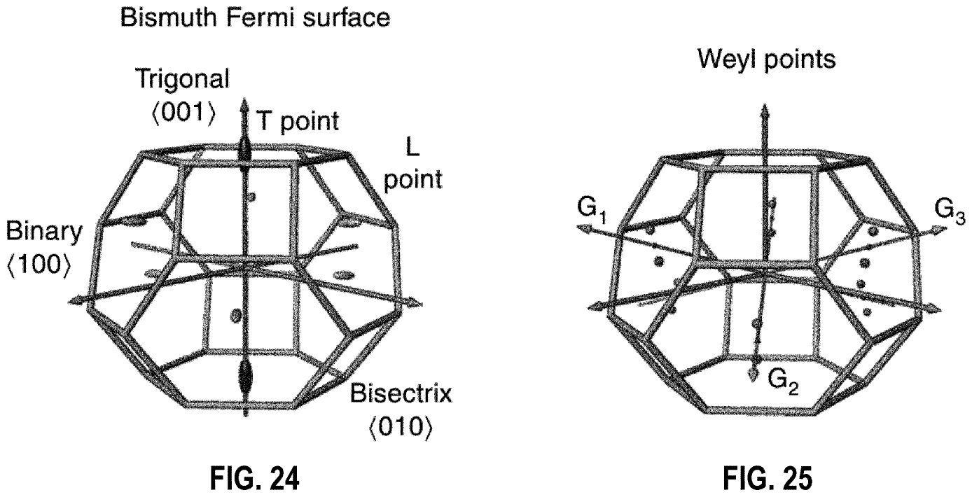

FIGS. 26-28 depict the electronic and thermal properties of Bi₈₉Sb₁₁ and Bi₈₅Sb₁₅ versus temperature T, with FIGS. 26 and 27 showing carrier concentration and mobility. The samples switch from dominantly n-type at 300 K to dominantly p-type at 10 K. FIG. 28 depicts Bi₈₉Sb₁₁ zero-field thermal conductivity κ_{zz} (where z denotes the (001) crystallographic direction) separated into lattice thermal conductivity κ_{L} and electronic thermal conductivity κ_{E} parts. The dashed bold line is the thermal conductivity κ_{E} calculated from the resistivity and the Wiedemann-Franz law with L=L₀. The error bars are standard deviations.

Evidence for the thermal chiral anomaly is shown in six single-crystal samples of Bi₁₋ₓSbₓ for x≈11% and 15%. As a control, the absence of the anomaly was measured in two semi-metallic samples with x≈5% since an ideal Weyl semimetal does not exist for this composition. The sample compositions and characterizations are presented in Table 1. The temperature dependence of the resistivity and low-field Hall effect of the best samples (sample 1 with x=11% and x=15%) are used to derive carrier concentration and mobility (FIGS. 26 and 27) showing that charge carriers freeze out. This, and the absence of Shubnikov-de Haas oscillations in the high-field longitudinal magnetoresistivity down to 2 K and other transport properties indicate that they are ideal Weyl semimetals. The zero-field thermal conductivity κ_{zz} along the trigonal direction of sample 1 is given in FIG. 28. The thermal conductivity κ_{zz} consists of a phonon κ_{L} and electronic κ_{E} contribution separated by measuring κ_{zz}(H_{y}), where subscript y denotes the (010) crystallographic direction. This shows a steady decrease to a saturation value at high field, which is the ordinary behavior of high-mobility materials used to isolate κ_{L}=lim_{Hy→∞}(κ_{zz}(H_{y}) for T<120 K. For T>120 K, κ_{L}(T) is extrapolated following a T^{1/3} law to 300 K. Lattice thermal conductivity κ_{L} dominates κ_{zz} below 35 K, limiting measurements of κ_{E} to T>35 K. At zero field, κ_{E} (at zero magnetic field H_{z}=0) follows the Wiedemann-Franz law with L=L₀ above 35 K, as shown by the dashed line in FIG. 28).

TABLE 1

| | | | | | Mobility |
|---|---|---|---|---|---|
| Sample | Growth | x (%) | Used for | Density (cm⁻³) | (cm² V⁻¹ s⁻¹) |
| Sample 1 | Travelling | 10.5 + 0.5 | k_{zz}(H_{z}), k_{zz}(H_{y}), | | |
| | Molten Zone | | k_{zz}(H_{z}) Ag contacts | | |
| Hall | Travelling | 10.5 + 0.5 | Hall, resistivity | 3 × 10¹⁵ (10K) | 1.9 × 10⁶ (10K) |
| | Molten Zone | | | | |
| Sample 2 | Czochralski | 11.3 + 0.7 | Negative | | |
| | | | Magnetoresistance | | |
| | | 11.3 + 0.7 | Magneto-Seebeck | | |
| | | 11.3 + 0.7 | k_{zz}(H_{z}), k_{zz}(H_{y}) | | |
| Sample 3 | Czochralski | 11.3 + 0.7 | k_{zz}(H_{z}), k_{zz}(H_{y}) | | |
| | | 11.3 + 0.7 | k_{zz}(H_{z})-angular | | |
| | | | dependence | | |
| Sample 4 | Czochralski | 11.3 + 0.7 | k_{zz}(H_{z}), k_{zz}(H_{y}) | | |
| Hall | Czochralski | 11.3 + 0.7 | Hall, resistivity | 1.4 × 10⁶ (12K) | 2 × 10⁴ (12K) |
| Sample 5 | Travelling | 15.1 + 0.7 | k_{zz}(H_{z}), k_{zz}(H_{y}) | | |
| | Molten Zone | | | | |
| Hall | Travelling | 15.1 + 0.7 | Hall, resistivity | 3 × 10¹⁶ (10K) | 4.5 × 10⁵ (10K) |
| | Molten Zone | | | | |
| Sample 6 | Travelling | 10.5 + 0.5 | k_{zz}(H_{z}), ρ_{zz}(H_{y}), | As sample 1 | As sample 1 |
| | Molten Zone | | | | |
| Semimetal | Bridgeman | 5 + 0.5 | k_{zz}(H_{z}), k_{zz}(H_{z}) Ag | 4.5 × 10¹⁶ (79K) | 8 × 10⁴ (79K) |
| | | | contacts, Hall, | | |
| | | | resistivity | | |

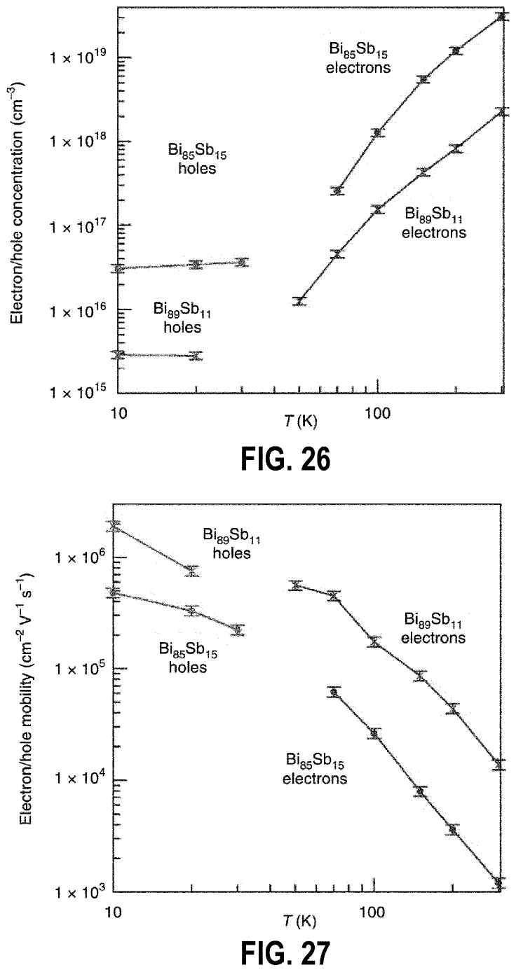

FIGS. 29-32 depict the dependence of magnetothermal conductivity κ_{zz}(H_{z}) on longitudinal magnetic field H along the trigonal (z=(001)) direction at various temperatures for Bi₉₅Sb₅, Bi₈₉Sb₁₁, and Bi₈₅Sb₁₅. FIG. 29 shows that Bi₉₅Sb₅ is a conventional (not Weyl) semimetal having a magnetothermal conductivity κ_{zz}(H_{z}) that monotonically decreases with H_{z} due to a positive magnetoresitance. FIGS. 30 and 31 show the magnetothermal conductivity κ_{zz}(H_{z}) of Bi₈₉Sb₁₁ (sample 1) and Bi₈₅Sb₁₅ decreasing due to a conventional positive magnetoresistance in the topological insulator regime, followed by an increase. The increase is evidence for the thermal chiral anomaly. FIG. 32 shows the contribution of the electronic thermal conductivity κ_{E} to the total thermal conductivity κ_{zz} for Bi₈₉Sb₁₁ is obtained by subtracting the lattice contribution κ_{L}. The electronic thermal conductivity κ_{E} shows an increase as large as 300% in a magnetic field at 9 tesla. The error bars indicate the standard deviation relative to the field dependence, which is temperature dependent and are the same for all samples at the same temperatures.

FIGS. 29-32 show the longitudinal magnetothermal conductivity κ_{zz}(H_{z}) of three samples: Bi₉₅Sb₅ (not a Weyl semimetal), Bi₈₉Sb₁₁, and Bi₈₅Sb₁₅ (both Weyl semimetals in magnetic fields above 1-2 tesla). The electronic thermal conductivity κ_{E}(H_{z}) of Bi₈₉Sb₁₁ is reported as a function of H_{z} in FIG. 32. The relative electronic thermal conductivity κ_{E} increases as magnetic field reaches above 300% from 34 K to 85 K at 9 tesla. At low magnetic fields, dκ_{z}/dH_{z}<0 for a magnetic field H_{z}<1 tesla at a temperature T<50 K and a magnetic field H_{z}<3 tesla at T=160 K. Here, the last Landau levels of the conduction and valence bands have not crossed in energy. At high field, in Weyl semimetal phase, dκ_{zz}/dH_{z}>0. The large increase in magnetothermal conductivity κ_{zz}(H_{z}) (See FIGS. 30-32) at high field is experimental evidence for the thermal chiral anomaly. The following observations support this assertion.

First, FIG. 29 shows that dκ_{zz}/dH_{z}<0 at all fields for Bi₉₅Sb₅. At zero magnetic field, Bi₉₅Sb₅ is a conventional semimetal with a trivial hole pocket in its Fermi surface at the Brillouin zone T-point, not a topological insulator. In Bi₉₅Sb₅, the band crossing with field does not create an ideal Weyl semimetal phase. If the dκ_{zz}/dH_{z}>0 observation on Bi₈₉Sb₁₁ and Bi₈₅Sb₁₅ resulted from effects other than the chiral anomaly (e.g., ionized impurity scattering known to be weak even in doped Bi), the observation would also occur in similarly prepared Bi₉₅Sb₅.

Second, to ascertain that a circulating current or an artifact on the sample surfaces does not induce the effect, samples of Bi₉₅Sb₅ and Bi₈₉Sb₁₁ were mounted with the top and bottom faces thereof covered by electrically conducting Ag epoxy. No effect was observed from the added surface conducting layers.

Third, the dκ_{zz}/dH_{z}>0 data at high H_{z} were reproduced on Bi₈₉Sb₁₁ samples 2-4, which had a mobility of only 2×10⁴ cm²V⁻¹s⁻¹ at 12 K. This demonstrates the robustness of the observations vis-à-vis defect scattering.

Fourth, dκ_{zz}/dH_{z}>0 in FIGS. 30-32 is observed up to 200 K, which is twice the Bi Debye temperature. This demonstrates the robustness of the effect to phonon scattering. For T>200 K, the rate of change in thermal conductivity κ_{z} with respect to changes in the magnetic field H_{z} is less than zero (dκ_{zz}/dH_{z}<0) at all magnetic fields due to thermal smearing of the carrier population between the Weyl points. The fourth observation is demonstrated below as being due to thermal smearing of the carrier population between the Weyl points, independent of phonons.

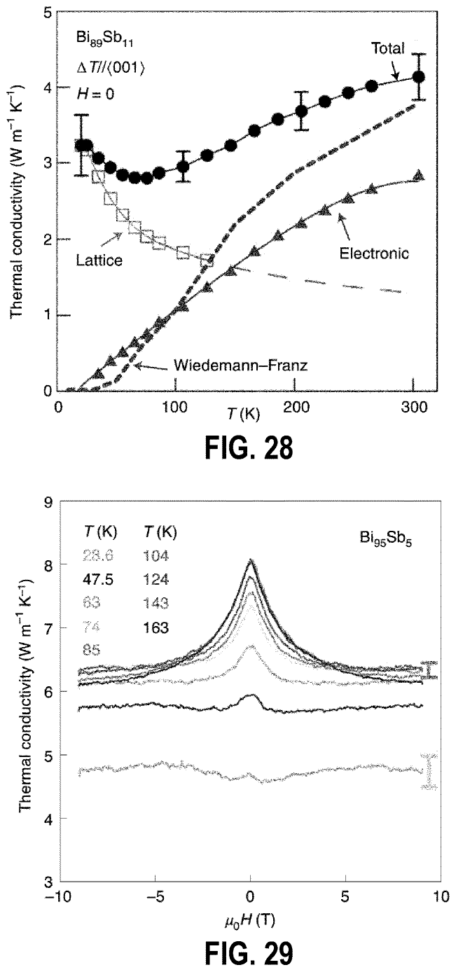

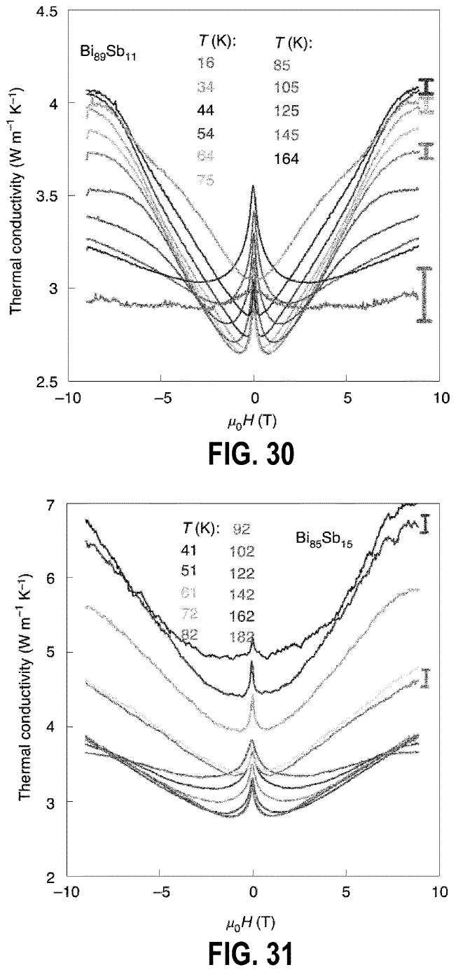

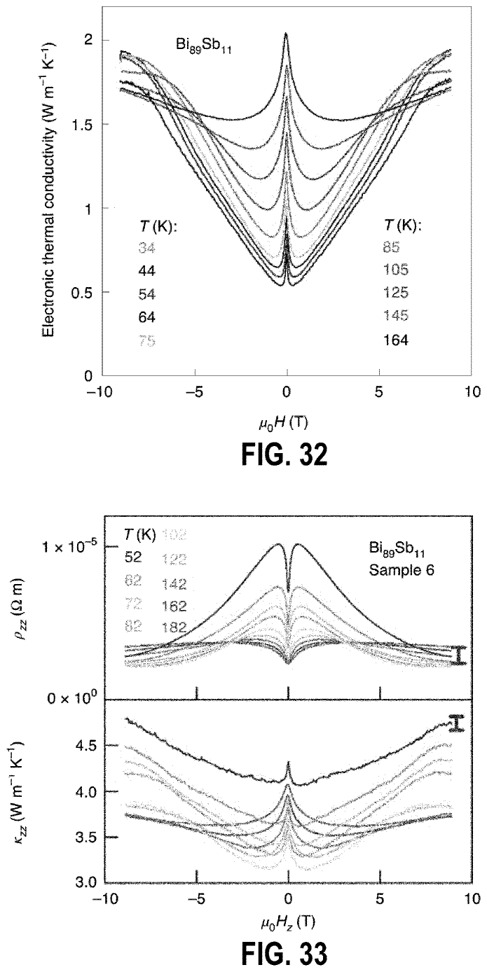

FIG. 33 depicts a graph illustrating the magnetothermal conductivity κ_{zz}(H_{z}) and resistivity ρ_{zz}(H_{z}) of Bi₈₉Sb₁₁ (sample 6). The graph includes error bars indicating the standard deviations of each. FIG. 34 depicts the Lorenz ratio L=κ_{zz,E}(H_{z})ρ_{zz}(H_{z})/T derived from the data depicted in FIG. 33 normalized to L₀T at two values of H_{z} showing that Lis independent of H_{z} within the error bar. The error bars arise from the errors on ρ_{zz} (H_{z}) and on κ_{zz,e}(H_{z}) determined from κ_{zz,E}(H_{z}) and κ_{L}. FIG. 35 depicts a graph illustrating that the inter-Weyl point scattering time, τ (e.g., derived from Equation 24) fits Arrhenius plots at T>60 K with an activation energy of Eₐ=34 meV for Bi₈₉Sb₁₁ and 15 meV for Bi₈₅Sb₁₅. The inset shows the temperature dependence of dκ_{zz}(H_{z})/dH_{z} for magnetic fields H_{z} of between 4 and 8 tesla using sample 1 (see Table 1) on Bi₈₉Sb₁₁ and Bi₉₅Sb₁₅.

FIG. 33 depicts simultaneous magnetothermal conductivity κ_{zz}(H_{z}) and magnetoresistance ρ_{zz}(H_{z}) measurements that were taken on a specially prepared Bi₈₉Sb₁₁ sample. Subtracting the lattice thermal conductivity κ_{L} from the total magnetothermal conductivity κ_{zz}(H_{z}) gives the electronic thermal conductivity κ_{zz,E}(H_{z}). The Wiedemann-Franz law is tested by plotting the product κ_{zz,E}(H_{z})×ρ_{zz}(H_{z}) normalized to L₀T in FIG. 34 as function of T for H_{z}=5 tesla and 9 tesla. The H_{z} dependence of the result is within the error bars, and FIG. 34 verifies that the Wiedemann-Franz law holds in an applied field with L≈L₀. Since the material is an ideal Weyl semimetal and the Weyl semimetal phase is induced in extreme quantum limit, the Lorenz ratio is expected to be L₀. The error bar increases with decreasing T as the lattice conductivity κ_{L} increasingly dominates total magnetothermal conductivity κ_{zz}(H_{z}) and becomes as large as the signal below 50 K. The lattice conductivity κ_{L} masks the electronic contribution completely below 35 K. This knowledge allows fitting the dκ_{zz}/dH_{z} experimental temperature dependence at T>60 K (see inset in FIG. 35). Using Equations 19 and 22 with L=L₀ and N_{w}=12 to derive the thermal chiral conductivity, then taking its field derivative, we obtain:

$$\frac{d {κ}_{zz}}{d {H}_{z}} = \frac{π e v {k}_{B}^{2}}{{ℏ}^{2}} T τ \qquad Eqn . 27$$

Using the calculated v≈4.5×10⁵ m/s, Equation 27 can be used to derive the temperature dependent inter-Weyl point scatting time τ(T). (See FIG. 35). Below ~60 K, the inter-Weyl point scattering timer of Bi₈₉Sb₁₁ tends asymptotically to 10⁻¹² seconds, and is temperature independent at a value one order of magnitude longer than the electron relaxation time in Bi₉₅Sb₅ at 4.2 K. This suggests a high degree of charge-transport protection. In Bi₈₅Sb₁₅ and at T>60 K in Bi₈₉Sb₁₁, the scattering sime τ increases exponentially with T⁻¹, and is an activated behavior with activation energy of 34±2 me V for Bi₈₉Sb₁₁ and 15±2 meV for Bi₈₅Sb₁₅. This is expected when the mechanism that limits the scattering time τ is charge carriers being thermally excited above the Weyl band width. The calculated band width at 7.5 tesla is E_{BW}=35 meV for x=10.5% and E_{BW}=20 meV at 7.5 tesla for x=15.1%, which are the measured concentrations in the samples. The correspondence between Eₐ and E_{BW} for two compositions suggests that thermal smearing of the carrier population between the Weyl points is the main mechanism inhibiting the observed increase in magnetothermal conductivity κ_{zz}(H_{z}), and that E_{BW} is the only energy scale in the observations.

Altogether, the observation that dκ_{zz}/dH_{z}>0 constitutes robust experimental evidence for energy pumping between opposite chirality monopoles when a thermal gradient is applied parallel to a magnetic field in an ideal Weyl semimetal. This is related to the excess electrical conductivity due to the charge pumping between opposite chirality monopoles, the chiral anomaly and, by the Wiedemann-Franz law, with a Lorenz number of (π³/3)×(k_{B}/e)². The robustness of the results with respect to defect and phonon scattering, and the identification of the Weyl band width as the only energy scale, all point to the topological origin of the data.

Additional information regarding the thermal chiral anomaly in the magnetic-field induced ideal Weyl phase of Bi₁₋ₓSbₓ topological insulators is provided below.

### Section 1 the Wiedemann Franz Law in Semi-Classical and Extreme-Quantum Limits

The Wiedemann-Franz law is a statement about the ratio of longitudinal thermal conductivity κ/T to longitudinal electrical conductivity σ, quantified by the Lorenz ratio:

$$L ≡ \frac{κ}{σ T} \qquad Eqn . 28$$

In a free-electron metal, Equation 24 yields:

$$L = {L}_{0} ≡ \frac{{π}^{3}}{3} {( \frac{{k}_{B}}{e} )}^{2} {\to }^{yields} ( {L}_{0} = 2.4 \times 1 {0}^{- 8} {( V {/}_{K} )}^{2} ) \qquad Eqn . 29$$

if the scattering time of electrons in electrical and thermal conductivity are identical.

There are two aspects of violation of the Wiedemann-Franz law, corresponding to two questions: (1) Is the Lorenz ratio L temperature dependent? (2) Is the Lorenz ratio L equal to the free-electron value L₀? We describe these questions in the semi-classical and extreme-quantum limits of a Weyl semimetal in an external magnetic field, and consider the case of ambipolar thermal conductivity, which can be relevant in semimetals and intrinsic semiconductors.

From Onsager's generalized transport equations, the flux vectors of charge (J^{e}) and heat (J^{Q}) are related to the electric field (E) and temperature gradient by:

$$( \begin{matrix}{J}^{e} \\ {J}^{Q}\end{matrix} ) = ( \begin{matrix}σ & α \\ - α T & {κ}_{0}\end{matrix} ) ( \begin{matrix}E \\ - ∇ T\end{matrix} ) \qquad Eqn . 30$$

where σ, α, and κ₀ are the electrical conductivity, thermoelectric conductivity, and thermal conductivity tensors, respectively. With the electric field and thermal gradient applied along the z direction, and upon imposing the boundary condition that no current flows in or out of the sample,

$$0 = {J}_{z}^{e} = {σ}_{zz} {E}_{z} + {α}_{zz} ( - {∇}_{z} T ) ,$$

we obtain an induced thermoelectric field,

$${E}_{z}^{ind} = - ( \frac{{α}_{zz}}{{σ}_{zz}} ) ( - {∇}_{z} T ) \qquad Eqn . 31$$

in the opposite direction of the thermal gradient to prevent the electric current flow. The quantity

$$S ≡ ( \frac{{α}_{zz}}{{σ}_{zz}} ) \qquad Eqn . 32$$

is the Seebeck coefficient. The total open-circuit thermal conductivity then is given by:

$${κ}_{zz} ≡ \frac{{J}_{z}^{Q}}{( - {∇}_{z} T )} = {κ}_{zz , 0} + \frac{{α}_{zz}^{2} T}{{σ}_{zz}} = {κ}_{zz , 0} + {S}^{2} σ T \qquad Eqn . 33$$

as reported above.

Here, the first two indices indicate the direction of the applied field and the induced current. The second term in Equation 33 is the ambipolar thermal conductivity κ_{A}=S²σT. It can be see that the Wiedemann-Franz law may be violated if: (a) S or α_{zz} is finite because the Wiedemann-Franz law holds only for κ_{zz,0}, in which this case L>L₀, or (b) S=0 or α_{zz}=0, but different scattering mechanisms limit κ (often dominated by inelastic scattering, which is temperature dependent) and σ (often dominated by momentum or elastic scattering). This gives L<L₀. In classical materials, L ranges from 0.5 to 2.6×10⁻⁸ (V/K)², or slightly more for semimetals.

From the Boltzmann equation, we obtain the longitudinal magnetothermal κ_{zz,z}, magneto-electrical σ_{zz,z}, and magneto-thermoelectrical α_{zz,z} conductivities (here, the third index is the direction of the applied magnetic field), given by:

$${κ}_{zz , z} = \int \frac{{d}^{3} k}{{( 2 π )}^{3}} D ( B , Ω ) τ {( {v}_{z} + \frac{{eB}_{z}}{ℏ} Ω \cdot v )}^{2} ( - \frac{\partial {f}_{0}}{\partial ε} ) \frac{{( ε - μ )}^{2}}{T} \qquad Eqn . 34$$

$${σ}_{zz , z} = {e}^{2} \int \frac{{d}^{3} k}{{( 2 π )}^{3}} D ( B , Ω ) τ {( {v}_{Z} + \frac{{eB}_{Z}}{ℏ} Ω \cdot v )}^{2} ( - \frac{\partial {f}_{0}}{\partial ε} ) \qquad Eqn . 35$$

$${α}_{zz , z} = e \int \frac{{d}^{3} k}{{( 2 π )}^{3}} D ( B , Ω ) τ {( {v}_{z} + \frac{{eB}_{z}}{h} Ω \cdot v )}^{2} ( - \frac{\partial {f}_{0}}{\partial ε} ) \frac{ε - μ}{T} \qquad Eqn . 36$$

where μ is the chemical potential and

$$D ( B , Ω ) = {[ 1 + ( \frac{e}{ℏ} ) B Ω ]}^{- 1} \qquad Eqn . 37$$

arises due to the modification of the phase space in an external magnetic field. Equations 35-37 are written assuming that the same relaxation time τ governs the thermal and electrical conductivity. Further, we assume that τ¹ is the inter-Weyl-point scattering probability.

It is shown below that in an ideal Weyl semimetal with the chemical potential at the Weyl points (μ=0) in the extreme-quantum limits, α_{zz}=0 and the Wiedemann-Franz law holds with the free-electron Lorenz number L=L₀. In the semi-classical regime at B=0, on the other hand, the Lorenz number for μ=0 is different from the free-electron value: L>L₀ at temperatures below the band width of the Weyl bands. With increasing T, due to contributions from non-linear parts of the electronic structure, the Lorentz ratio decreases towards L₀. Further, at low T if μ≠0, the Lorenz ratio L shows a linear B dependence only in the semi-classical regime, arising from a non-zero Seebeck coefficient and ambipolar thermal conductivity that depends linearly on the magnetic field, which leads to a violation of the Wiedemann-Franz law.

### Extreme-Quantum Limit

In the extreme-quantum limits, the energy dispersion for the n^{th} Landau level is given by:

$${ε}_{n} ( {k}_{z} ) = \{ \begin{matrix}\pm ℏ v \sqrt{2 \vert n \vert {ℓ}_{B}^{- 2} + {k}_{z}^{2} ,} & n \neq 0 \\ 𝒳ℏ {vk}_{z} , & n = 0\end{matrix} \qquad Eqn . 38$$

where [symbol] _{B}=\sqrt{h/eB} is the magnetic length, v is the Fermi velocity, and χ is the chirality of the Weyl point. This implies that the n=0 Landau level disperses in opposite directions at the two nodes. The density of states for the n=0 Landau level is given by:

$$D ( ε ) = \int \frac{{d}^{3} k}{{( 2 π )}^{3}} δ ( ε - {ε}_{k} ) = \frac{1}{{( 2 π )}^{2} ℏ v {ℓ}_{B}^{2}} = \frac{eB}{4 {π}^{2} {ℏ}^{2} v} \qquad Eqn . 39$$

from which we obtain the following results for the transport coefficients in the extreme-quantum limits at μ=0:

$$\begin{matrix}{κ}_{zz , z}^{EQ} = {N}_{w} \int d ε D ( ε ) τ {v}^{2} ( - \frac{\partial {f}_{0}}{\partial ε} ) \frac{{( ε - μ )}^{2}}{T} = {N}_{w} \frac{{eB}_{z} v {τ ( {k}_{B} T )}^{2}}{4 {π}^{2} {ℏ}^{2} T} {I}_{2} \\ = {N}_{w} \frac{ev τ {k}_{B}^{2}}{4 {π}^{2} {ℏ}^{2}} \frac{{π}^{2}}{3} {TB}_{z}\end{matrix} \qquad Eqn . 40$$

$${σ}_{zz , z}^{EQ} = {N}_{w} {e}^{2} \int d ε D ( ε ) τ {v}^{2} ( - \frac{\partial {f}_{0}}{\partial ε} ) = {N}_{w} \frac{{e}^{3} {B}_{z} v τ}{4 {π}^{2} {ℏ}^{2}} {I}_{0} = {N}_{w} \frac{{e}^{3} v τ}{4 {π}^{2} {h}^{2}} {B}_{z} \qquad Eqn . 41$$

$${α}_{zz , z}^{E Q} = {N}_{w} e \int d ε D ( ε ) τ {v}^{2} ( - \frac{\partial {f}_{0}}{\partial ε} ) \frac{ε - μ}{T} = {N}_{w} \frac{{e}^{2} {B}_{z} v τ {k}_{B}}{4 {π}^{2} {ℏ}^{2}} {I}_{1} = 0 \qquad Eqn . 42$$

$$with :$$

$${I}_{m} ≡ {\int }_{- ∞}^{∞} {x}^{m} ( - \frac{\partial {f}_{0}}{\partial x} ) dx = \{ \begin{matrix}1 , & m = 0 \\ 0 , & m = odd \\ 2 m Γ ( m ) ς ( m ) ( 1 - {2}^{1 - m} ) , & m \neq 0 , m = even\end{matrix} \qquad Eqn . 43$$

Here m∈{0,1,2, . . . }, the number of Weyl points is N_{w}, the velocity along the z-axis is,

$${v}_{z} = \frac{\partial {ε}_{k}}{ℏ \partial {k}_{z}} = v \qquad Eqn . 44$$

the reduced energy scale is,

$$x ≡ \frac{( ε - μ )}{{k}_{B} T} \qquad Eqn . 45$$

the Fermi-Dirac distribution is,

$${f}_{0} = {\{ 1 + exp ( x ) \}}^{- 1} \qquad Eqn . 46$$

the gamma function is Γ(m), and the Riemann-zeta function is ζ(m).

In this regime, we find that the Wiedemann-Franz law holds for the chiral n=0 Landau level:

$$L = {( \frac{{k}_{B}}{e} )}^{2} [ \frac{{I}_{2}}{{I}_{0}} ] = \frac{{π}^{2}}{3} {( \frac{{k}_{B}}{e} )}^{2} = {L}_{0} \qquad Eqn . 47$$

When chemical potential is set at the energy of Weyl points (μ=0), α, S, and thus, the ambipolar thermal conductivity vanish identically. Note that when the inelastic scattering time of electrons that enters the thermal conductivity is τ_{eff} such that

$${τ}_{eff}^{- 1} = {τ}^{- 1} + {τ}_{ε}^{- 1} ,$$

where τ_{ε} is the inelastic scattering time, the Lorenz ratio is reduced by the ratio τ_{eff}/τ, and L<L₀.

### The Semi-Classical Regime

At B=0 and for a linear dispersion:

$${ε}_{k} = \pm hv \vert k - {k}_{W} \vert \qquad Eqn . 48$$

around the Weyl points at ±k_{W}, we obtain the density of states:

$$D ( ε ) = \frac{{ε}^{2}}{2 {{π}^{2} ( ℏ v )}^{3}} \qquad Eqn . 49$$

Assuming an energy-independent scattering time τ, we obtain at μ=0

$${κ}_{zz} = {N}_{w} \frac{{τ ( {k}_{B} T )}^{4}}{2 {π}^{2} {ℏ}^{3} vT} {I}_{4} = {N}_{w} \frac{7 {π}^{2}}{30} \frac{τ {k}_{B}^{4}}{{ℏ}^{3} v} {T}^{3} \qquad Eqn . 50$$

$${σ}_{zz} = {N}_{w} \frac{{e}^{2} τ}{2 {π}^{2} {ℏ}^{3} v} {( {k}_{B} T )}^{2} {I}_{2} = {N}_{w} \frac{1}{6} \frac{{e}^{2} τ {k}_{B}^{2}}{{ℏ}^{3} v} {T}^{2} \qquad Eqn . 51$$

$${α}_{zz} = {N}_{w} \frac{e τ}{2 {π}^{2} {ℏ}^{3} v} {( {k}_{B} T )}^{3} {I}_{3} = 0 \qquad Eqn . 52$$

The Lorentz ratio can then be given by:

$$L = {( \frac{{k}_{B}}{e} )}^{2} [ \frac{{I}_{4}}{{I}_{2}} ] = \frac{7 {π}^{2}}{5} {( \frac{{k}_{B}}{e} )}^{2} \qquad Eqn . 53$$

Thus, in an ideal Weyl semimetal at zero field, the Lorenz ratio is a constant, but deviates from the free-electron value. However, in the extreme-quantum limits, Lorenz ratio recovers the free-electron value.

These above conclusions are based on the fact that the Fermi integrals can be solved analytically in each of the described cases. This is unlike the case of the factor π²/3 that shows up in the Mott relation for the thermopower of degenerate semiconductors and metals. There, it is the result of a Bethe-Sommerfeld expansion.

Section 2 Using a Modified Virtual Crystal Approximation Model to Calculate the g-Tensors, and Experimental Validation.

The evolution of Bi₁₋ₓSbₓ alloys shown in FIGS. 16-25 is based on calculations made using the tight-binding model. As explained above, in the absence of a magnetic field, Bi₁₋ₓSbₓ alloys are conventional semimetals for x<~7.7% and become topological insulators for x>8.8%. In a trigonal magnetic field H_{z}∥(001), the direct band gap at the L-point of the Brillouin zone is calculated to first close with increasing H_{z}, then invert at high values of H_{z}, forming a Weyl semimetal.

We can check qualitatively the closing of the direct energy gap at the L-point in the magnetic-field range where Bi₈₉Sb₁₁ is a semiconductor by measuring the magnetic field-dependent Hall concentration as a function of temperature. For Hall resistivity, we use the notation ρ_{xy}(H_{z}), where x is the index of the direction of the voltage measured, y is the direction of the applied current, and z is the direction of the applied magnetic field. Here, we measure ρ_{xy}(H_{z}) with x along the binary direction (100), y along the bisectrix direction (010), and z along the trigonal direction (001). This approach only holds when the Hall effect measurement correctly represents the excess carrier concentration, the difference between the density of electrons and that of holes, i.e., when:

$$n ( T , {H}_{z} ) = \frac{1}{e ( \frac{d {ρ}_{xy} ( {H}_{z} )}{{dH}_{z}} )} \qquad Eqn . 54$$

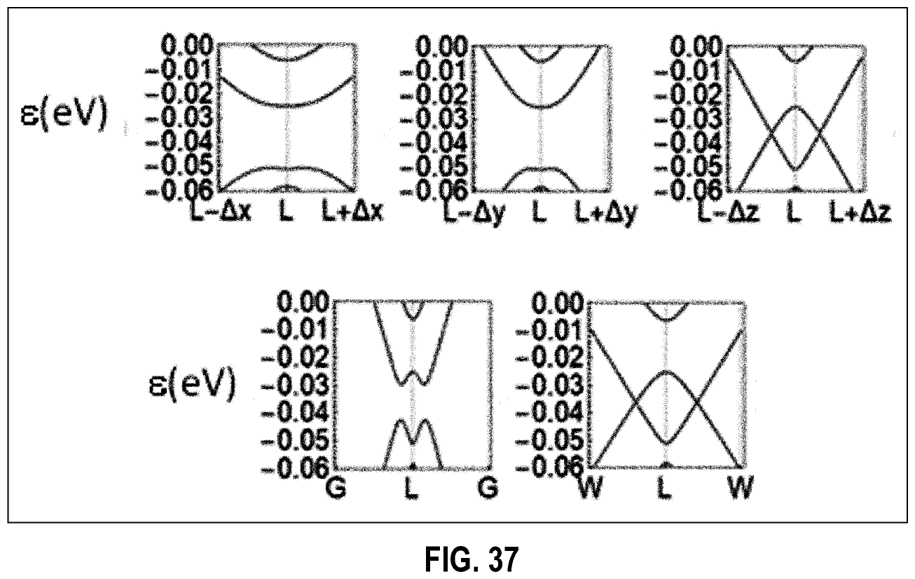

This approach does not hold when the Hall effect becomes dominated by multi-carrier effects, which occurs in the presence of both electrons and holes in near-equal concentrations. Here, this is the case either in the semi-metallic regime at higher magnetic fields, or once the temperature is high enough that the material becomes a semiconductor with thermally excited intrinsic electrons and holes. This becomes the case at fields above about 0.5 tesla and when E_{g}(H_{z})<k_{B}T. Measurements of ρ_{xy}(H_{z}) at μ₀H_{Z}<0.047 tesla are used with Equation 54 to calculate the concentrations and mobilities shown in FIGS. 26 and 27, and as reported in Table 1. Here, in contrast, values for n(T,H_{z}) derived from Equation 54 at various values of H_{z} are plotted versus 1/T in FIG. 38 (top graph). An Arrhenius function,

$$n ( T , {H}_{z} ) = {n}_{0} ( {H}_{z} ) e - \frac{{E}_{a} ( {H}_{z} )}{{k}_{B} T} \qquad Eqn . 55$$

can be fit through the data between 60 K and 100 K, giving a field-dependent value for the thermal activation energy Eₐ(H_{z}). The resulting values are shown in FIG. 38 (bottom graph), which displays a clear decrease in Eₐ with field H_{z}. The band calculations predict Eₐ, which is related to E_{g}, to decrease linearly with H_{z} since the gap closing is due to a Zeeman energy term. While the decrease is observed, the linearity with H_{z} is not. This is because with increasing H_{z}, the Hall data include more multi-carrier effects and Equation 54 becomes less accurate. Nevertheless, FIG. 38 shows that the gap closes with H_{z}.

### Section 3 the Berry Curvature Calculation, the Fukui Method, and the Location of Weyl Points in the Brillouin Zone.

The Berry curvature Ωₙ(k)=∇ₖ×Aₙ(k) is a gauge-invariant geometric quantity that can be obtained from the Berry connection Aₙ(k)=i [symbol] n(k)|∇ₖ|n(k) [symbol] , which is the analog of the electromagnetic vector potential. Two Weyl points each carry the Berry curvature of a monopole Ω(k)=χk/k³ with opposite chirality of χ=±1. The Chern number γₙ is obtained by integrating the Berry curvature (γₙ=∫dS·Ωₙ(k)) over a closed surface (the Brillouin zone), and is related to the Berry phase γₙ through the relation cₙ=γₙ/2π. A numerical calculation of the Chern numbers is carried starting from a multiplet of wave vectors ψ=(|n₁ [symbol] , . . . , |n₁₀ [symbol] ), eigenfunctions of H. The Berry curvature \tilde{F} may be calculated to make the distinction between the discretized \tilde{F} and the Berry curvature Ω in continuum.

The discretized Chern number \tilde{c}ₙ=(2πi)⁻¹>Σ1\tilde{F}(kₗ) of n^{th} band is determined from \tilde{F}, and the total Chern number is obtained by summing the Chern numbers of all filled bands up to n=10. Numerically, this is done by integrating \tilde{F} in the (G₁, G₂) plane (FIG. 25) while sweeping along the G₁ axis. An integer change in the Chern number, which constitutes the evidence for a change of the topology and existence of the Weyl points, is detected in a pair of points separated symmetrically near each L-point in the 3D Brillouin zone (FIG. 25). Weyl points are located by determining the locations of the Berry curvature monopoles and nodes with opposite chirality χ=±1. The position of the monopoles is given schematically in FIG. 25 and precisely hereunder. To find the monopoles of Berry curvature, i.e. the Weyl points, we determine the distribution of Berry curvature in k-space. This is done most efficiently using the Fukui numerical method described in the following steps:

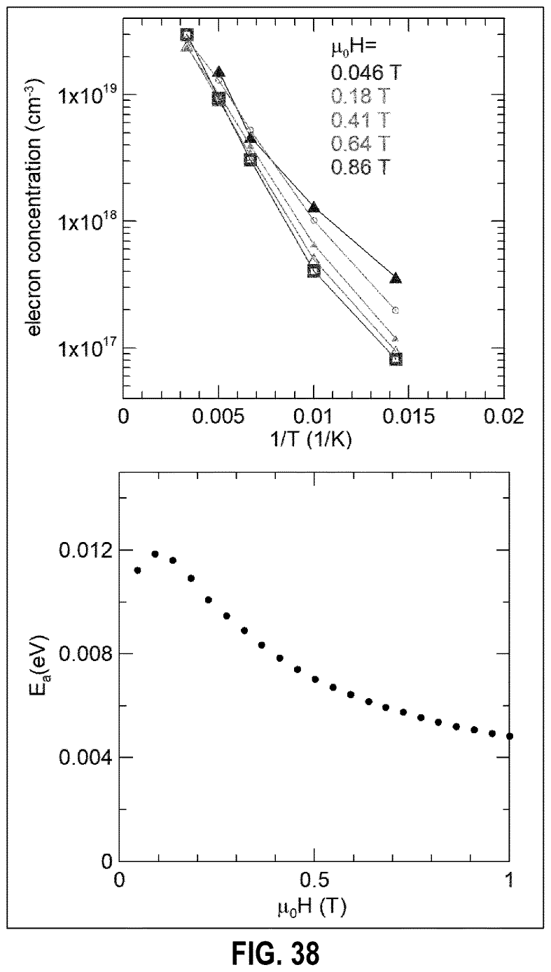

Step 1: Using the reciprocal lattice vectors G=(G₁, G₂, G₃) along the Γ-L lines shown in FIG. 39 as a reference frame, we fix the fraction along the direction G₃−k₃·G₃ where k3∈[0,1], and discretize the two-dimensional Brillouin zone spanned by reciprocal lattice vectors (G₁′ G₂) into small δG₁′ δG₂ patches, where {k₁} are the k-points.

Step 2: Next, we calculate the Berry flux through each small patch as:

$$\tilde{F} ( {k}_{l} ) = ln {U}_{1} ( {k}_{l} ) {U}_{2} ( {k}_{l} + δ {G}_{1} ) {U}_{1}^{- 1} ( {k}_{l} + δ {G}_{2} ) {U}_{2}^{- 1} ( {k}_{l} ) \qquad Eqn . 56$$

where Uᵢ(kₗ) is a link variable, which gives the phase acquired by the wave function of the nth band as an electron moves from kₗ to kₗ+δGᵢ given by: (index i=1, 2)

$${U}_{i} ( {k}_{l} ) = \frac{det {ψ}^{†} ( {k}_{l} ) ψ ( {k}_{l} + δ {G}_{i} )}{\vert det {ψ}^{†} ( {k}_{l} ) ψ ( {k}_{l} + δ {G}_{i} ) \vert} \qquad Eqn . 57$$

Step 3: Finally, we compute the sum of the Berry flux through each patch to obtain the lattice Chern number for the nth band: \tilde{c}ₙ=(2πi)⁻¹Σ1\tilde{F}(kₗ).

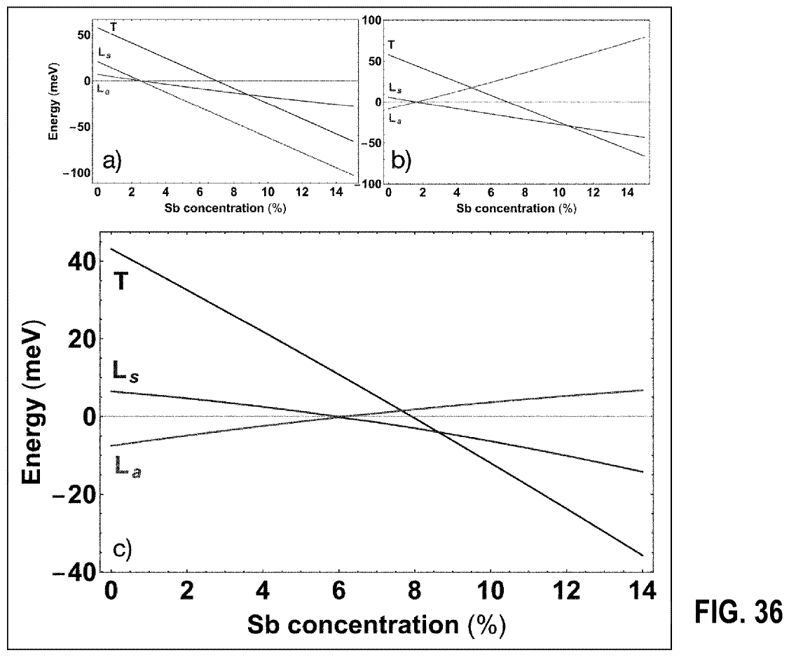

The Weyl points are centered around the L-points of the Brillouin zone. The separation found from the Berry curvature plot (see FIG. 25 and FIG. 37) is mainly along field direction (z), with a minor contribution along the Γ-L direction. The coordinates for the separation (½ on either side of each L-point) at H_{z}=8 tesla for the upper half of the Brillouin zone are: (0.678, 0.520, 0.520), (0.520, 0.678, 0.520), (0.520, 0.520, 0.678), in the G=(G₁, G₂, G₃) axis system, where (0, 0, 0) is the Γ-point and (0.5, 0, 0) is the L-point along G₁.

### Section 4: Single-Crystal Growth and Structural Characterization.

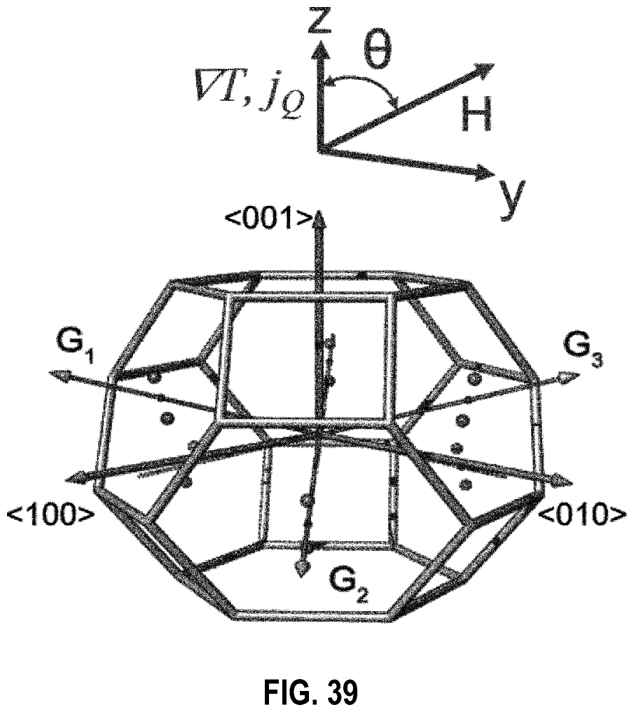

FIG. 40 illustrates the principle of the travelling molten zone (TMZ) single crystal growth technique in binary phase diagram of Bi—Sb alloys. The travelling molten zone growth technique of growing a crystal of uniform composition xₛ consists of moving a liquid zone of composition x_{L} across the crystal. The charge from which the single crystal is grown also has the composition xₛ. The end of the charge from which the liquid zone is started has the composition x_{L} even when solid.

### Crystal Growth

High-quality, single crystals of Bi—Sb alloys were grown by the travelling molten zone technique, which is specifically designed to grow crystals with uniform compositions of alloys that form solid solutions, but have very large segregation coefficients, as is the case for the Bi₁₋ₓSbₓ system. The basic principle is to create a crystal at the composition of the solidus (xₛ) from a charge that also has the composition of the solidus xₛ, by melting only a small section of the charge that has the composition of the liquidus (x_{L}) at the melting point and moving that molten section across the charge (see FIG. 40). To obtain a crystal of Bi₈₅Sb₁₂ (xₛ=0.12), the composition of the molten zone was maintained at the Bi₉₇Sb₃ composition (x_{L}=0.03). The bulk of the charge was a Bi₈₅Sb₁₂ polycrystal, but the leading end, calculated to have the same volume as the molten zone, was a Bi₉₇Sb₃ polycrystal. According to the binary phase diagram of Bi—Sb, with the Bi₉₇Sb₃ liquid composition, solid Bi—Sb alloys will start to precipitate out of the liquid phase at the trailing end of the molten zone with a solid-phase composition of Bi₈₈Sb₁₂. The starting materials (99.999% pure Bi and Sb) were purchased, and in-house Bi zone-refinement applied before use to obtain crystals with a low-temperature residual charge-carrier concentration <10¹⁷ cm⁻³. The traveling speed of the molten zone was set to 1 mm/hour to ensure equilibrium cooling conditions and to avoid coring. The growth apparatus was horizontal with a free top surface to accommodate expansion of the alloys upon solidification.

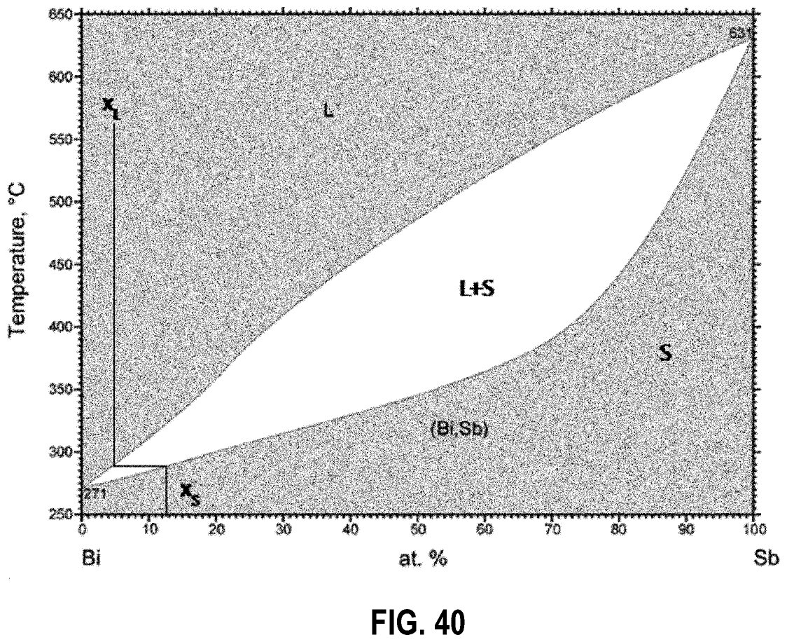

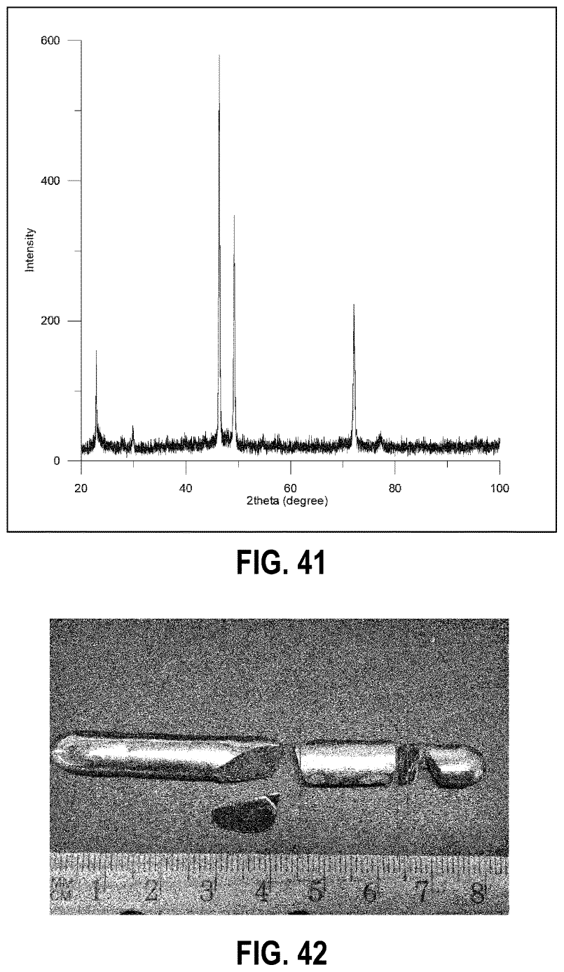

FIG. 41 illustrates the X-ray diffraction spectrum of the for a travelling molten zone crystal of Bi₈₉Sb₁₁, and FIG. 42 depicts the crystal itself. In practice, while the target composition was x_{S}=12%, the resulting single crystal had a composition of approximately x=11%, with an uncertainty and non-uniformity (see below) of composition of 1% over the whole length (80 mm) of the crystal. This length was much longer than the samples used for the measurements (typically 5×2×1 mm). The Bi₉₅Sb₁₅ crystal was grown using two travelling molten zone passes, under the same circumstances, except that the liquid phase composition contained x_{L}=5.8% Sb and the bulk of the charge was a Bi₈₄Sb₁₆ polycrystal (x_{S}=16%).

The Bi₉₅Sb₅ semimetal crystal was grown in-house by the Bridgeman technique. A charge with the composition of the liquidus x_{L}=5% was created by melting a solid mixture of high-quality elemental bismuth and antimony at the desired % in a furnace at 700° C. The liquid was then cooled to 350° C. The liquid mixture was cooled slowly at rate of 0.1° C./min from 350° C. to 200° C. in a temperature gradient induced by natural convection inside the furnace. The temperature gradient cause solid Bi—Sb alloys to start to precipitate out of the liquid phase at the colder end with a solid-phase composition of x_{S}>x_{L}. As the furnace temperature drops and more solid single crystal forms, the liquidus composition xs also drops, creating a composition gradient along the length of the crystal. Slices were cut along the length of the crystal and compositions checked by X-ray fluorescence.

### Crystallography

Referring again to FIGS. 41 and 42, the travelling molten zone single crystals were cleaved revealing shiny, metallic cleavage surfaces. Single-crystal flakes from the cleaved surfaces were collected at the positions marked in FIG. 42 on the crystal for characterization using X-ray diffraction (XRD). Si powder was sprinkled on the sample holder and leveled with the exposed surface of the flakes to serve as calibration peaks in the spectrum result shown in FIG. 41. The cleaved surface was confirmed to be the (001) plane. The Si lines were used to correct small misalignments between sample and XRD spectrometer. These corrections affect the [003] peaks the most, and the [006] peaks, to which they were closest, the least. Therefore, the following calculations (Table 3) used only [006] and [009] peaks. The composition at each measured position shown by FIG. 42 was calculated by interpolating the measured lattice spacing c (Table 3) in the (001) direction with respect to the reported variation of lattice spacing of Bi—Sb alloy in literature. The accuracy of the measurement of x is the composite of the measurement accuracy (0.49%) and the possible variation in composition across the sample. The latter is approximately 0.1% since the measured sample is 2 mm wide, with a non-uniformity of 1% observed across a 20 mm piece of crystal. The final composition at each position on the sample was 10.5±0.5%, which is rounded off to Bi₈₉Sb₁₁. The difference between the composition aimed for with the travelling molten zone charge (12%) and that obtained (11%) was close to the standard deviation of the measurements.

TABLE 3
Uniformity analysis, Bi₈₉Sb₁₁ TMZ crystal
Starting end:

| | | | | | |
|---|---|---|---|---|---|
| Si 111 | 28.4 | shift | −0.032 | c (A) | x (%) |
| Bi 003 | 22.59 | corrected | 22.622 | 11.78223 | 15.64 |
| Bi 006 | 46.05 | corrected | 46.082 | 11.80869 | 10.51 |
| Bi 009 | 71.87 | corrected | 71.902 | 11.80852 | 10.55 |
| | | | | Mean | 10.53 |
| | | | | (006, 009) | 0.02 |
| | | | | St. deviation | |

Measured sample (adjacent to starting end):

| | | | | | |
|---|---|---|---|---|---|
| Si 111 | 28.39 | shift | −0.042 | c (A) | x (%) |
| Bi 003 | 22.55 | corrected | 22.592 | 11.79767 | 12.65 |
| Bi 006 | 46.05 | corrected | 46.092 | 11.80627 | 10.98 |
| Bi 009 | 71.84 | corrected | 71.882 | 11.81136 | 10 |
| | | | | Mean | 10.49 |
| | | | | (006, 009) | |
| | | | | St. deviation | 0.49 |

Finishing end:

| | | | | | |
|---|---|---|---|---|---|
| Si 111 | 28.41 | shift | −0.022 | c (A) | x (%) |
| Bi 003 | 22.57 | corrected | 22.592 | 11.79767 | 12.65 |
| Bi 006 | 46.04 | corrected | 46.062 | 11.81354 | 9.57 |
| Bi 009 | 71.83 | corrected | 71.852 | 11.81563 | 9.17 |
| | | | | Mean | 9.37 |
| | | | | (006, 009) | |
| | | | | St. deviation | 0.2 |

Single-crystal flakes from the cleaved surfaces of the Bi₈₅Sb₁₅ crystal were collected at positions near the two ends, 45 mm apart, of the crystal for characterization using electron dispersive spectroscopy. The atomic percentage of Bi and Sb at each position is summarized in the Table 4. The characterization measurement accuracy is 0.7% with non-uniformity of less than 2% observed across 45 mm. The sample used for transport measurements is adjacent to the sample collected at the starting end of the crystal which has composition rounded to Bi₈₅Sb₁₅.

TABLE 4
Uniformity analysis, Bi₈₅Sb₁₅ TMZ crystal

| | Net | | Error |
|---|---|---|---|
| Element | Intensity | Atomic % | (%) |
| Starting end of the Bi₈₅Sb₁₅single crystal, from which | | | |
| the measured sample was cut | | | |
| Bi | 56575.3 | 84.88 | 1.1 |
| Sb | 3462.3 | 15.12 | 4.8 |

Finishing end of the single crystal

| | | | |
|---|---|---|---|
| Bi | 57888.6 | 82.93 | 1.11 |
| Sb | 4121.6 | 17.07 | 4.73 |

The Bridgeman single crystal was cleaved revealing shiny, metallic cleavage surfaces. The crystal was cut into slices perpendicular to the cleavage surfaces. Composition of each slice was checked by X-ray fluorescence. The composition of the measured sample was 5±0.5% The uniformity was checked by interpolating the compositions of adjacent slices which vary from 4.4±0.5% to 5.4±0.5% across a 4 mm distance on the crystal, resulting a uniformity of better than 0.5% across the sample size.

### Section 5: Sample Characterization: Hall Effect, Magnetoresistance and Thermal Conductivity.

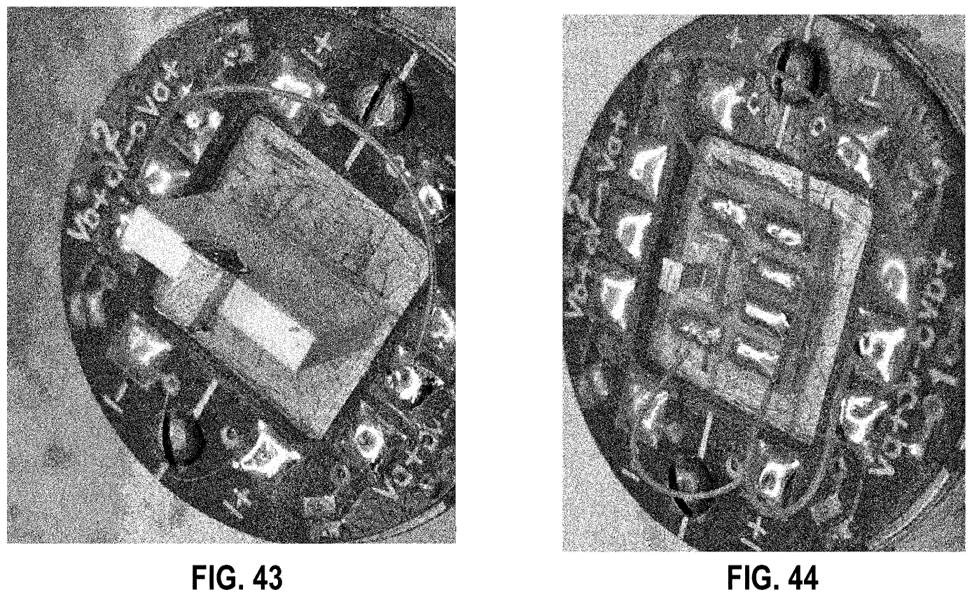

FIGS. 43 and 44 illustrate the isothermal resistivity, magnetoresistance, and Hall measurement setup. FIG. 43 depicts the Hall and magnetoresistance setup for isothermal measurements in a transverse magnetic field, and FIG. 44 depicts the setup for magnetoresistance measurements in a longitudinal magnetic field.

### Sample Mount and Error Bars

As described above, five samples originating from three separate single crystals were studied for thermal conductivity. Sample #1 originated from the travelling molten zone growth of composition Bi₈₉Sb₁₁. Samples #2, #3 and #4 originated from the Bi₈₅Sb₁₂ Czochralski crystal growth by Jacobus Meinhard Noothoven van Goor. Sample #5 originated from the travelling molten zone growth of composition Bi₈₅Sb₁₅. One additional sample (other than those used for thermal conductivity measurements, and on which no electrical contacts were made) from each crystal was subjected to electrical measurements.

The isothermal resistivity and Hall resistivity were measured along the (001) axis of separate samples cut from both the travelling molten zone crystal and the Czochralski crystal using standard Hall bar-geometry setup (5-point probe method), with the magnetic-field direction perpendicular to the electric-field direction. As depicted by FIGS. 43 and 44, the sample was mounted on a boron nitride block that is electrically insulating, but thermally conducting. This was done to keep the temperature gradient along the length of the sample negligible, thus negating the effect of secondary Seebeck voltage and ensuring isothermal measurement conditions. Electrical probing contacts were made with 25 μm copper wires that were spot welded to the sample. Electrical current contacts were made using a current spreader and electrically contacted to the sample with a thin layer of silver epoxy to create an even distribution of current lines. Longitudinal magnetoresistivity was measured on the samples along the (001) crystal axis with the direction of the magnetic field parallel to the electric field. Measurements were conducted at discreet temperature points between 10 K and 300 K. The sample was stabilized thermally at each temperature point for 30 minutes before each measurement was started. Electrical measurements were conducted with direct current and sweeping-down magnetic field from a maximum field of 9 tesla to a minimum field of −9 tesla in a Quantum Design Physical Property Measurement System with a sweeping rate of 5 mT/s. Controls software was programmed using LabVIEW.

The error in the high-field Hall and resistivity measurements (i.e., when the product of the mobility times the field is larger than unity, or H>5 mT at 10 K or 50 mT at 100 K) in the transverse magnetic-field setup comes from the geometric effect. Since the sample is short (L/W ratio is approximately 1.8), at higher field (i.e. μₘₒB>1), the effect of distorted current lines could lead to an underestimation of Hall resistivity by as much as 5 to 10%, as reported in literature.

### Low-Field Transverse Measurements: Zero-Field Resistivity, Low-Field Hall, Carrier Concentration, and Mobility

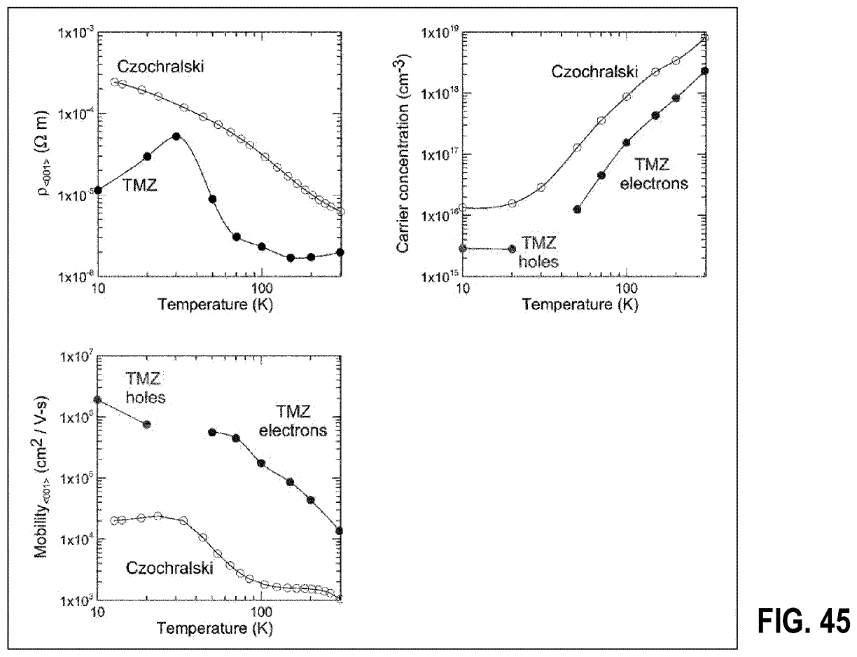

The low-field (i.e., H<5 mT at 10 K and <50 mT at 100 K) Hall coefficients of Bi₈₉Sb₁₁ (both travelling molten zone and Czochralski) and Bi₉₅Sb₁₅ were measured and converted into a carrier concentration. The low-field mobility was then derived from the resistivity and this carrier concentration. The results are given for both travelling molten zone samples in FIGS. 26-28. FIG. 45 depicts graphs contrasting the data on the travelling molten zone and Czochralski samples of composition Bi₈₉Sb₁₁. The analysis of the data at higher field is described above in Section 2.

FIG. 45 illustrates the temperature dependence of the Bi₈₉Sb₁₁ resistivity, Hall carrier concentrations, and mobilities along the trigonal direction of a separate sample of the Czochralski crystal (solid markers—top left graph) which remains n-type, and of the TMZ crystal which is n-type above 50 K (solid markers—top left and bottom right graphs) but becomes p-type below 52 K (open markers). The Bi₈₉Sb₁₁ travelling molten zone crystal had an electron density and mobility of 2.3×10¹⁸ cm⁻³ and 13,700 cm²V⁻¹s⁻¹ at 300 K, and 1.2×10¹⁶ cm⁻³ and 559,000 cm²V⁻¹s⁻¹ at 50 K. Below 50 K, the polarity of the Hall effect switched from n-type to p-type, with a concentration and mobility of 3×10¹⁵ cm⁻² and 1,900,000 cm²V⁻¹s⁻¹ at 10 K, indicating an almost complete freeze-out of the charge carriers. A similar behavior is observed in the travelling molten zone-Bi₈₅Sb₁₅ sample, as reported in FIGS. 26-28. The Bi₈₈Sb₁₂ Czochralski crystals had electron densities and mobilities of 8×10¹⁸ cm⁻³ and 1,050 cm²V⁻¹s⁻¹ at 300 K, which froze out to 1.4×10¹⁶ cm⁻³ and 20,000 cm²V⁻¹s⁻¹ at 12 K. The increase in magnetothermal conductivity κ_{zz}(H_{z}) observed on two such vastly different crystals, with low temperature mobilities varying by a factor 100, demonstrates the robustness of the main result to disorder scattering.

### High-Field Longitudinal Magnetoresistance Effect and Error Analysis

As outlined in the above, the longitudinal magnetoresistance measurements on Weyl semimetals, which generally have electrons of very high mobility, can contain extrinsic signals unless care is taken in sample preparation, dimensions, and alignment. The extrinsic signals can be generated in three ways: current jetting, the galvanomagnetomorphic effect, and the geometric magnetoresistance. Current jetting and the galvanomagnetomorphic effect give rise to an extrinsic negative longitudinal magnetoresistance, the same sign as would the chiral anomaly. The galvanomagnetomorphic effect is not likely to occur in our samples because their dimensions are orders of magnitude larger than the Larmor radius of the electrons in fields above 1 T, and because the data disclosed above show the transport to be robust to defect scattering, so that it likely also robust to surface scattering. Current jetting is minimized and checked for by keeping sample dimensions small and placing the voltage contacts at different locations, looking for variations.

The geometric magnetoresistance gives rise to an extrinsic positive magnetoresistance, and arises either when the sample surface is not smooth, or when the field is slightly misaligned with respect to the current flow lines in the sample, as can occur during sample mounting. This is the main cause of difficulties in the present measurements of longitudinal magnetoresistance. The positive geometric magnetoresistance is given, in general, by

$${ρ}_{Geom} = ρ ( 1 + A {μ}_{mo}^{2} {B}_{⊥}^{2} )$$

and the relative correction for the positive geometric magnetoresistance is:

$$\frac{Δ {ρ}_{Geom}}{ρ} = A {μ}_{mo}^{2} {B}_{⊥}^{2} \qquad Eqn . 58$$

where B_{⊥}=μ₀H_{⊥} is the magnetic induction in the direction perpendicular to the current, μₘₒ the mobility, and the pre-factor A depends on the ratio between the length of the sample (along the current flow direction) to the width of the sample. The pre-factor varies from A=1 for a Corbino disk geometry, to A=0 for an infinitely long and thin sample. For the geometries of concern here, there is an uncertainty of almost a factor of 2 on A between the experimental values reported by Weiss and Welker on InSb and the calculated values from Wick. We therefore cannot use these estimates to calculate a correction term for the magnetoresistance, so we use A only to calculate an error bar. We adopt the Weiss & Welker values, taking A=0.05 for a length-to-width ratio near 10:1. In longitudinal measurements \vec{B} is in theory parallel to the current direction, but in practice field misalignment by an angle θ generates a transverse component B_{⊥}=|\vec{B}| sin θ to the magnetic field vis-à-vis the current lines, so that the Lorenz force distorts them. The relative error bar on longitudinal magnetoresistance measurements is

$$\frac{Δ {ρ}_{Geom}}{ρ} = A {μ}_{mo}^{2} {B}^{2} {sin}^{2} ( θ ) \qquad Eqn . 59$$

In some samples, this error is the main source of error in determining the Lorenz ratio because it affects the electrical resistivity measurements. However, this error much less the thermal conductivity ones for the reasons outlined above. In sample #6, however, the error provided by Equation 59 is minimized, and the main source of error on the Lorenz ratio at T>60K comes from thermal conductivity measurements as described in Section 10, below.

### Czochralski Samples

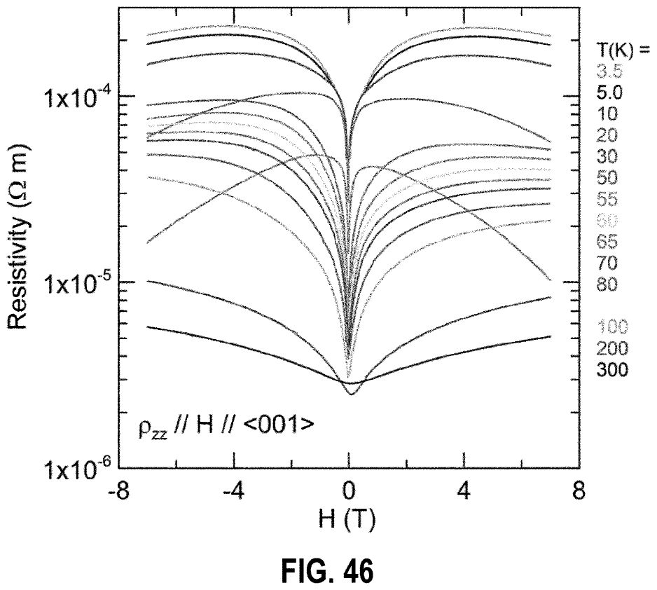

FIG. 46 illustrates the longitudinal magnetoresistance along the trigonal direction of Czochralski sample #3 as a function of magnetic field at the temperatures indicated. Van Goor reports that the magnetoresistance of Czochralski samples is dominated by the extrinsic geometric magnetoresistance due to striations in the sample. The negative magnetoresistance is only discernable at the lowest temperatures. Data such as these cannot be used to verify the Wiedemann-Franz law. Magnetoresistance measurements of the Czochralski crystals contain an additional extrinsic component, which has been identified by Noothoven van Goor. Their surfaces display small striations in which the current lines are not exactly aligned with respect to the magnetic field. The striations arise because the rotation during the Czochralski growth method results in annular irregularities along the sample length, some 0.05 mm deep on a 3 mm diameter sample. Noothoven van Goor shows how these slight irregularities in the sample surface are sufficient to generate an extrinsic geometric magnetoresistance. FIG. 46 illustrates that the longitudinal magnetoresistance of Czochralski Bi₈₅Sb₁₂ crystal sample #3 is uniformly positive at T>40 K, where the increase in κ_{zz} in response to changes in the magnetic field is observed. At lower temperature and higher field, the sample develops a negative magnetoresistance. Due to the difficulties described above, where extrinsic effects can induce either a striation-induced positive or a current jetting-induced negative magnetoresistance, we were unable to attribute either behavior to intrinsic properties of the samples. We were also unable to verify the Wiedemann-Franz law experimentally in a magnetic field on samples with irregular sides.

### Travelling Molten Zone Samples

Since both Bi₈₉Sb₁₁ travelling molten zone samples have a high mobility (up to 2×10⁶ cm²V⁻¹s⁻¹ at 10 K), the extrinsic positive geometric magnetoresistance that can arise may become an order of magnitude larger than the intrinsic (negative) sample magnetoresistance unless care is taken in sample preparation and alignment.

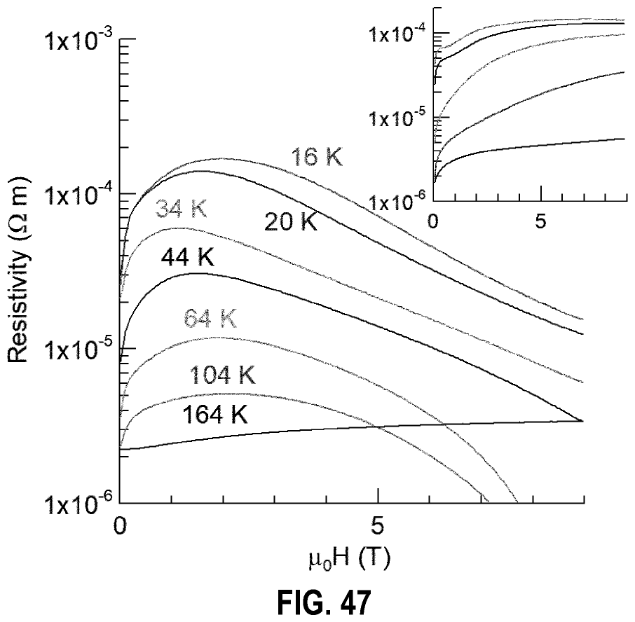

FIG. 47 illustrates the effect of sample geometry on the longitudinal magnetoresistance measurements of the TMZ sample #1. The main frame shows the longitudinal magneto-resistivity ρ_{zz}(H_{z}) of sample #1 after thinning the sample to dimensions of 1.7×1.39×0.52 mm. The alignment of the longitudinal axis with the magnetic field of the order 0.15±0.05°. The insert shows ρ_{zz} (H_{z}) of the same sample, but with sample dimensions of 3.35×1.43×1.64 mm, and the alignment of the longitudinal axis with the magnetic field of order 3.8°. For sample #1, the longitudinal magnetoresistance is given for the same sample in two different geometries. A field misalignment angle θ=3.8 degrees completely eliminates the negative magnetoresistance. No attempts were made to use the electrical data of the 3.35×1.43×1.64 mm sample in any subsequent analysis. The thinned down sample, which was realigned with a field misalignment angle θ=0.15 degree, displays a negative magnetoresistance with an error bar that is described below.

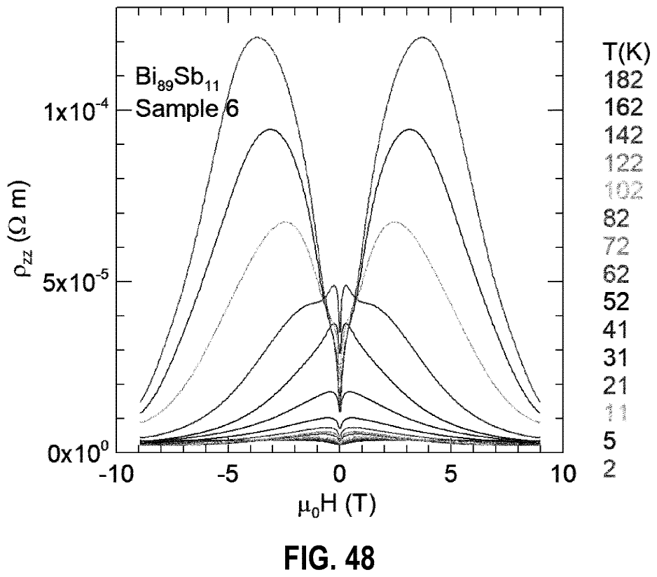

Sample #6 was designed specially to minimize all extrinsic effects, as described in the methods section. The main difference is that mechanical thinning is supplemented by etching, resulting in a smooth surface. The dimensions of sample #6 are 3×0.4×0.6 mm and the misalignment angle was minimized to a field misalignment angle θ=0.1±0.05 degree by the following process. Two blocks of boron nitride ceramics were precision cut and glued to the base to serve as precise guides for the sample to stand upright on the platform, with the applied field of Quantum Design PPMS to be perpendicular to the platform. These guides constrain both degrees of freedom of sample misalignment. Once the sample was mounted to the platform with silver epoxy, solvents were used to dissolve the glue and the guides were removed. The precision of the guides and the final alignment were checked with goniometer (Wixey Model WT41) to be 89.9±0.05 degrees. The sample was mounted in a 4 probe geometry. The voltage wires were attached to the sample along the spine of the sample to minimize effect of current jetting. The voltage wires were attached to the sample with a significant distance from the current wires to avoid regions of large current line distortion. The measured resistivity ρ_{zz}(H_{z}) is shown in FIG. 33. The same data extended to 2 K is shown in FIG. 48. No quantum oscillations are observed even at 2 K, as expected from an ideal Weyl semimetal.

The relative errors in magnetoresistance measurements introduced by the geometry are examined next. The geometries are such that for the 3.35×1.43×1.64 mm sample #1, A~0.2 and field misalignment angle θ=3.8 degrees. For the 1.70×1.39×0.52 mm sample #1, A~0.25 and field misalignment angle θ=0.15 degrees. For sample #6, A~0.05 and field misalignment angle θ=0.1 degrees. At 60 K, the mobility of the travelling molten zone Bi₈₉Sb₁₁ crystal is of order of 50 m²V⁻¹s⁻¹. The relative errors for the three samples above are thus a factor of 70%, 11%, and 1% at 5 tesla, and a factor of 3 times higher at 9 tesla.

FIG. 48 illustrates longitudinal magnetoresistance of the travelling molten zone sample #6. The sample has dimensions of 3.0×0.4×0.6 mm, and the misalignment angle θ=0.1±0.05°. No quantum oscillations are observed down to 2 K. The error bars increase as the temperature is lowered below 60 K. At 10 K μₘₒ=2×10⁶ cm²V⁻¹ s⁻¹ and only sample #6 gives magnetoresistance data that are accurate within 50%. Accurate mobilities are not available in the 30 K to 60 K range, due to the polarity of the Hall effect changing in that range. Since the low-temperature mobility of charge carriers along the trigonal direction of Bi follows a T² law, it is reasonable to expect that the error bars increase with T⁴. Consequently, the determination of the absolute magnitude of the negative magnetoresistance (and thus the Lorenz ratio) cannot be made accurately below 60 K. At 50 K, the error bars given above have already doubled.

### Section 6: Error Analysis of Thermal Conductivity Measurements.

The thermal conductivity measurement error has a systematic component that dominates the absolute values of the conductivity reported, and a relative component that dominates the error bars in the temperature and field dependence. The systematic error in the absolute values is composed of a geometric error, an error in the estimate of the heat flux, and an error in thermocouple calibration. The uncertainty of the geometry of the sample is of the order of 10%. Heat losses were calculated from the measured heat leaks of the instrument, which vary with temperature, but are of the order of 1 mW/K at 300 K. Thus, heat losses were smaller than the thermal conductivity of the sample. Below 200 K, instrumental heat losses are negligible. The Cu-Constantan thermocouples were calibrated in magnetic field using the process described below and summarized in Table 5.

The sensitivity of Cu-Constantan thermocouples used in thermal conductivity measurements of this work has been checked experimentally. The Seebeck coefficients of constituent 25 μm diameter copper and Constantan (Ni—Cu alloy) wires used to fabricate the thermocouples were measured as follows: A temperature gradient was created along the length of a slender piece of glass with one end bonded to a resistive heat source and one end bonded to a heat sink. At steady-state condition, the heat sink temperature is controlled by the temperature controller of Quantum Design PPMS, and the heat flux was constant. At two specific points on the glass, where the ends of the sample wires were welded, temperatures of these points were measured with Cernox® temperature sensors that are calibrated in the temperature and field range of the experiment by Quantum Design. The voltage between two ends of the sample wires were measured with a Keithley nanovoltmeter. The measurements were conducted at discreet temperature points between 5 K to 300 K, in sweeping-down magnetic field from maximum field of 7 T to minimum field of −7 T in Quantum Design PPMS. Controls software was programmed using LabVIEW.

TABLE 5
The thermocouple calibration procedure.

| | S_{TC} at | Max. | Relative | S_{TC} | Deviation of |
|---|---|---|---|---|---|
| | zero | deviation | deviation | from | S_{TC} from |
| | field | of S_{TC} in field | of S_{TC} | NBS125 | NBS125 |
| T(K) | (V/K) | (V/K) | field (%) | (V/K) | (%) |
| 60 | 1.30E−05 | 1.33E−05 | 2.2 | 1.38E−05 | −5.8 |
| 40 | 9.42E−06 | 1.02E−05 | 8.1 | 1.02E−05 | −7.3 |
| 20 | 5.33E−06 | 5.83E−06 | 9.4 | 5.50E−06 | −3.0 |
| 10 | 2.44E−06 | 2.62E−06 | 7.3 | 3.03E−06 | −20 |

The calculated field dependence of Cu-Constantan thermocouples is the difference between columns 2 and 3, given in % in column 4.

The Seebeck coefficient of the sample wires may be calculated using the following formulas:

$${S}_{Cu} = \frac{{V}_{Cu}}{{τ}_{H - {T}_{C}}} - {S}_{M} \qquad Eqn . 60$$

$${S}_{Co} = \frac{{V}_{Co}}{{T}_{H} - {T}_{C}} - {S}_{M} \qquad Eqn . 61$$

where V_{Cu} and V_{Co} are the voltages measured between the two ends of sample wires, T_{H} and T_{C} are temperatures measured at the two ends of sample wires, and S_{M} is the Seebeck coefficient of the measuring circuit. Accordingly, we calculate the Seebeck coefficient of the Cu-Constantan couples using:

$${S}_{TC} = {S}_{Cu} - {S}_{Co} = ( \frac{{V}_{Cu}}{{T}_{H} - {T}_{C}} - {S}_{M} ) - ( \frac{{V}_{Co}}{{T}_{H} - {T}_{C}} - {S}_{M} ) = \frac{{V}_{Cu}}{{T}_{H} - {T}_{C}} - \frac{{V}_{Co}}{{T}_{H} - {T}_{C}} \qquad Eqn . 62$$

The resulting values are reported in Table 5.

The absolute values of the error, the deviation from NBS reported in the last column, is below 6% down to 60 K, where most of the data is plotted, but can reach 7% at 40 K, and up to 20% below 40 K. Below 20 K, the thermocouples lose their sensitivity, which makes the data noisy. As a result, the calibration errors can reach 20%, which affects the temperature dependence reported in FIG. 31. Combined with the geometric error, the total error at 20 K is 22%. For these reasons, absolute values for the thermal conductivity below 20 K are not depicted in FIG. 31. Above 60 K, the total error is 12%, but the relative error on the temperature dependence is below 6%.

The relative error in the magnetic-field dependence is dominated by the magnetic-field sensitivity of the thermocouples. The dependence on field up to 7 tesla was checked, is reported in Table 5, and is given as error bars in FIG. 30. This uncertainty is less than or equal to 2% down to 60 K, and less than 10% at 34 K, the lowest temperature where the electronic component of κ_{Ezz} is reported. Note that the error bar on the curve at 16 K in FIG. 30 is the only relative error that is relevant to the field dependence; the absolute error, which affects the zero-field value, is much larger and of the order of 25% (\sqrt{0.22²+0.1²}), as discussed above.

### Section 7: Thermal Conductivity κ_{zz} Measurements Along the Trigonal Direction.

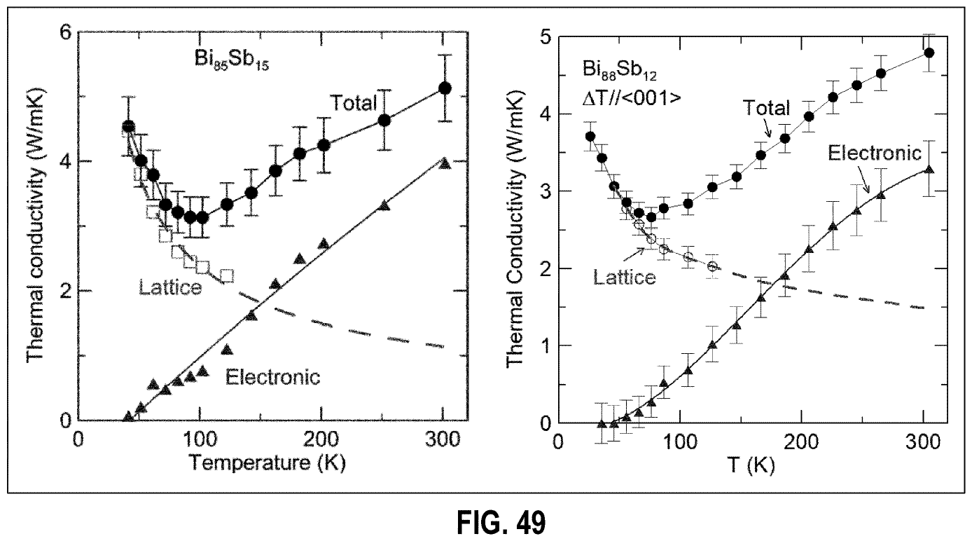

FIG. 49 illustrates the zero-field lattice and electronic thermal conductivity of the TMZ sample of Bi₈₅Sb₁₅ and of Czochralski Bi₈₈Sb₁₂ Sample #3. The error bars on the latter represent only the relative error, which is described in Section 9 above.

Zero-Field Conductivity κ_{zz} and its Electronic (κ_{E}) and Lattice (κ_{E}) Contributions

FIG. 28 shows the zero-field thermal conductivity of Bi₈₉Sb₁₁ sample #1. The equivalent figure for the travelling molten zone sample of Bi₈₅Sb₁₅ and of the Czochralski Bi₈₈Sb₁₂ sample #3 is given in FIG. 49. The thermal conductivity is separated into κ_{L} and κ_{E} by transverse thermal magnetoresistance measurements described below.

Longitudinal Magnetothermal Conductivity κ_{zz}(H_{z}): Sample-to-Sample Reproducibility

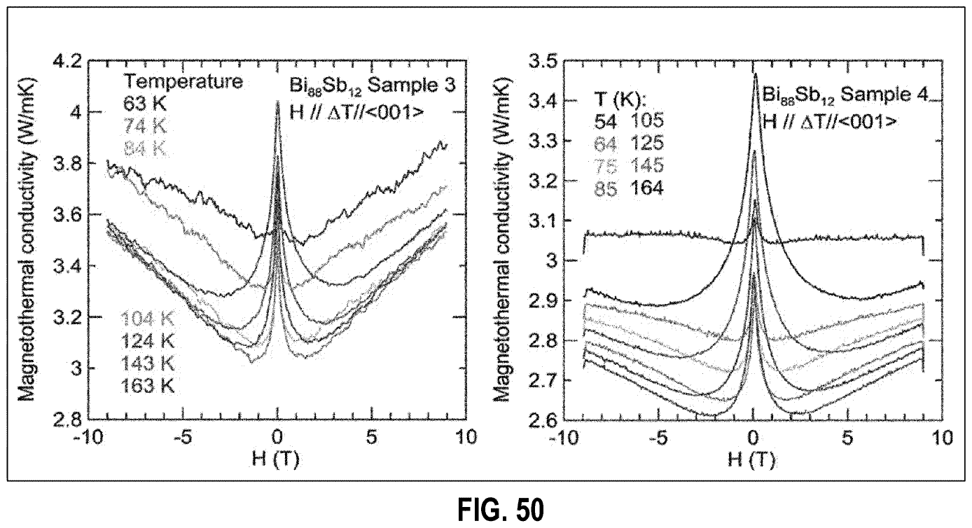

FIG. 50 illustrates the trigonal thermal conductivity in a longitudinal magnetic field for samples #3 and #4, which were cut from the Czochralski crystal. Besides the sample used for the transverse Hall measurements, three more samples were cut from the Czochralski crystal, with the data on two presented in this section. Sample #4 was subjected to a study of the angular dependence of the effect and the data are shown in Section 8 below. The zero-field κ_{zz} of sample #3 was analyzed again in terms of an electronic and lattice contribution, as had been done for sample #1. These results are shown in FIG. 49.

The κ_{zz}(H_{z}) data on samples #3 and #4 shown in FIG. 49 at zero magnetic field and with a magnetic field have curves are similar to those in FIG. 12. A region with dκ_{zz}/dH_{z}>0 is visible above a critical field, illustrating the robustness of the effect on impurity scattering, since these samples come from a crystal that has a mobility 100 times smaller than the travelling molten zone samples at 10 K. Czochralski sample #2 shows very similar data, and is described below.

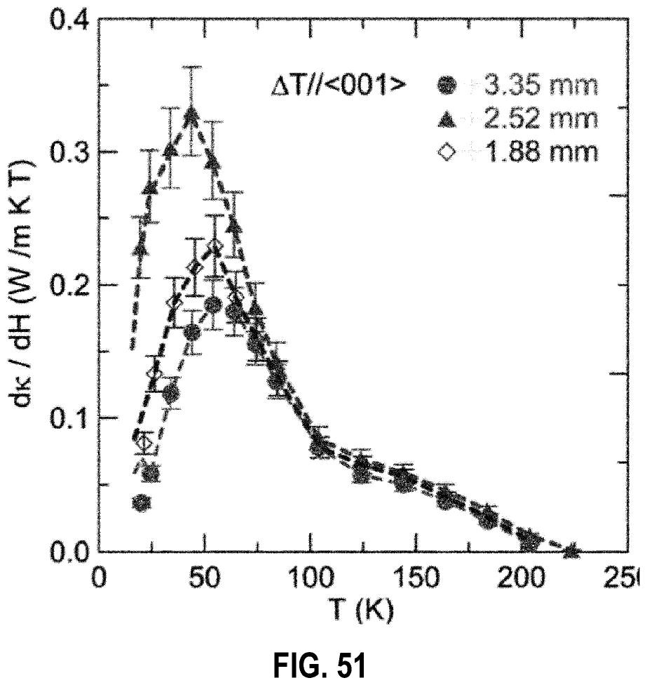

In addition, the sample length dependence of the dκ_{zz}/dH_{z} slope of the travelling molten zone Bi₈₉Sb₁₁ sample #1 was examined. The slope, taken at 4.5 tesla, is shown in FIG. 51. No length dependence is observed that is significantly above the error bars in the temperature range of the reported results (T>60 K).

Transverse Magnetothermal Conductivity κ_{zz}(H_{y}).

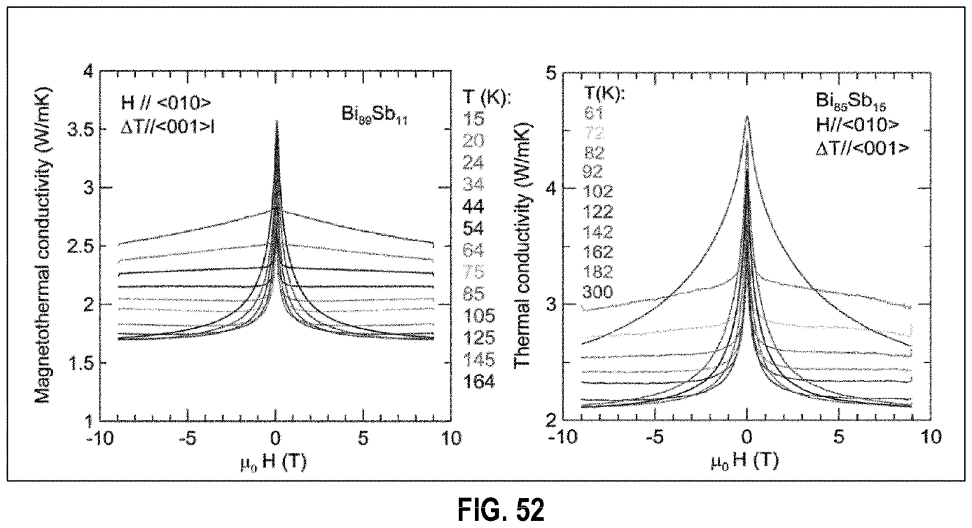

FIG. 51 illustrates the length dependence of the slope of magnetothermal conductivity κ_{zz}(H_{z}) of sample #1. No length dependence is observed experimentally. FIG. 52 depict graphs illustrating that applying a magnetic field H_{y} along the bisectrix direction y=(010) causes the thermal conductivity along the trigonal direction (magnetothermal conductivity κ_{zz}(H_{z})) to decreases monotonically. This is the ordinary behavior of high-mobility materials such as graphite and Bi and Bi₁₋ₓSbₓ alloys. It is used to isolate the lattice term as κ_{L}=lim_{Hy→∞}(κ_{zz}(H_{y})). The experimental data for κ_{zz}(H_{y}) saturates for T<120 K. The saturation value is labeled κ_{L} in FIG. 15 and “Lattice” FIG. 49. At T>120 K, the saturation of the magnetothermal conductivity κ_{zz}(H_{y}) is not achieved in the fields available, and the lattice conductivity κ_{L}(T) in FIG. 28 and FIG. 49 is extrapolated as a dashed line labeled as “Lattice” following a T^{-1/3} law 300 K. The electronic thermal conductivity κ_{E} is taken to be κ_{zz}=κ_{L}. FIG. 52 illustrates trigonal thermal conductivity in transverse magnetic field of TMZ samples Bi₈₉Sb₁₁ samples #1 and Bi₈₅Sb₁₅.

Section 8: Angular Dependence of Magnetothermal Conductivity κ_{zz}(H_{z})

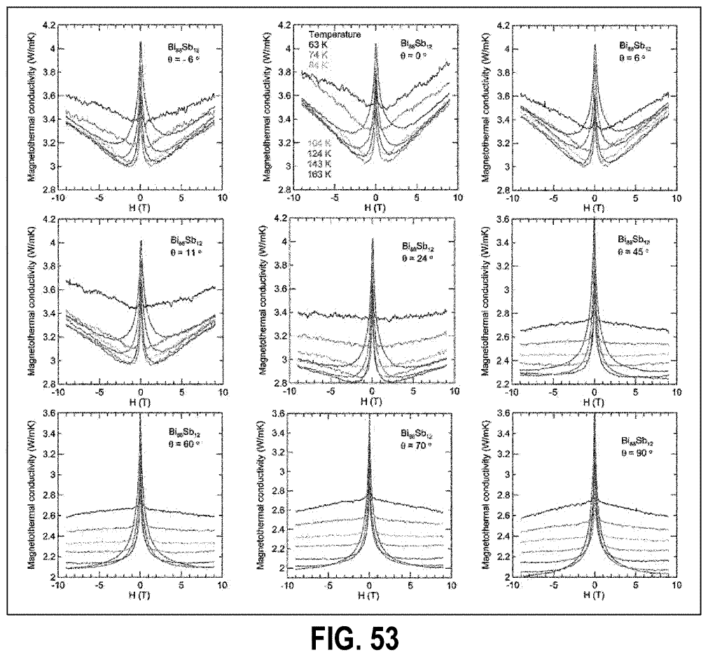

FIG. 39 illustrates the angle between the direction of the magnetic field H_{θ} and the trigonal axis along which κ_{zz}(H_{θ}) is measured. FIG. 53 illustrates the magnetothermal conductivity κ_{zz}(H_{θ}) of Czochralski sample #4 as a function of temperature and H_{θ} for the different values of θ.

The angular dependence of the effect was measured on sample #4. The magnetothermal conductivity κ_{zz}(H_{θ}) was measured as a function of temperature and magnetic field H_{θ} applied at an angle θ between the direction of field and temperature gradient in the trigonal direction (θ=0° for H_{θ}=H_{z} along (001) plane)/bisectrix direction (θ=90° for H_{θ}=H_{y} along (010) plane), as illustrated by FIG. 39. The data is shown in FIG. 53. The value Δκ_{E}=κ_{zz}(H=9T)−κ_{zz,MIN}, where κ_{zz,MIN} is the value of magnetothermal conductivity κ_{zz}(H_{θ}) at the magnetic field that produces minimum conductivity. Sample #2 at θ=0 again reproduces the data on samples #3 and #4 quite well.

Section 9: Test of κ_{zz}(H_{z}) for Surface Effect.

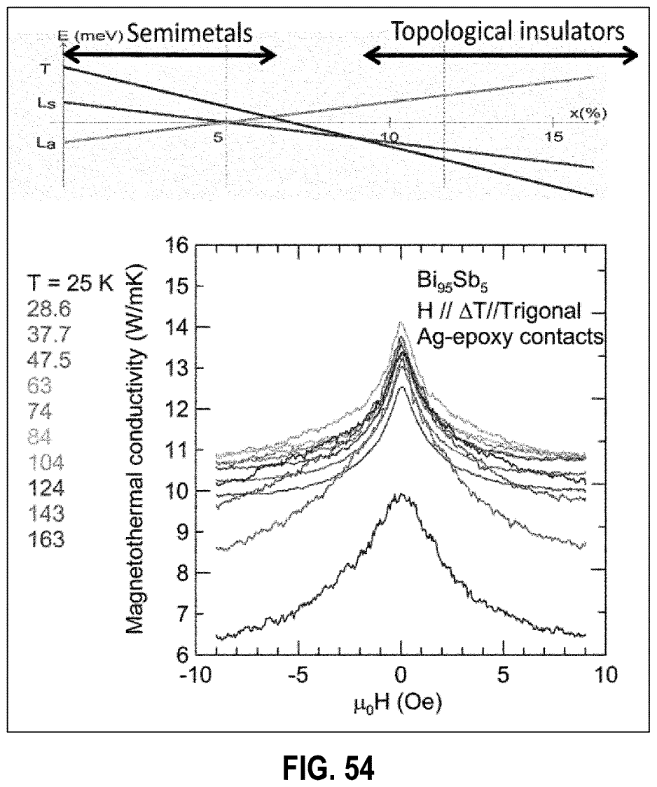

FIG. 54 illustrates the thermal conductivity κ_{zz} of Bi₉₅Sb₅ along the trigonal (z=(001)) direction, mounted with Ag-epoxy contacts. The results are the same as illustrated by FIG. 29 when this sample was mounted with electrically insulating contacts.

To test the hypothesis that the increase in thermal conductivity reported in FIGS. 30-32 is due to the Weyl nature of the Bi₈₅Sb₁₅ and Bi₈₉Sb₁₁ samples studied, the same experiments were carried out on semi-metallic samples of Bi₉₅Sb₅ that are not topological insulators at zero field, and thus do not move into the Weyl phase at high values of H_{z}. The magnetothermal conductivity κ_{zz}(H_{z}) of this Bridgeman sample is shown in FIG. 29, and shows dκ_{zz}/dH_{z}<0 for all magnetic fields, consistent with the thesis that dκ_{zz}/dH_{z}>0 is evidence for the chiral anomaly in the Weyl phase. In order to exclude further the possibility that the dκ_{zz}/dH_{z}>0 effect might be an extrinsic effect due to surface conduction, a second piece of the same crystal was mounted, this time with electrically conducting Ag-epoxy contacts on the top and bottom surface. The results were unchanged. This test was also repeated on a piece of the Bi₈₉Sb₁₁ crystal that showed the positive dκ_{zz}/dH_{z}>0, and again the Ag coating on the surface had no effect.

### Section 10: Reproducibility of the Verification of the Wiedemann-Franz Law on a Second Sample.

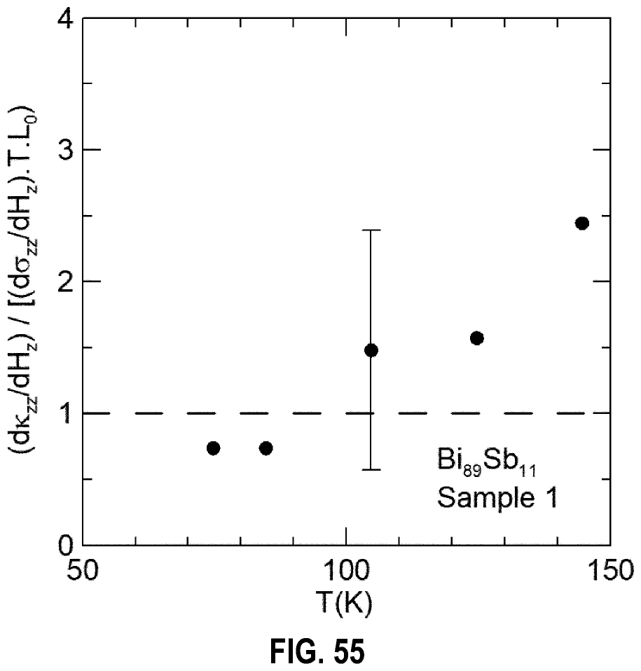

FIG. 55 illustrates the Lorenz ratio L/L₀ at H_{z}=6 tesla for Bi₈₉Sb₁₁, sample #1. The Lorenz ratio L/L₀ is obtained here by the derivative method. While less accurate than the values of L/L₀ reported for sample #6 above, the results on sample #1 are consistent with those on sample #6, illustrating the reproducibility of the data in magnetic fields.

FIG. 34 shows the verification of the Wiedemann-Franz law and gives the value for the Lorenz ratio L on sample #6, on which it has been possible to measure the magnetothermal conductivity κ_{zz}(H_{z}) and the electrical resistivity ρ_{zz}(H_{z}) simultaneously, and on which, as described in Section 5, the error on the geometric magnetoresistance is kept around 3% at T≥60 K. Whereas the main result of this article, the measurements of the thermal conductivity in longitudinal field, has been reproduced on six samples, the verification of the Wiedemann-Franz law requires accurate and intrinsic measurements of ρ_{zz}(H_{z}) that are only reported for sample #6. Sample #6 was thinned by acid etching and mounted using precision-cut guides with an alignment to the field of 0.1 degree. As explained in Section 5, ρ_{zz} (H_{z}) in all samples has extrinsic contributions from geometric effects, due to sample shape and misalignment, but they are minimized in sample #6. Attempts at eliminating these effects by thinning the other samples resulted in sample breakage. As explained in Section 5, the geometric error in the measurements of ρ_{zz}(H_{z}) is treated as a contribution to its error bar, which contributes to the error bar on L.

In this section, we present Wiedemann-Franz law verification data in magnetic field on sample #1. While less accurate, this data agrees with data showed in FIG. 34. This section uses the magnetothermal conductivity κ_{zz}(H_{z}) data of FIG. 33 and the resistivity data of FIG. 47. As discussed in Section 5, here the geometric magnetoresistance error is of order of 11-33% (depending on the field) at T≥60 K, but could be double that if other values of A are considered. The error becomes prohibitively large at low temperature (T<60 K) where the mobility μₘₒ is large. The effect of this contribution is to overestimate the resistivity and thus overestimate the Lorenz ratio L.

Determining the Lorenz ratio as done in FIG. 34 has a second source of error, namely the need to subtract the lattice thermal conductivity κ_{L} from the measured total. This is done by measuring the thermal conductivity with the field aligned along the bisectrix direction, as explained in section Section 7, above. For sample #6, we were able to measure all properties on the same sample. For sample #1, the thermal and electrical data were taken on the same crystal but samples of different sizes and separate measurements. To work around the accuracy problems associated with the subtraction of κ_{L}, we devised a new method to derive the Wiedemann-Franz law ratio of sample #1 in the presence of an external magnetic field, based not on the absolute values of electrical and electronic thermal conductivity itself, but on their field derivatives. The Lorenz ratio, normalized to L₀, is then calculated for sample #1 as:

$$\frac{L}{{L}_{0}} = \frac{( \frac{d {κ}_{zz}}{{dH}_{z}} )}{{TL}_{0} ( \frac{d {σ}_{zz}}{{dH}_{z}} )} \qquad Eqn . 63$$

and is shown in FIG. 55. Here dκ_{zz}/dH_{z} is taken from the inset to FIG. 35 and dσ_{zz}/dH_{z} from FIG. 47 at 6 tesla. Because the conductivities change linearly in field from about 4 to 8 tesla, estimated L is not field-dependent in that range.

The error bar in FIG. 55 has a different origin that the error bars in FIG. 34. It is a combination of three errors. First, the error due to the geometric magnetorestance, discussed in section Section 5, is still present. Second, the samples used for FIG. 55 were mounted separately for the electrical and thermal measurements, so that the geometric uncertainties associated with the contact placements (about 10%) and sample dimensions affect the measurements in FIG. 55. This was not the case for FIG. 34, where the copper wires of the type-T thermocouples served simultaneously for the electrical and thermal measurements in both field directions. Third, derivative methods have more noise that direct methods. Taken together, and adding the uncertainty on the value of A, the error bar on the determination of the Lorenz ratio on sample #1 in FIG. 55 is of the same order of magnitude as the measured value itself.

In summary, while less accurate than the Lorenz ratio obtained by the direct method on sample #6, the results reported in FIG. 55 are consistent with the results obtained on sample #6 FIG. 34.

### Basis of Operation of the Second Thermal Switch

The ADR stage includes two switches, one that is open in the presence of a magnetic field and has its thermal conductivity increase with the application of the magnetic field, and one that is closed in the presence of a magnetic field and has its thermal conductivity decrease with the application of a magnetic field. The operation of the second switch relies on the abovementioned Wiedemann-Franz relation between electrical conductivity and the electronic thermal conductivity. The Wiedemann-Franz relation is maximized in solids that have a strong magnetoresistance, where the electrical and thermal conductivities both decrease with the magnetic field. The materials that exhibit the strongest magnetoresistance are materials in which electrons and holes coexist at the operating temperature. They are members of a group comprising trivial semimetals, Dirac semimetals, Weyl semimetals when the field is applied to a direction normal to the separation of the Weyl point, semiconductors and topological insulators with an energy gap less than k_{B}T where T is the operating temperature. The latter are labeled intrinsic semiconductors. Electrons and holes co-exist in intrinsic semiconductors because they are thermally excited across the energy gap. Classical transport theory (E. H. Putley, The Hall effect and semiconductor physics, Dover Publications Inc., New York 1968] for multivalley semimetal of intrinsic semiconductors, in which there are two carriers of densities n₁ and n₂ with mobilities μ₁ and μ₂, the electrical conductivity σ becomes the following function of the applied magnetic field:

$$σ = \frac{{( {σ}_{1} + {σ}_{2} )}^{2} + {B}^{2} \frac{{σ}_{1}^{2} {σ}_{2}^{2}}{{e}^{2}} {( \frac{1}{{n}_{1}} + \frac{1}{{n}_{2}} )}^{2}}{{σ}_{1} [ 1 + {μ}_{2}^{2} {B}^{2} ] + {σ}_{2} [ 1 + {μ}_{1}^{2} {B}^{2} ]} \qquad Eqn . 64$$

Here σ₁=n₁eμ₁ and σ₁=n₂eμ₂. This equation gives an electrical conductivity that rapidly decreases with magnetic field (a B² function) in high-mobility materials, in particular Dirac semimetals. As a consequence of the Wiedemann-Franz law, the electronic thermal conductivity also decreases with magnetic field. Equation 64 shows that the effect of the mobility has on the magnetic field dependence of electronic thermal conductivity as pre-factor. This field dependence indeed increases quadratically with mobility at lower magnetic fields. Therefore, higher mobility materials are preferred. In the Bi₁₋ₓSbₓ system, there are two values of x where the mobility is maximum, x=0 and x=0.04. In elemental Bi (x=0), alloys scattering of electrons is avoided, resulting in an optimal mobility. At x=0.04 the alloys are Dirac semimetals, and the charge carriers at the Dirac point have theoretically a zero effective mass. Since the mobility scales with the inverse of the effective mass, theoretically the mobility diverges. This situation may be difficult to reach in practice, since the chemical potential is unlikely to be exactly at the Dirac point, but nevertheless these alloys also have the highest mobility.

Another factor which should be taken in consideration is that the lattice thermal conductivity is present and is not affected by the magnetic field. A high lattice thermal conductivity relative to the electronic thermal conductivity reduces the switching ratio. The lattice thermal conductivity should therefore be as low as possible, while the electronic contribution to the thermal conductivity should be as high as possible. The former can be achieved by increasing the antimony content, which increases alloy scattering of phonons. This is why an optimum exists near ₓ=0.04, but all alloys with 0<x<0.16 are suitable. A second way to reduce the lattice thermal conductivity at the operating temperatures is to shape the material in the second switch as a series of laminated thin plates, to induce boundary scattering, as is described for the first thermal switch.

A third way to reduce the lattice thermal conductivity and not the electronic conductivity is to add charge-neutral nanoparticles, for example silica powder, to the magnetothermal material. In the case of the second thermal switch, the electronic thermal conductivity may not necessarily benefit from topological protection. However, the electron mean free path in most semiconductors below a temperature of 10 K is of the order of 100 nm, while the phonon mean free path is of the order of a millimeter. Therefore, particles having diameters of 100 nm to 100 μm scatter phonons much more than electrons, and are suitable for this purpose.

The electronic thermal conductivity can be increased by doping the alloys n-type with Te, which is a donor impurity in the Bi₁₋ₓSbₓ alloys. The doping level may be optimized to increase the density of electrons, but also to limit the effects of ionized impurity scattering of these electrons, which decreases the mobility. An optimal value is 300 ppm Te. Values between 50 ppm and 400 ppm are also effective.

The reduction of the thermal conductivity in applied magnetic fields has been used by Red'ko, Soviet Physics Technical Physics Letters, Volume 16, p 868-869, 1990, who mentions how a magnetic field is used to separate the electronic from the lattice thermal conductivity. Samples were prepared to show the effect, which is reported experimentally in FIG. 52.

1. A thermal switch, comprising:
a magnetothermal element including a first end face and a second end face, the magnetothermal element being made of a magnetothermal material that is inherently or is inducible by a magnetic field into being a Weyl semimetal;
a first thermal terminal thermally coupled to the first end face of the magnetothermal element; and
a second thermal terminal thermally coupled to the second end face of the magnetothermal element.

2. The thermal switch according to claim 1, wherein the magnetothermal material is induced into being the Weyl semimetal by the magnetic field.

3. The thermal switch according to claim 1, wherein an on-off state of the thermal switch is controlled by the magnetic field being applied to a direction parallel to a separation of Weyl points in the magnetothermal material.

4. The thermal switch according to claim 1, wherein the magnetothermal material has a thermal conductivity that increases in response to application of the magnetic field.

5. The thermal switch according to claim 1, wherein:
the magnetothermal material is a bismuth-antimony alloy (Bi₁₋ₓSbₓ) including a first crystallographic axis and a second crystallographic axis,
the first end face and the second end face of the magnetothermal element are normal to the first crystallographic axis,
the magnetothermal material is a thermal insulator without the magnetic field or in magnetic fields oriented along the second crystallographic axis, and becomes a magnetic field-induced Weyl semimetal when the magnetic field is oriented along the first crystallographic axis,
the first crystallographic axis is the (001) axis of the magnetothermal material, and
the second crystallographic axis is one of the (100) axis or the (010) axis of the magnetothermal material.

6-7. (canceled)

8. The thermal switch according to claim 5, wherein x is between 0.04 and 0.22.

9. (canceled)

10. The thermal switch according to claim 5, wherein the Bi₁₋ₓSbₓ is doped with a concentration of tin between 10 and 200 part per million tin (Sn).

11. The thermal switch according to claim 1, wherein the magnetothermal element includes a plurality of sections of the magnetothermal material that form a laminate.

12. The thermal switch according to claim 11, wherein each section of the plurality of sections has a length dimension, a lateral dimension less than the length dimension, and is oriented so that the length dimension is orthogonal to one or both of the first end face and the second end face.

13. The thermal switch according to claim 1, wherein the first end face and the second end face of the magnetothermal element are spaced apart in a longitudinal dimension, and the magnetothermal element is configured so that paired Weyl points in the magnetothermal material are spaced along a line parallel to the longitudinal dimension.

14. The thermal switch according to claim 1, wherein the magnetothermal element includes nanoparticles in a size range of 10 nm to 100 μm, made from an electrically insulating substance, and in a concentration range from 1 to 30% by volume.

15. A thermal switch, comprising:
a magnetothermal element including a first end face and a second end face, the magnetothermal element being made of a magnetothermal material that is a member of a group consisting of trivial semimetals, Dirac semimetals, Weyl semimetals when a magnetic field is applied to a direction normal to a separation of Weyl points in the magnetothermal material, Weyl semimetals when the magnetic field does not have a component parallel to the separation of Weyl points and normal directions to at least one of the first end face or the second end face of the magnetothermal material, and intrinsic semiconductors and topological insulators when the magnetic field does not induce Weyl semimetal phase with an energy gap less than k_{B}T where T is an operating temperature;
a first thermal terminal thermally coupled to the first end face of the magnetothermal element; and
a second thermal terminal thermally coupled to the second end face of the magnetothermal element.

16. The thermal switch according to claim 15, wherein the magnetothermal material has a thermal conductivity that decreases in response to application of the magnetic field.

17. The thermal switch according to claim 16, wherein:
the magnetothermal material is a bismuth antimony alloy (Bi₁₋ₓSbₓ) including a first crystallographic axis and a second crystallographic axis,
the magnetothermal material has a first thermal conductivity without the magnetic field and a second thermal conductivity lower than the first thermal conductivity when the magnetic field is oriented along one of the first crystallographic axis or the second crystallographic axis,
the first end face and the second end face of the magnetothermal material are normal to the second crystallographic axis if the magnetic field is oriented along the first crystallographic axis,
the first end face and the second end face of the magnetothermal material are normal to the first crystallographic axis if the magnetic field is oriented along the second crystallographic axis,
the first crystallographic axis is the (001) axis of the magnetothermal material, and
the second crystallographic axis is one of the (100) axis or the (010) axis of the magnetothermal material.

18-40. (canceled)

41. A method of controlling heat flow, comprising:
providing a magnetothermal element including a first end face and a second end face, the magnetothermal element being made of a magnetothermal material that is inherently or is inducible by a magnetic field into being a Weyl semimetal;
thermally coupling a first thermal terminal to the first end face of the magnetothermal element; and
thermally coupling a second thermal terminal to the second end face of the magnetothermal element.

42. The method according to claim 41, further comprising inducing the magnetothermal material into being the Weyl semimetal by applying the magnetic field.

43. The method according to claim 41, wherein:
the magnetothermal material is a bismuth-antimony alloy (Bi₁₋ₓSbₓ) including a first crystallographic axis and a second crystallographic axis,
the magnetothermal material is a thermal insulator without the magnetic field or in magnetic fields oriented along the second crystallographic axis, and becomes a magnetic field-induced Weyl semimetal when the magnetic field is oriented along the first crystallographic axis,
the first crystallographic axis is the (001) axis of the magnetothermal material, and
the second crystallographic axis is one of the (100) axis or the (010) axis of the magnetothermal material.

44. The method according to claim 41, further comprising:
sectioning the magnetothermal material into a plurality of sections, and
forming a laminate from the plurality of sections.

45. The method according to claim 44, wherein each section of the plurality of sections has a length dimension, a lateral dimension less than the length dimension, and further comprising:
orienting each section of the plurality of sections so that the length dimension is orthogonal to one or both of the first end face and the second end face.

46. The method according to claim 41, further comprising:
spacing the first end face and the second end face of the magnetothermal element in a longitudinal dimension; and
configuring the magnetothermal element so that paired Weyl points in the magnetothermal material are spaced along a line parallel to the longitudinal dimension.

47-57. (canceled)
